(19) United States
(12) Patent Application Publication
(10) Pub. No.: US 2026/0037045 A1
(43) Pub. Date: Feb. 5, 2026

(54) CRYPTOCURRENCY MINING SYSTEM ARCHITECTURE WITH POWER INPUTS ALIGNED TO PHASE

(71) Applicant: Block, Inc., Oakland, CA (US)

(72) Inventors: Brian Stegall, Fox Point, WI (US); Yenliang B. Cheng, San Francisco, CA (US); Fujia Chen, El Cerrito, CA (US); Arjun Mahanti, Brooklyn, NY (US); Thomas B. Templeton, Piedmont, CA (US); Inderpreet Hothi, Ottawa (CA); Michael Lamfalusi, Cupertino, CA (US); Jeremy Wade, San Francisco, CA (US)

(21) Appl. No.: 19/230,612

(22) Filed: Jun. 6, 2025

Related U.S. Application Data
(60) Provisional application No. 63/677,224, filed on Jul. 30, 2024.

(51) Int. Cl. G06F 1/26; H05K 7/20

(52) U.S. Cl. CPC G06F 1/263; H05K 7/20136; H05K 7/20218

(57) ABSTRACT

Systems and methods are disclosed for managing a cryptocurrency mining system. In some examples, a system analyzes contextual data associated with a mining system to identify a condition associated with at least one component of the mining system (of a plurality of components of the mining system). The contextual data includes at least one measurement of at least one characteristic of the at least one component. The system selects, based on the condition associated with the at least one component being identified, at least one indicator (of a plurality of indicators of the mining system) to activate. The plurality of indicators corresponds to the plurality of components of the mining system. The system activates the at least one indicator to indicate the condition associated with the at least one component.

### CROSS-REFERENCE TO RELATED APPLICATIONS

This application claims the benefit of U.S. Provisional Application No. 63/677,224, filed Jul. 30, 2024 and titled “Cryptocurrency Mining System Architecture and Interfaces,” which is hereby incorporated by reference in its entirety and for all purposes.

### TECHNICAL FIELD

A cryptocurrency is digital currency that is transferred using a distributed ledger, such as a blockchain ledger. Bitcoin is an example of a cryptocurrency. Cryptocurrency (e.g., Bitcoin) mining involves a mining system validating and adding new transactions to a distributed ledger (e.g., by solving cryptographic puzzles), for which the mining system is rewarded with an amount of a cryptocurrency. Bitcoin mining operations involve identifying a solution to a cryptographic puzzle in which transactions that are to be verified form part of the puzzle parameters. Bitcoin mining operations are typically performed via brute-force techniques (e.g., an exhaustive search for a puzzle solution performed across all possible solutions). The difficulty of the cryptographic puzzle has led to the use of dedicated circuitry designed specifically for Bitcoin mining. Such dedicated circuitry can be expensive to design, purchase, and operate.

### BRIEF DESCRIPTION OF THE DRAWINGS

The detailed description is set forth with reference to the accompanying figures. In the figures, the left-most digit(s) of a reference number identifies the figure in which the reference number first appears. The use of the same reference numbers in different figures indicates similar or identical items or features. Moreover, multiple instances of the same part are designated by a common prefix, in some cases separated from the instance number by a dash and/or parentheses. The drawings are not to scale.

FIG. 1 is a block diagram illustrating an example of a mining system that includes one control board, three hashboards, four fans, and a power supply unit, in accordance with some examples;

FIG. 2 is a block diagram illustrating an architecture of a mining hashboard, in accordance with some examples;

FIG. 3 is an isometric view diagram illustrating a mining system with two fans and an indicator interface visible, in accordance with some examples;

FIG. 4 is a diagram illustrating a package for a mining system in a closed state, in accordance with some examples;

FIG. 5 is a user interface diagram illustrating a notification indicating detection of a mining system on a network, in accordance with some examples;

FIG. 6 is a user interface diagram illustrating status information for multiple mining systems on a network, in accordance with some examples;

FIG. 7 is a user interface diagram illustrating graphed hashrate (efficiency) over time, and other statistics, for multiple hashboards of a mining system, in accordance with some examples;

FIG. 8 is a conceptual diagram illustrating a legend for light indicators of an indicator interface of a mining system, in accordance with some examples;

FIG. 9 is a user interface diagram illustrating an alert on a user device indicating that a fan of a mining system is not functioning and providing options to remotely reboot the mining system and/or view details of the mining system, in accordance with some examples;

FIG. 10 is a user interface diagram illustrating an interface on a user device indicating which particular mining device of a set of mining devices on a rack has a non-functional fan, with an indication that a light indicator of the particular mining device is flashing, in accordance with some examples;

FIG. 11 is a user interface diagram illustrating an interface on a user device indicating instructions to repair or replace a non-functional fan in a mining system, in accordance with some examples;

FIG. 12A is a user interface diagram illustrating an interface on a user device indicating ASIC temperatures for multiple hashboards of a mining system, in accordance with some examples;

FIG. 12B is a user interface diagram illustrating an interface on a user device with detailed information for a specific ASIC, overlaid over the interface indicating ASIC temperatures for multiple hashboards of the mining system, in accordance with some examples;

FIG. 13 is a user interface diagram illustrating an interface on a user device for setting and/or modifying a configuration of a rack of mining systems, in accordance with some examples;

FIG. 14 is a user interface diagram illustrating an interface initiated based on an interaction between a user device and an interactive element of a mining system that detects the mining system for installation, configuration, and/or monitoring, in accordance with some examples;

FIG. 15 is a user interface diagram illustrating graphed hashrate (in TH/s) and/or efficiency (in J/TH) over time, and other statistics, for multiple mining systems, in accordance with some examples;

FIG. 16 is the user interface diagram illustrating the graphed hashrate and/or efficiency over time of FIG. 15, along with a natural language interface through which a user input asks for help in troubleshooting the drop in hashrate and/or efficiency of the specific mining system starting around 4:00 AM, in accordance with some examples;

FIG. 17 is the user interface diagram illustrating the graphed hashrate and/or efficiency over time of FIG. 15 and FIG. 16, along with the natural language interface with a response to the user input indicating a dramatic rise in temperature of the specific mining system starting around 3:36 AM and overheating starting at 3:41 AM, in accordance with some examples;

FIG. 18 is a user interface diagram illustrating graphed energy usage over time, indicators of energy clearing prices, and other statistics, for multiple mining systems, in accordance with some examples;

FIG. 19 is the user interface diagram illustrating graphed energy usage over time, along with an interface to set or adjust a configuration of one or more mining systems (e.g., setting or adjusting energy level, hashrate, and/or other settings), in accordance with some examples;

FIG. 20 is a user interface diagram illustrating a detailed alert identifying that eight mining systems (R1, R2, R3, R4, R5, and three more) have stopped hashing, a location of the eight mining systems (Katangi, Container 2), and components to be repaired (four hashboards and twelve fans), in accordance with some examples;

FIG. 21 is a view of one side of a mining system (e.g., a front of the mining device), showing three hashboards (labeled 1, 2, and 3), an indicator interface, a diagnostic action button, several ports (e.g., for power and/or network connection(s)), and an interactive element (e.g., QR code), in accordance with some examples;

FIG. 22 is a user interface diagram illustrating an interface with instructions for replacing a hashboard, along with various mining system statistics, in accordance with some examples;

FIG. 34 is an isometric diagram illustrating packaging for a mining system in an open state, in accordance with some examples;

FIG. 23 is a user interface diagram illustrating an interface for making payments (e.g., based on cryptocurrencies mined using the mining systems), in accordance with some examples;

FIG. 24 is a circuit diagram illustrating a power supply unit (PSU) architecture with correction units, in accordance with some examples;

FIG. 25 is a circuit diagram illustrating a PSU architecture for hashboards with a smaller footprint than traditional PSUs, in accordance with some examples;

FIG. 26 is an isometric diagram illustrating a mining system with a housing through which internal components are visible, in accordance with some examples;

FIG. 27 is a block diagram illustrating a multi-key system for accessing a cryptocurrency wallet, in accordance with some examples;

FIG. 28 is a user interface diagram illustrating an interface for monitoring statistics and configurations for multiple mining systems, along with an alert indicating that a specific mining system is not hashing, tracking fan speed over time for the specific mining system, and identifying how to repair the specific mining system, in accordance with some examples;

FIG. 29 is a user interface diagram illustrating an interface for monitoring statuses of large numbers of mining systems, and identifying tools and workflows for repairing one or more of the mining systems, in accordance with some examples;

FIG. 30 is a diagram illustrating a user standing in front of racks of mining systems, with indicator interfaces of specific mining systems being illuminated to alert the user about the specific mining systems, in accordance with some examples;

FIG. 31 is a diagram illustrating a removal of fans and a hashboard from a mining system (e.g., as part of a repair or component replacement), in accordance with some examples;

FIG. 32A is a user interface diagram illustrating an interface for monitoring statistics and configurations for multiple mining systems, in accordance with some examples;

FIG. 32B is a user interface diagram illustrating an interface for monitoring additional statistics and configurations for multiple mining systems, in accordance with some examples;

FIG. 33 is a diagram illustrating connectors of a power management system for one or more mining systems, in accordance with some examples;

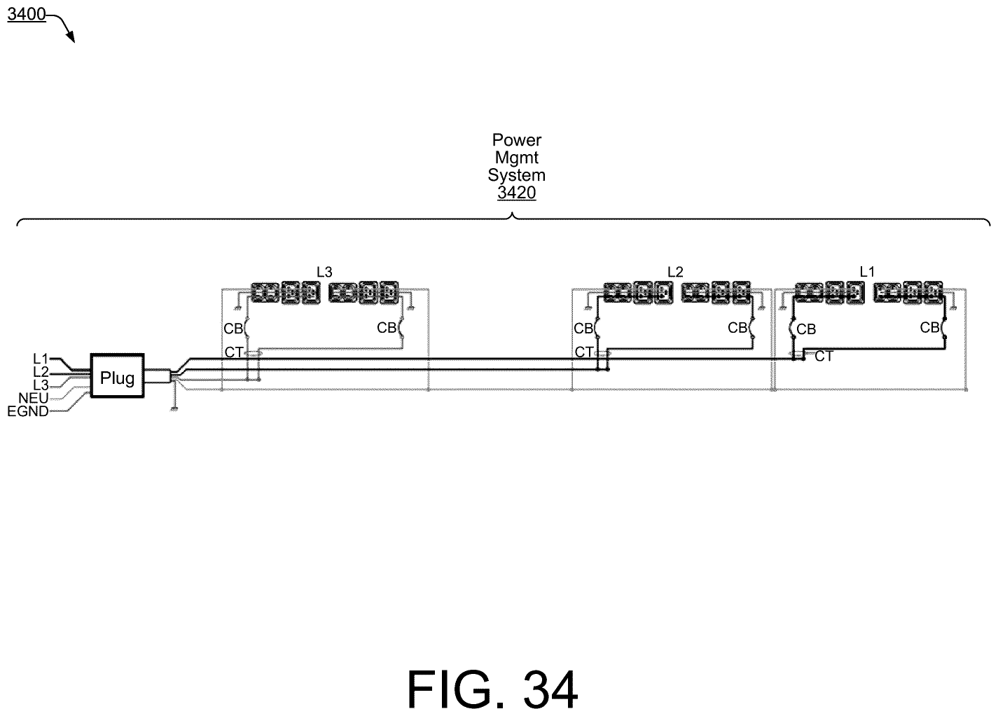

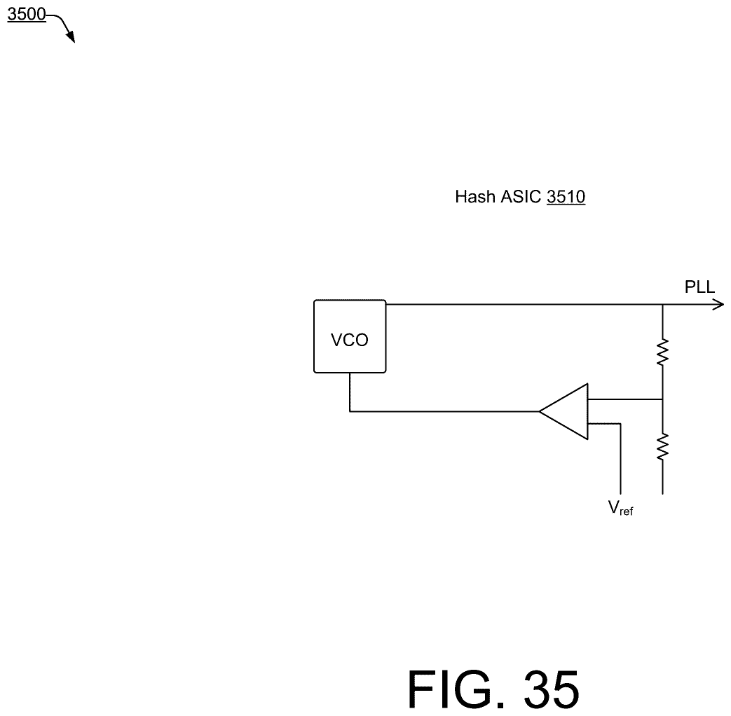

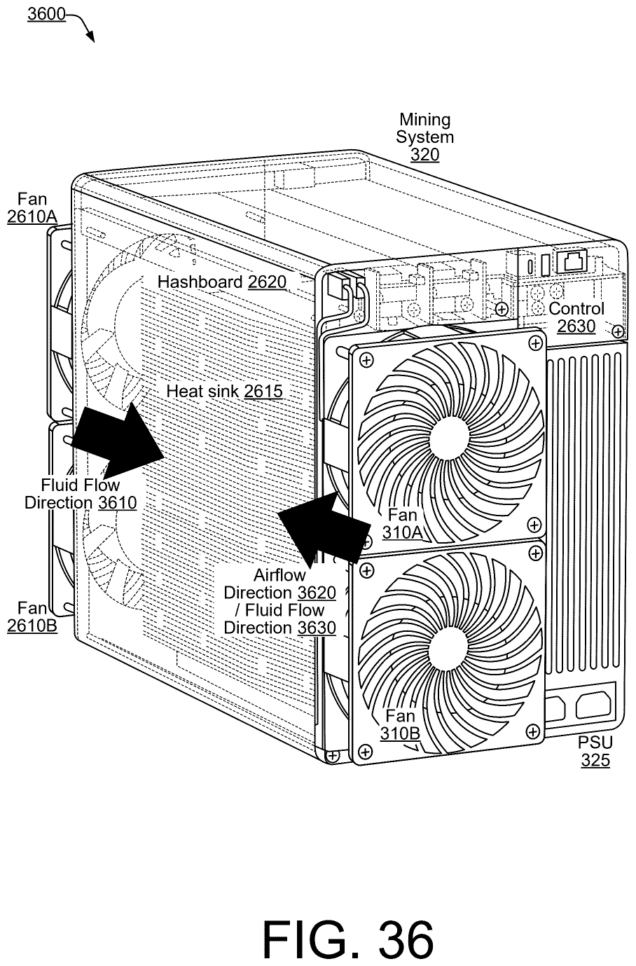

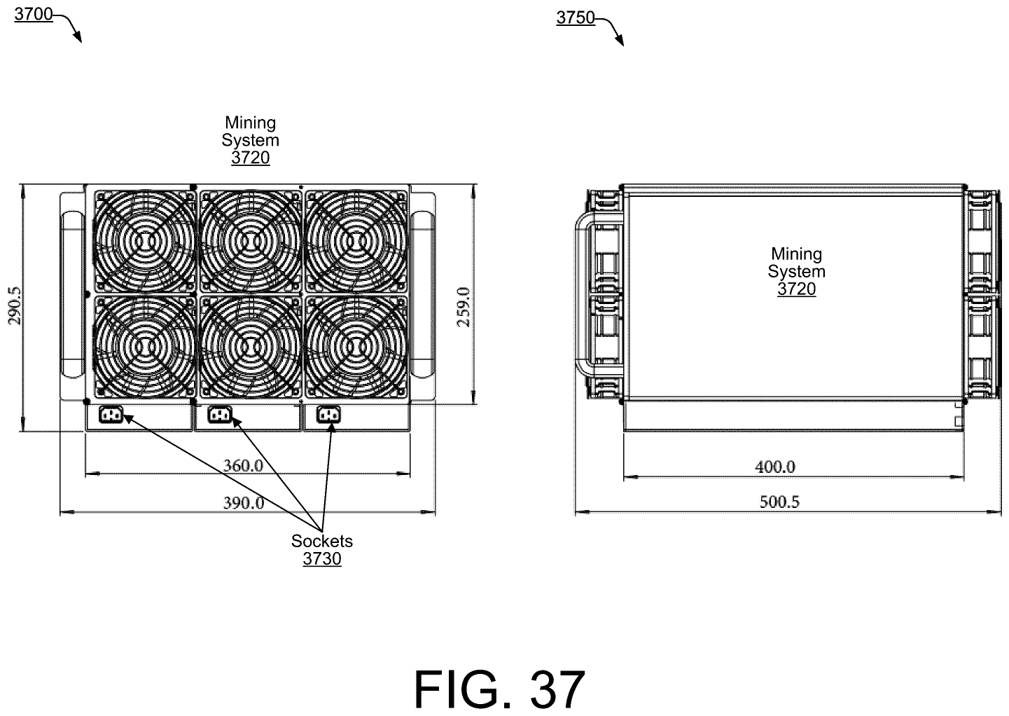

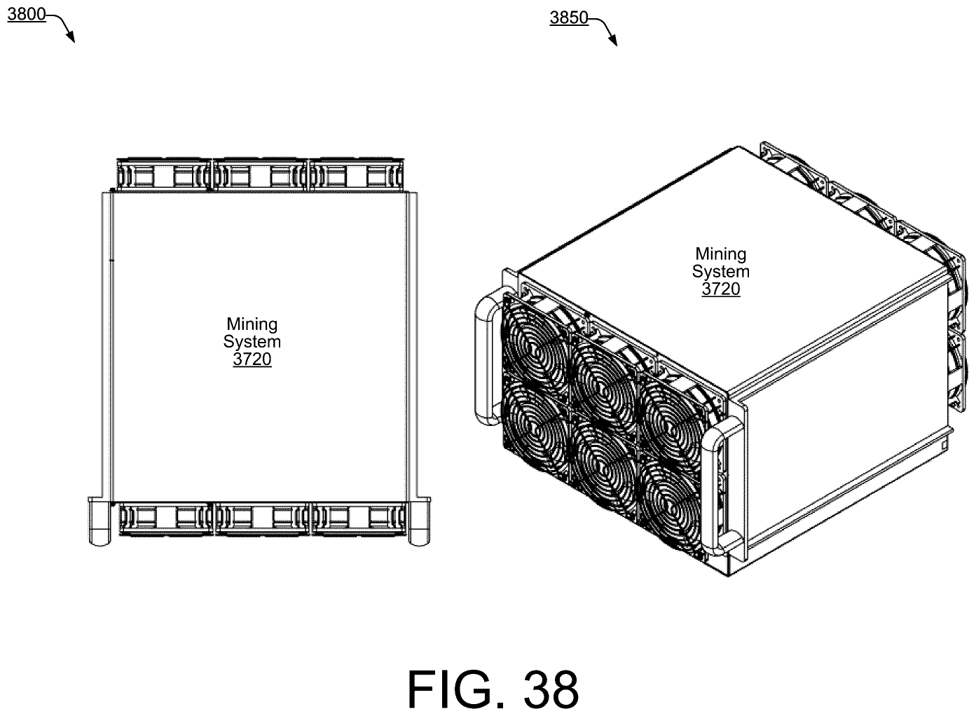

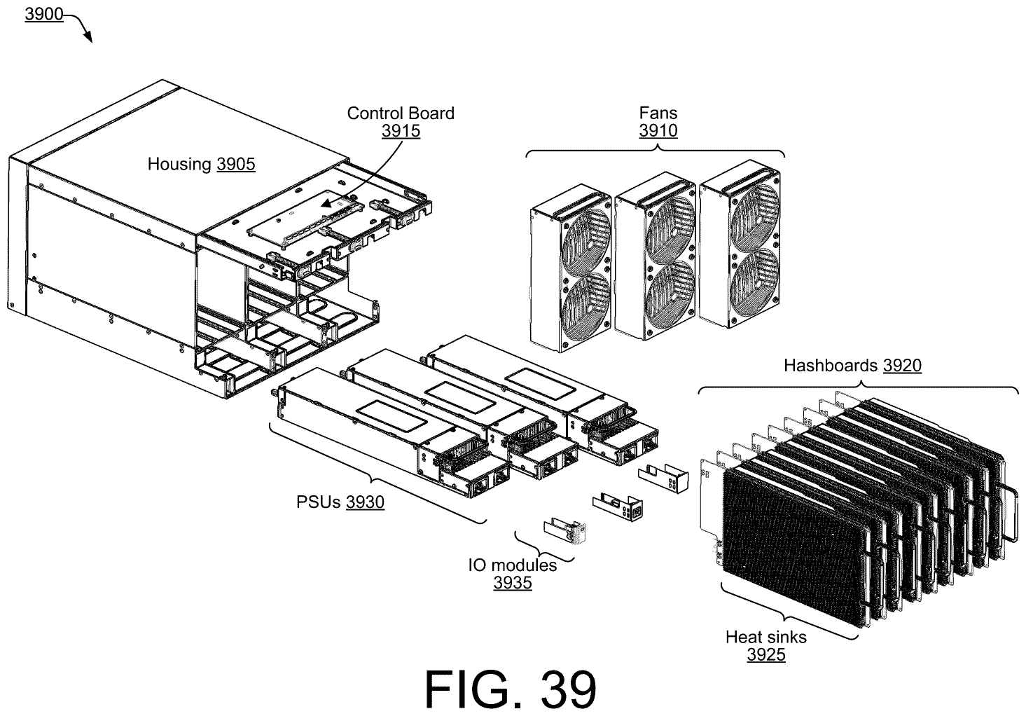

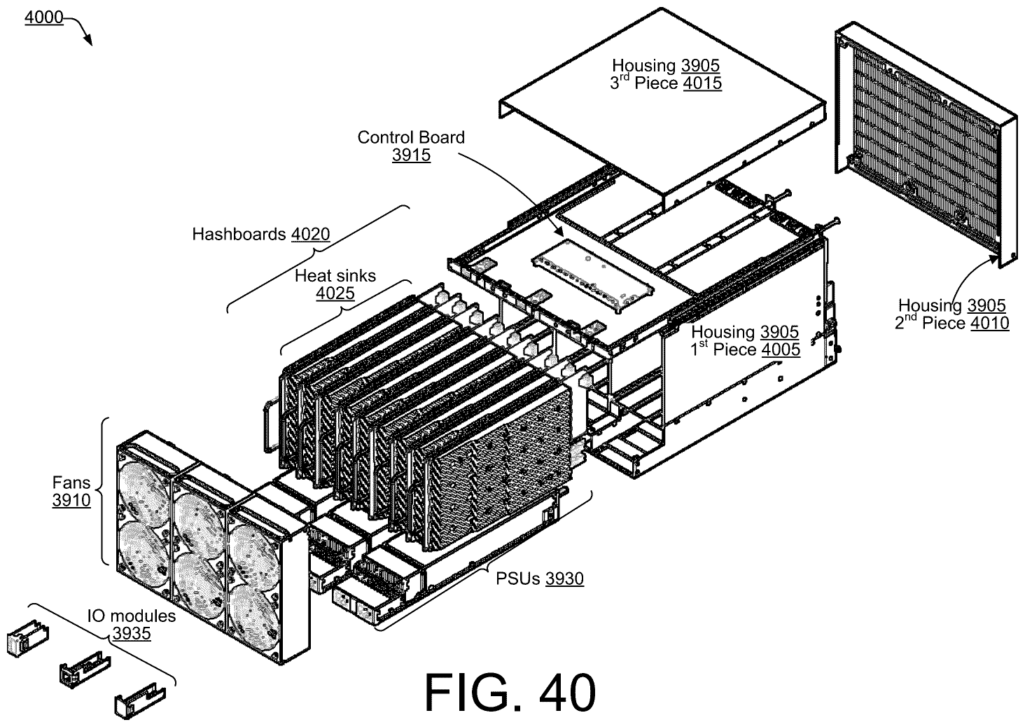

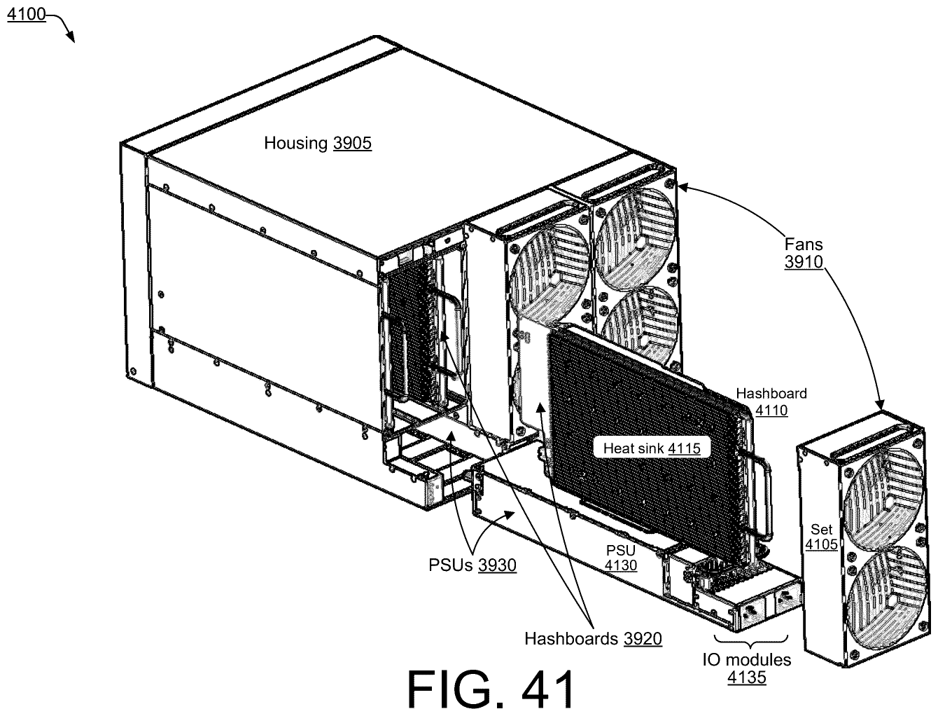

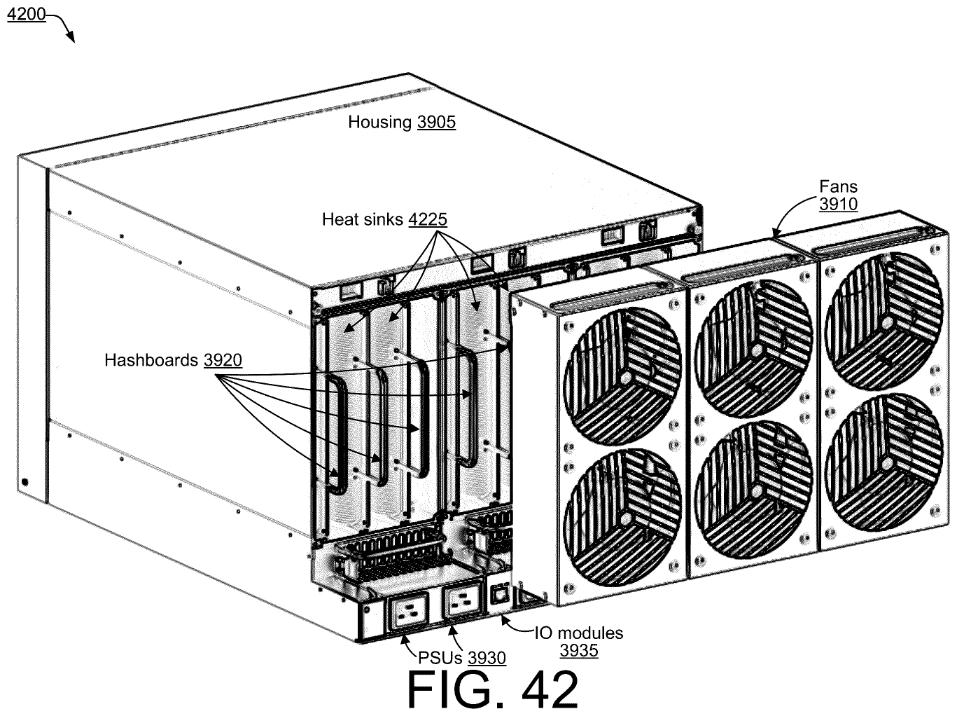

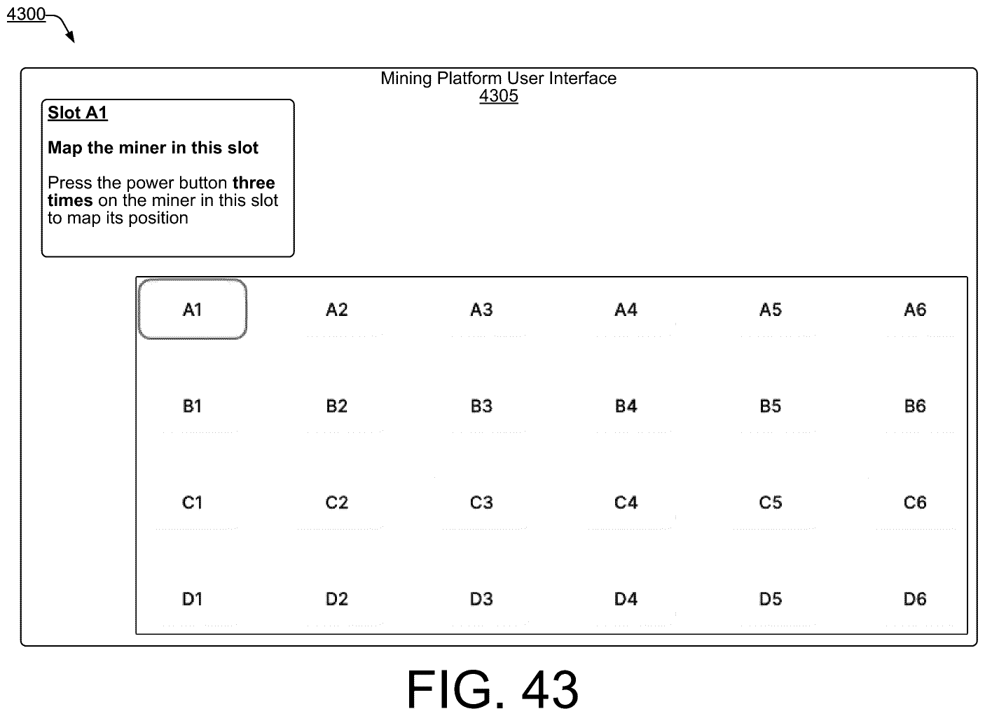

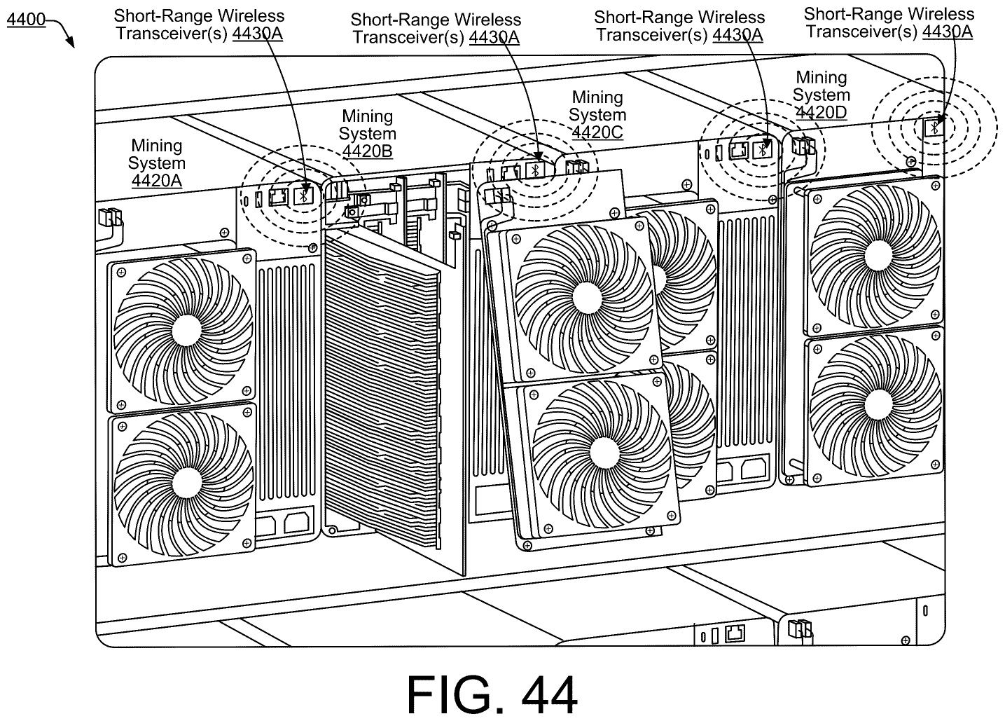

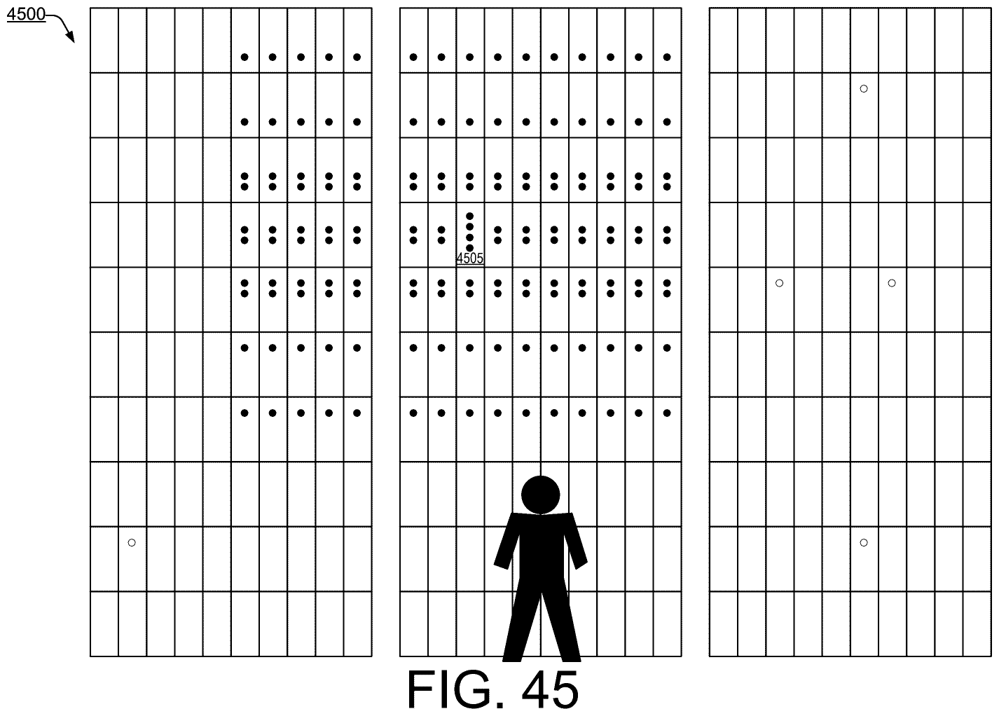

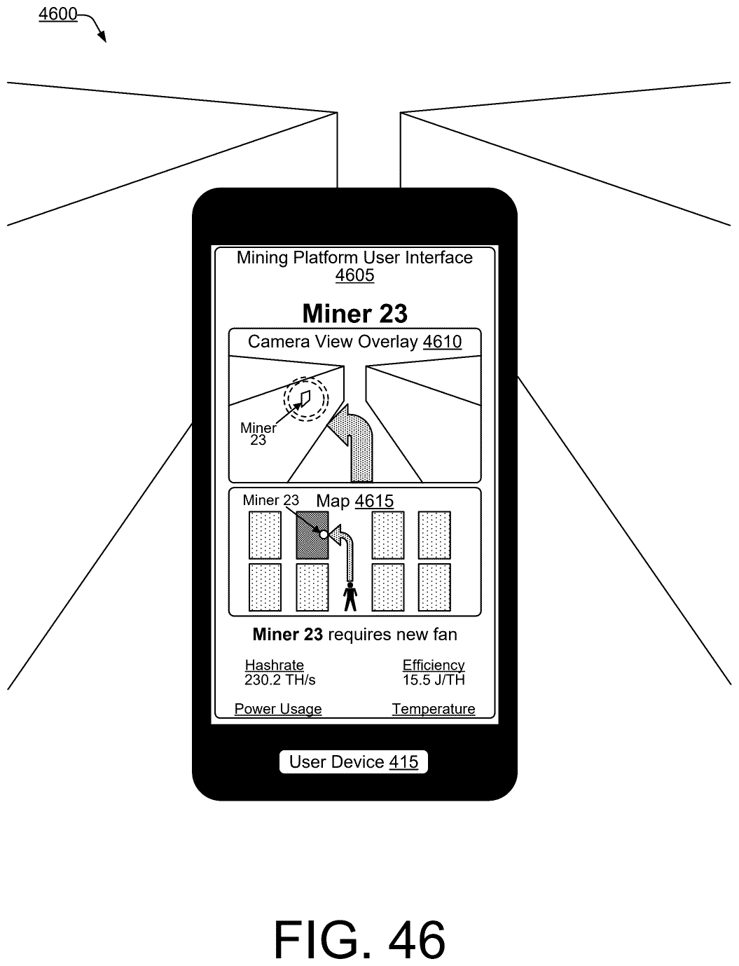

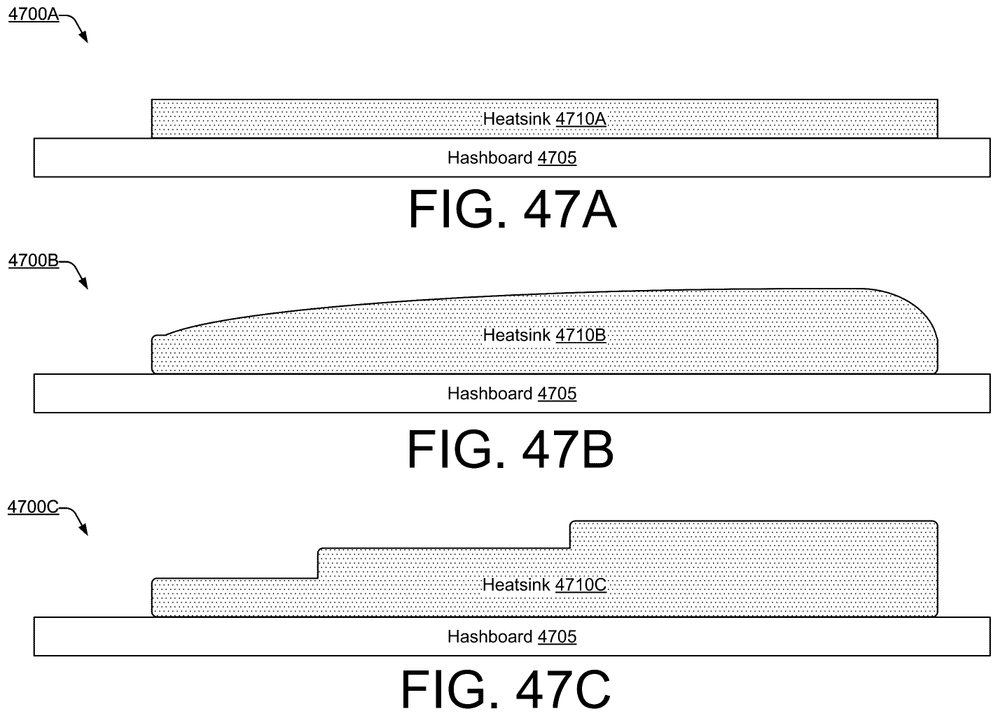

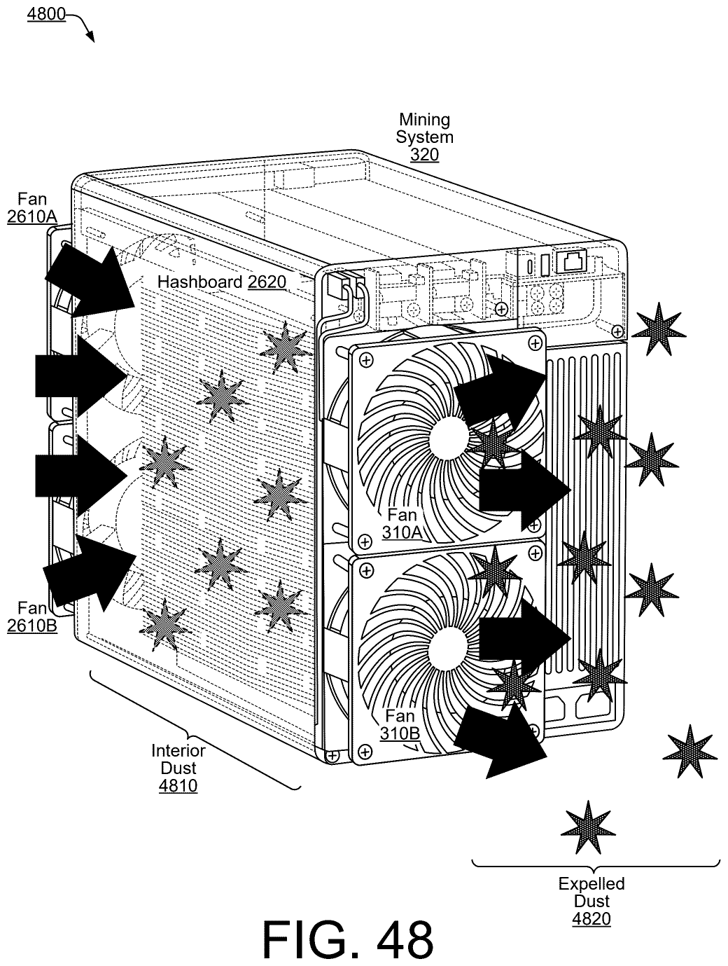

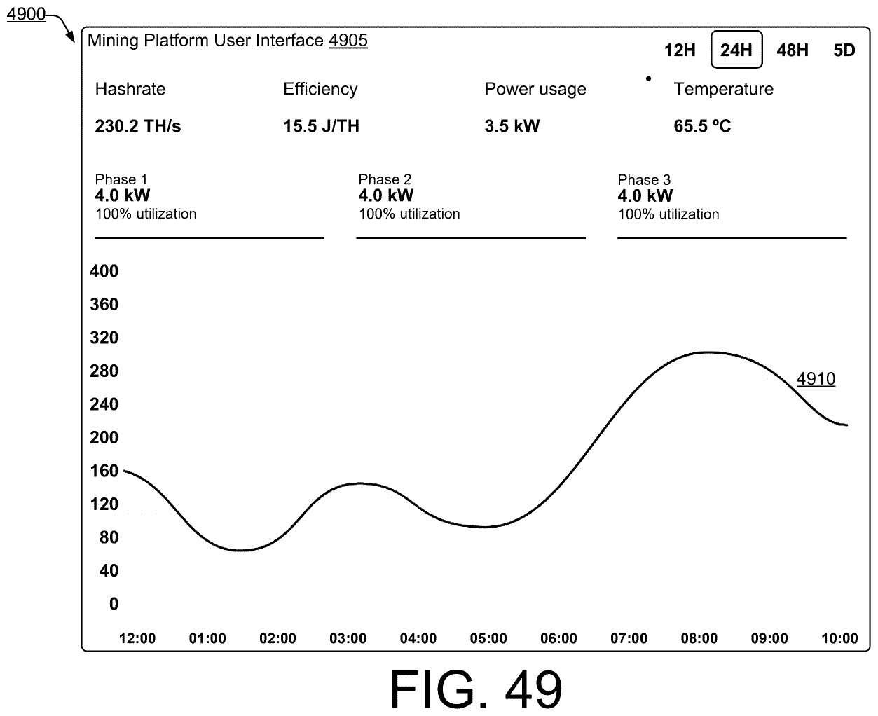

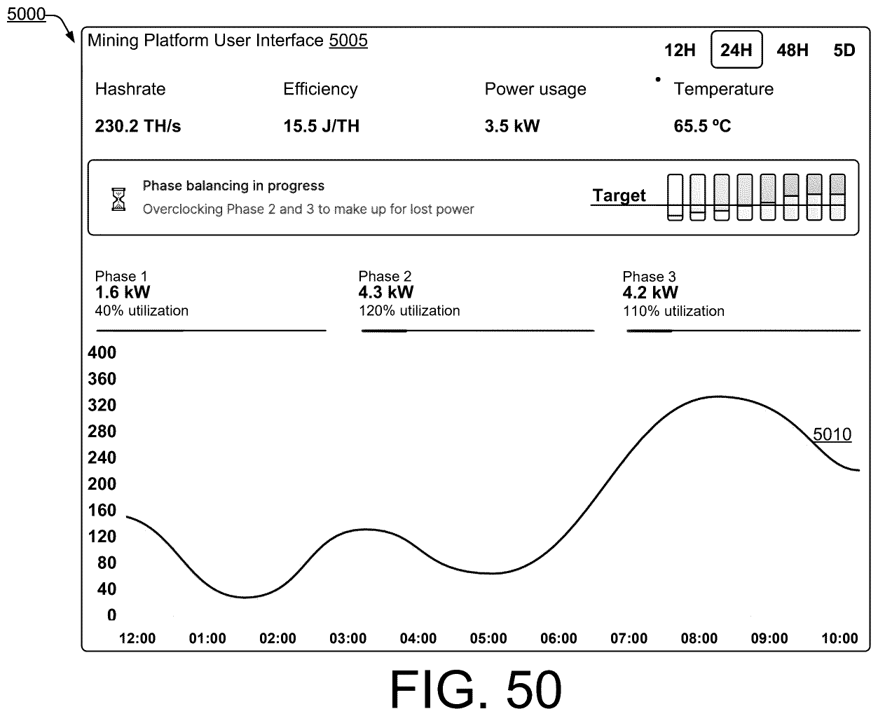

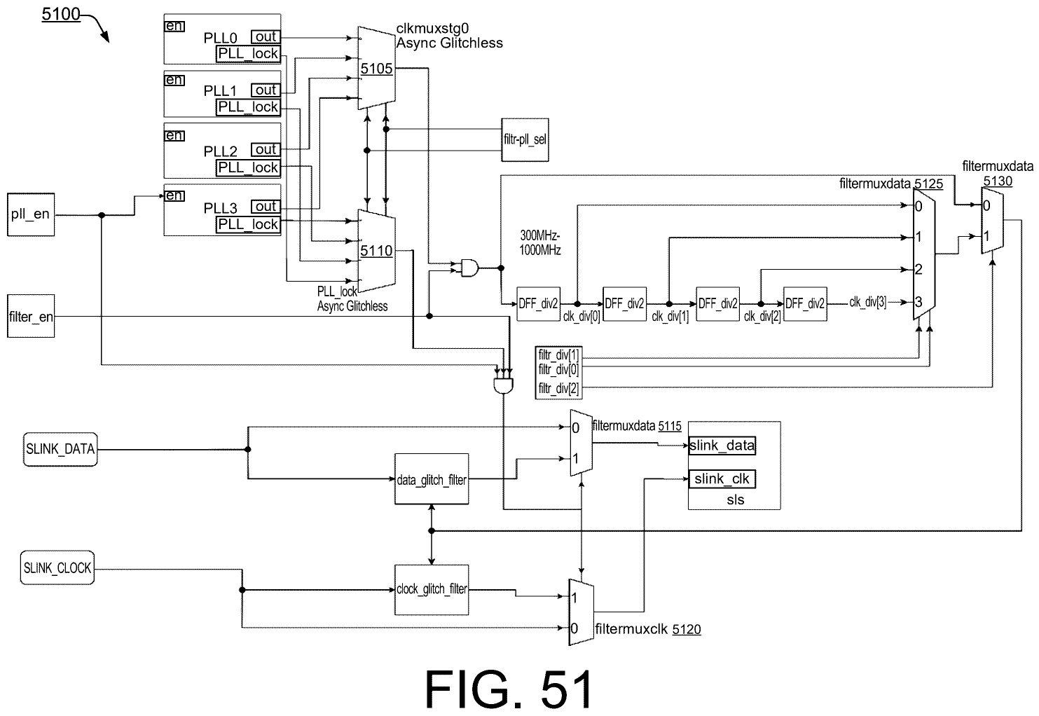

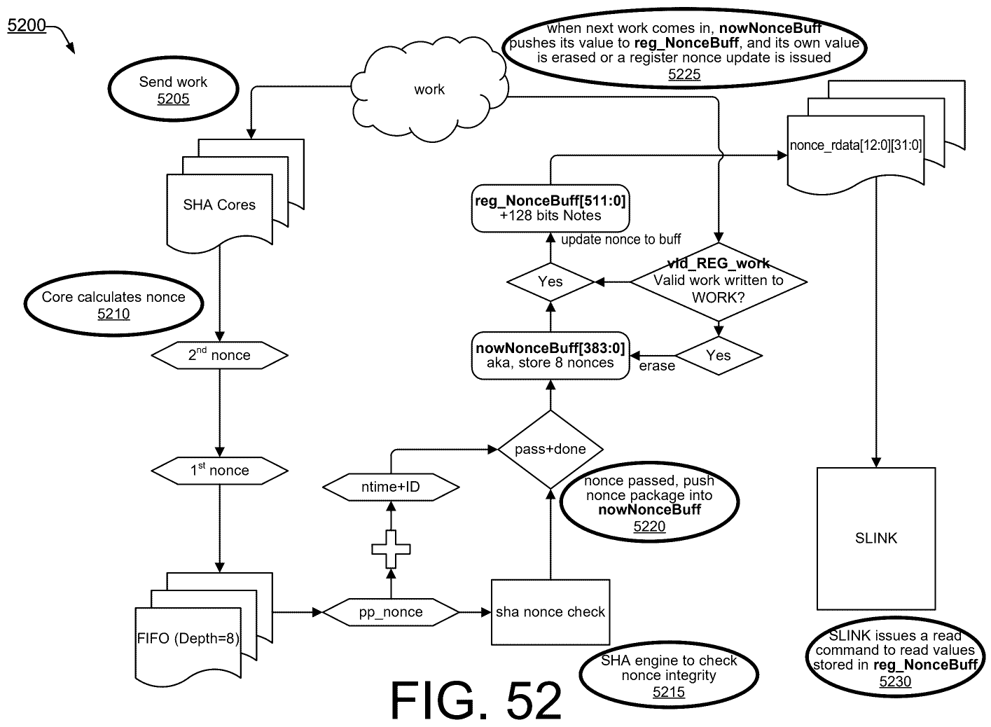

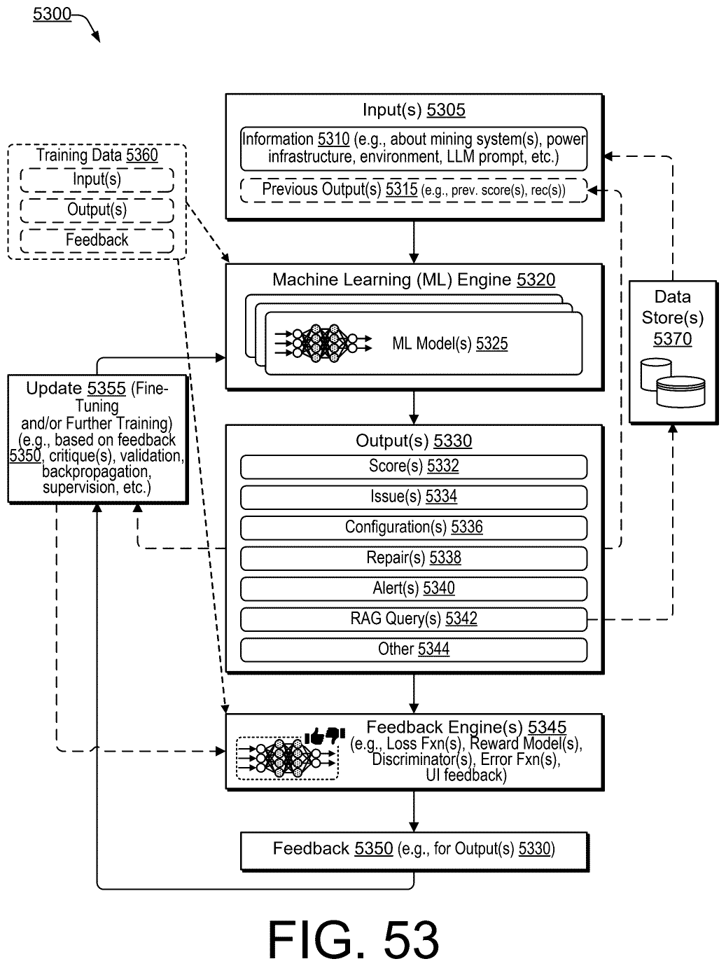

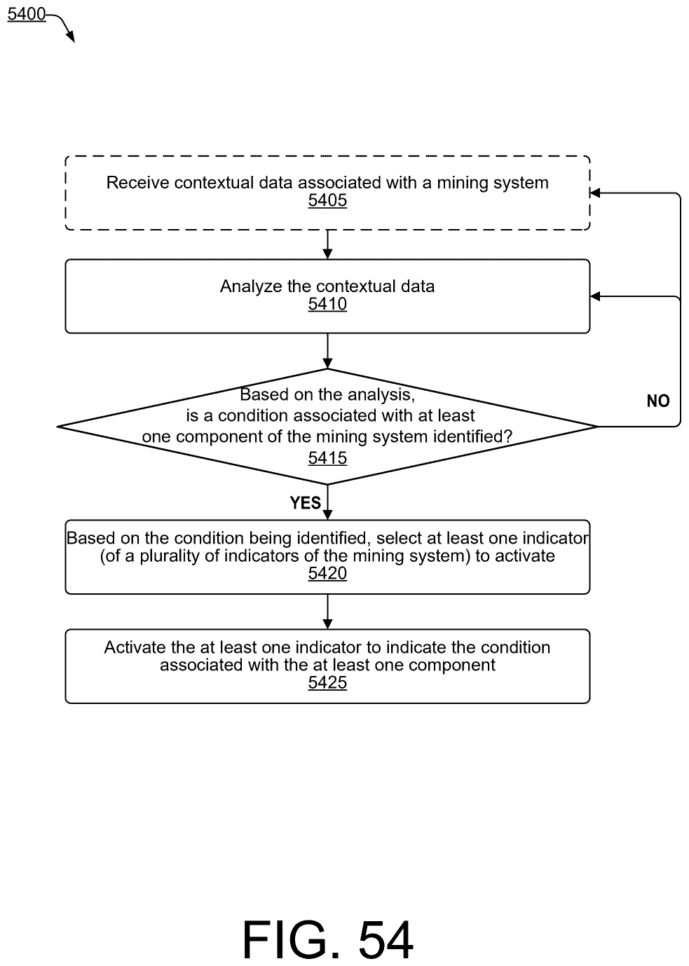

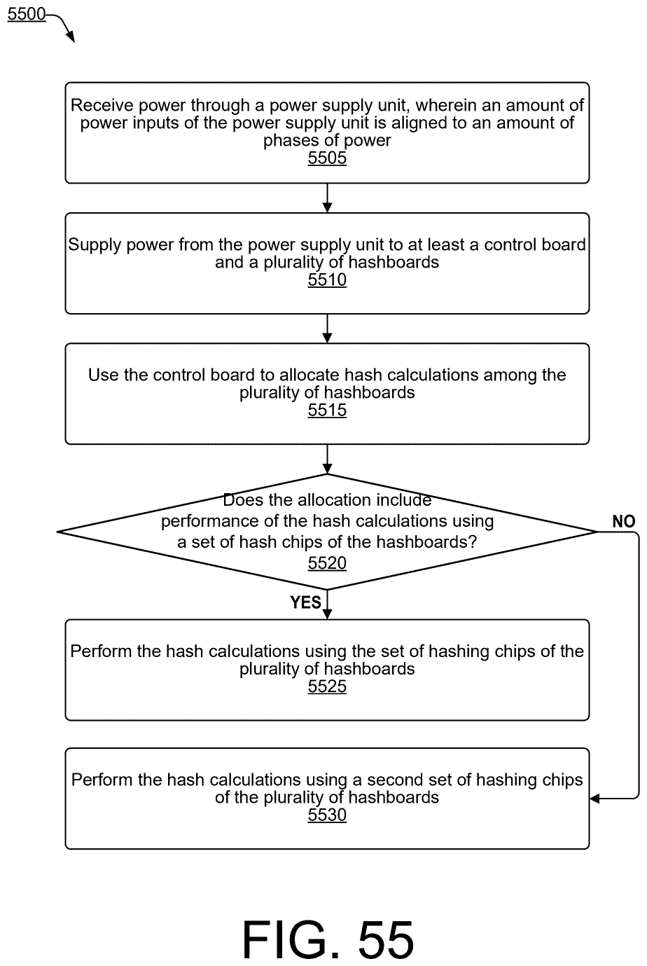

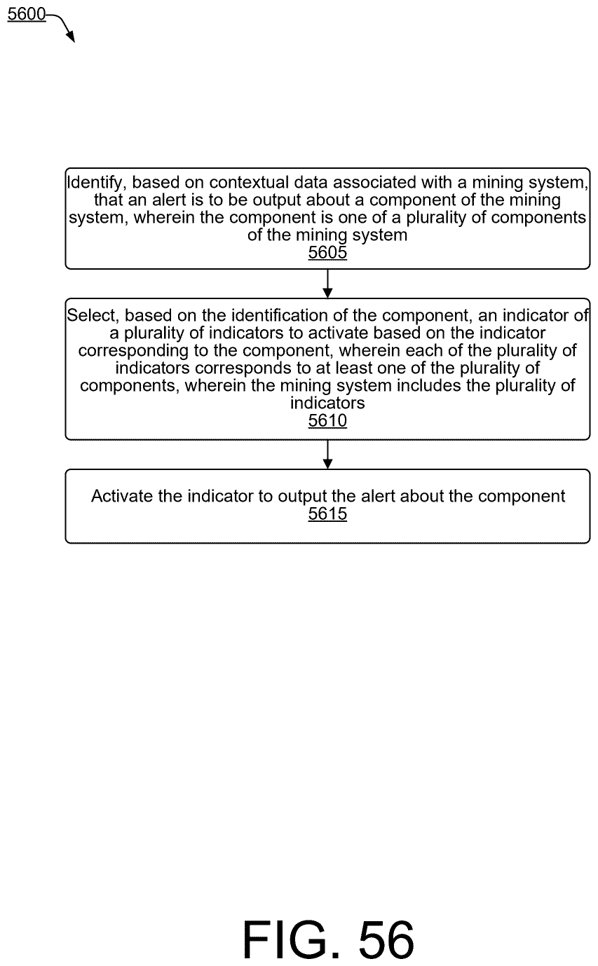

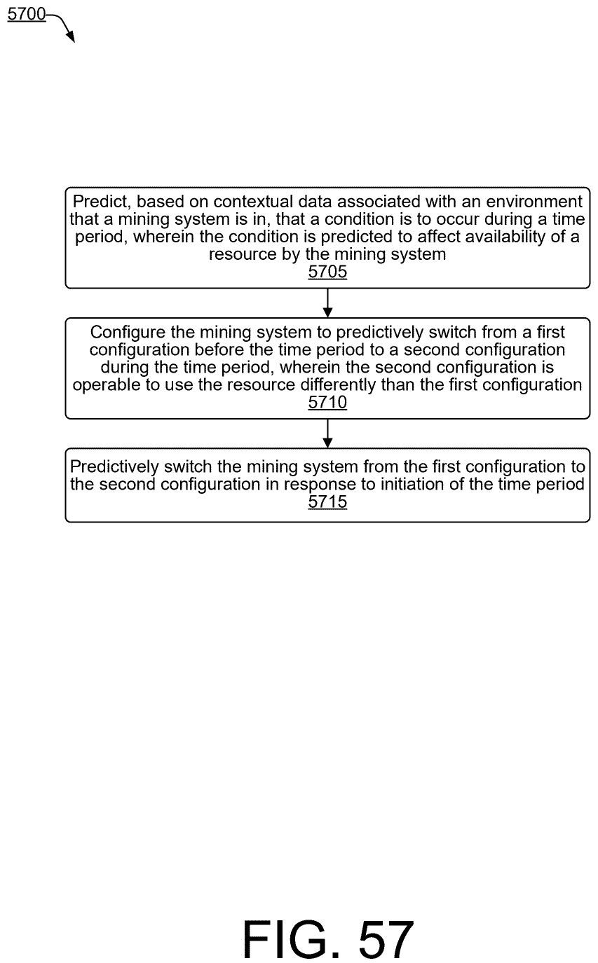

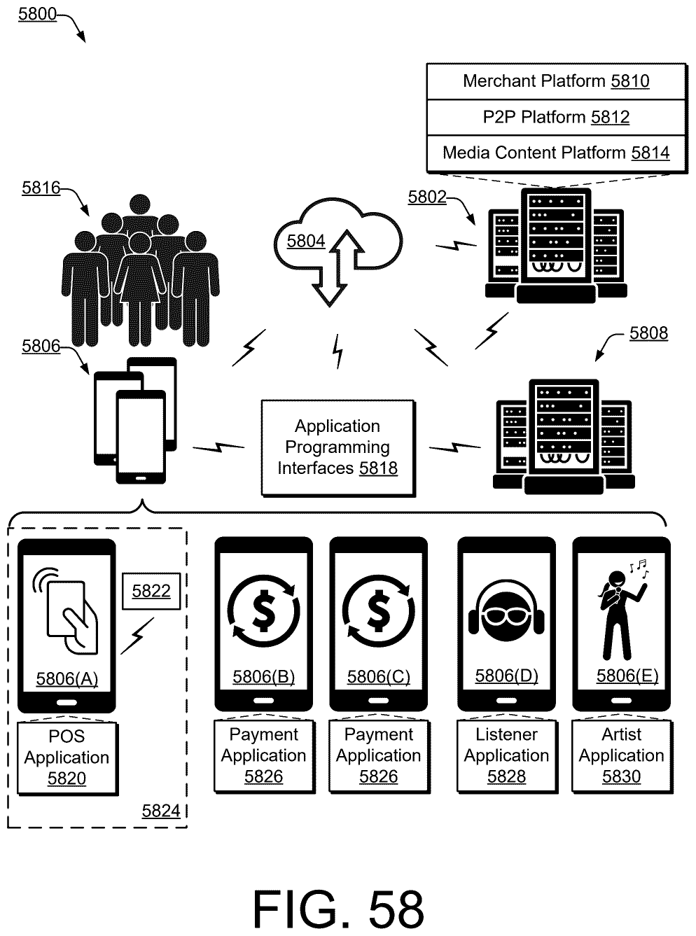

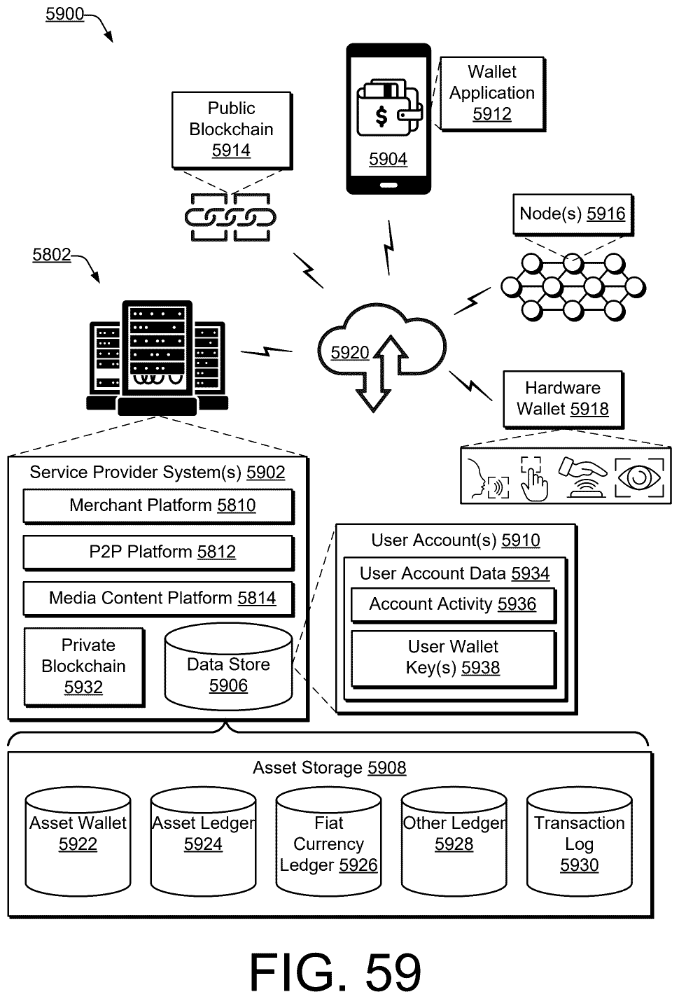

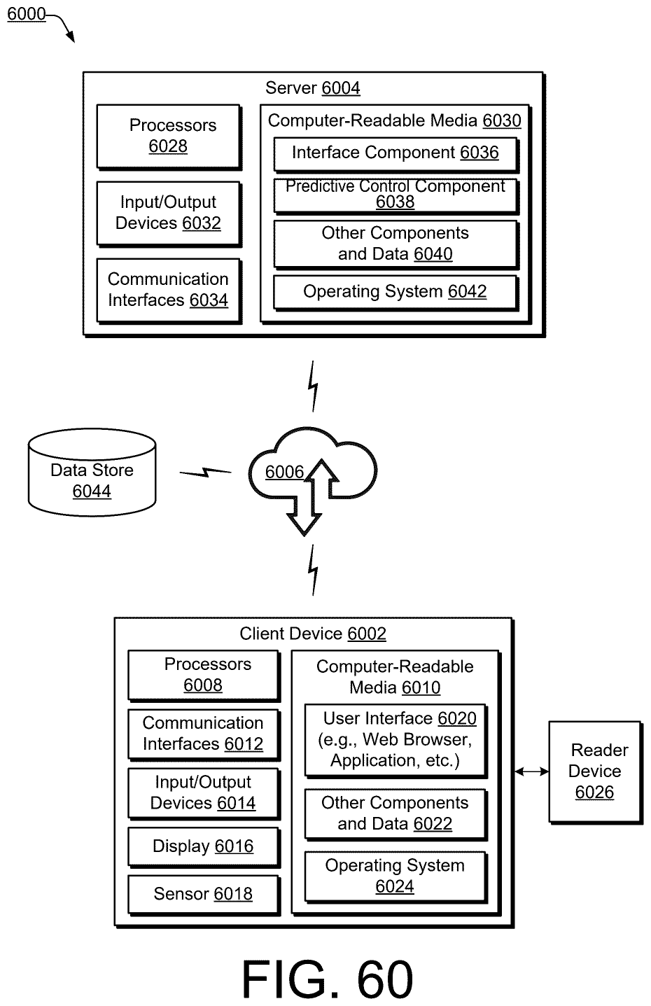

FIG. 34 is a diagram illustrating an architecture of a power management system for one or more mining systems, in accordance with some examples;

FIG. 35 is a circuit diagram illustrating a power supply control circuitry shown implemented on a hashboard in association with at least one hash ASIC, in accordance with some examples;

FIG. 36 is an image illustrating fluid flow direction and airflow direction for a hashboard in an immersion application, in accordance with some examples;

FIG. 37 includes a line diagram illustrating the anterior side of the modular mining system configured for immersion and a line diagram illustrating the posterior side of the modular mining system, in accordance with some examples;

FIG. 38 includes a line diagram illustrating the top or bottom side of the modular mining system configured for immersion and a line diagram illustrating an isometric view of the modular mining system, in accordance with some examples;

FIG. 39 is an exploded perspective view diagram illustrating a mining system with a housing, six fans, one control board, nine hashboards and corresponding heat sinks, three power supply units, and three input/output modules, in accordance with some examples;

FIG. 40 is another exploded perspective view diagram illustrating the mining system of FIG. 39, with the housing separated into three components, in accordance with some examples;

FIG. 41 is a perspective view diagram illustrating the mining system of FIG. 39 with a set of two of the fans, a hashboard, a corresponding heat sink, a power supply unit, and an input/output module removed, in accordance with some examples;

FIG. 42 is a perspective view diagram illustrating the mining system of FIG. 39 with the six fans removed, in accordance with some examples;

FIG. 43 is a user interface diagram illustrating an interface for mapping a mining system to a slot in a facility, in accordance with some examples;

FIG. 44 is a perspective view diagram illustrating a set of mining systems that each include short-range wireless transceiver(s) for communicating with one another and/or with nearby user device(s), in accordance with some examples;

FIG. 45 is a diagram illustrating a user standing in front of racks of mining systems, with indicator interfaces of specific mining systems being illuminated to directionally indicate a specific mining system that the user is to manage (e.g., perform a repair, replacement, or maintenance on), in accordance with some examples;

FIG. 46 is a user interface diagram illustrating an interface on a user device that provides information about a specific mining system and helps a user find the specific mining system using a camera view overlay and/or a map, in accordance with some examples;

FIG. 47A is a side view diagram illustrating a hashboard with a heatsink that has a uniform thickness, in accordance with some examples;

FIG. 47B is a side view diagram illustrating a hashboard with a heatsink that has a varying thickness and a curved shape, in accordance with some examples;

FIG. 47C is a side view diagram illustrating a hashboard with a heatsink that has a varying thickness and a stair-stepped shape, in accordance with some examples;

FIG. 48 is an isometric diagram illustrating actuation of the fans of a mining system to expel dust from an interior of the mining system to an exterior of the mining system, in accordance with some examples;

FIG. 49 is a user interface diagram illustrating an interface on a user device that provides information about multiple phases corresponding to one or more mining systems, in accordance with some examples;

FIG. 50 is a user interface diagram illustrating an interface on a user device that provides information about rebalancing between multiple phases corresponding to one or more mining systems, in accordance with some examples;

FIG. 51 is a circuit diagram illustrating a data filtering architecture, in accordance with some examples;

FIG. 52 is a flow diagram illustrating a process for job assignment, in accordance with some examples;

FIG. 53 is a block diagram illustrating an example of a machine learning system for training, use of, and/or updating of one or more machine learning model(s) that are used to analyze mining systems, in accordance with some examples;

FIG. 54 is a flow diagram illustrating a process for controlling and/or indicating condition(s) with component(s), in accordance with some examples;

FIG. 55 is a flow diagram illustrating a process for controlling and/or indicating condition(s) with component(s), in accordance with some examples;

FIG. 56 is a flow diagram illustrating a process for mining system interfacing, in accordance with some examples;

FIG. 57 is a flow diagram illustrating a process for predictive mining system control, in accordance with some examples;

FIG. 58 is a block diagram illustrating an example environment for providing an application and/or for customizing the application for different platforms, in accordance with some examples;

FIG. 59 is a block diagram illustrating an example environment including a service provider system which may be associated with the server(s) of FIG. 58, in accordance with some examples; and

FIG. 60 is a block diagram illustrating a system for performing techniques described herein, in accordance with some examples.

### DETAILED DESCRIPTION

Mining of cryptocurrency (e.g., Bitcoin) involves a mining system validating and adding new transactions to a distributed ledger (e.g., by solving cryptographic puzzles), for which the mining system is rewarded with an amount of a cryptocurrency. In some cases, cryptocurrency mining systems can include one or more hashboards. A hashboard is a circuit board, such as a printed circuit board (PCB), that hosts an array of mining chips or hashing chips, such as mining application specific integrated circuits (ASICs) or hashing ASICs. ASICs are integrated circuits that are customized for a particular use, rather than general use. Mining of cryptocurrencies such as Bitcoin often involves hash operations, for instance under a Proof of Work (PoW) consensus mechanism, that may be performed using these mining ASICs. In some examples, mining ASICs are single-die integrated circuits (ICs) comprising a hash core, arranged to perform processing for solving mining algorithms, and control logic arranged to control the hash core.

In some examples, the mining ASICs perform the complex computations, such as hashing calculations, that drive distributed ledger processes, such as cryptocurrency mining processes. For example, the hashing chips can hash a dataset (e.g., associated with a block of a blockchain ledger) that includes an interchangeable nonce value (e.g., in the header of the block) multiple times, each time with the nonce value set to a different value, to produce multiple hashes, until one of the hashes is within a target range associated with at least one threshold (e.g., below the threshold, above the threshold, between two thresholds, etc.). The threshold may be associated with a mining difficulty setting. In some cases, producing a hash that falls within the target range provides a reward (e.g., an amount of a cryptocurrency or another asset) and allows an associated block to be appended to the distributed ledger. In some examples, the hash algorithm may be a secure hash algorithm (SHA), such as SHA-256.

In some examples, a mining system may be a complex system that includes multiple hashboards, a power supply unit (PSU), fans, and a controller board (e.g., that controls the hashboards, the PSU, and/or the fans). In some examples, mining a substantial amount of a cryptocurrency may involve use of multiple such mining systems, which in some cases may be arranged on a rack, a set of racks, in a container, in a set of containers, or a combination thereof. In some examples, mining systems can be air-cooled or liquid-cooled. In some cases, liquid-cooled mining systems may be at least partially immersed (e.g., fully or partially immersed) in a reservoir of liquid in an immersion tank.

Each of the components in a mining system may, over time, become defective and/or require maintenance, repairs, or replacement. However, especially in large setups with numerous mining systems spread out across a facility with numerous racks and/or containers and/or immersion tanks, it can be difficult to identify which mining systems have an issue, and even then, what issue that mining system is experiencing. For instance, certain traditional mining systems only report a binary status-whether the mining system is active and mining or disabled or otherwise not mining (e.g., for any number of reasons, without providing any detail on what the reason for this status). Regular diagnostic checks ensure early detection of potential problems, allowing for timely intervention and replacement of faulty hashboards to further reduce the costs in running a Bitcoin mining rig regardless of location, design and scale. The term “mining rig” can refer to a mining system, a subset thereof, or a set of mining systems. In some cases, a mining system can include several mining rigs, each of which can each include one or more hashboards. In some examples, a mining rig refers to a hashboard and a control board associated with the hashboard.

The mining systems discussed herein (and/or server systems associated with the mining systems) provide remote management system and advanced energy controls to track granular status information of mining systems, for instance on the mining system itself (e.g., via indicator lights corresponding to specific components of the mining system) and/or via alerts sent to a user device (e.g., phone or other mobile device of the user). This granular status information can identify which specific components of which specific mining system are operational or to be repaired, replaced, undergo maintenance, otherwise require attention, or a combination thereof. In an ideal scenario, every single one of a set of mining systems is always on, constantly mining, with little or no interruptions. In reality, repairs, component replacements, and maintenance on certain systems is inevitable. This provision of granular status information therefore provides a technical improvement to the efficiency of the mining system and the set of mining systems as a whole, as troubleshooting is greatly expedited and any interruption of functioning of the mining systems can be removed or minimized, as users are immediately able to identify which mining system requires attention, and even more specifically, which component of which mining system requires attention. This is different from traditional mining systems where lack of modularity translates into replacement of the entire mining system.

In some examples, the mining systems discussed herein (and/or server systems associated with the mining systems) further preemptively generate information (e.g., notifications) for users as to what components are to be ordered (e.g., to perform a specific repair or replacement or maintenance task), what tools are required (e.g., to perform the specific repair or replacement or maintenance task), and the like, e.g., based on the status of the components. This ensures that a replacement is ready when a component is actually needed. Because mining facilities are often located in more remote locations, this, too, can provide technical improvement to the efficiency of the mining system and the set of mining systems as a whole, as troubleshooting is greatly expedited and any interruption of functioning of the mining systems can be removed or minimized, as users can guarantee that they have everything they need when they arrive on-site to the mining facility.

In some examples, the mining systems discussed herein (and/or server systems associated with the mining systems) can further predictively reconfigure mining systems based on predicted conditions, such as predicted weather conditions or predicted conditions of an electrical grid that powers the mining systems. For instance, extreme weather conditions (whether hot or cold weather) can result in increased power usage (e.g., for heating and/or air conditioning) and thus more strain on the electrical grid, which can make power less available and/or reliable, and/or can make power more expensive in some cases. If such extreme weather conditions are predicted (e.g., appear in a weather forecast), the mining systems can predictively switch settings to use less power during the periods of extreme weather, thereby adding less strain on the electrical grid and providing a technical improvement to the reliability electrical grid, to environmental sustainability (e.g., as electrical grids can draw from less renewable sources of energy when the energy grid is strained), and to the mining systems themselves (e.g., to help prevent a blackout or brownout that might interrupt service for all of the mining systems, and/or to help prevent an associated power surge that might damage the mining systems). In some cases, such events could trigger mass replacement of components, and as such, the methods disclosed herein automatically and preemptively fulfill orders.

In some examples, the mining systems discussed herein (and/or server systems associated with the mining systems) can further predictively order components for repairs, replacements, and/or maintenance that are identified to be performed and/or that are predicted to be performed. For instance, if a specific component is already identified as malfunctioning and being in need of repair, replacement, and/or maintenance, the mining systems discussed herein (and/or server systems associated with the mining systems) can predictively order a replacement of the specific component, and/or can predictively order other components that might be needed for the repair, replacement, and/or maintenance (e.g., screws, coolant, heat sinks, thermal pad, thermal paste, wires, tubes for air or liquid cooling, etc.). Further, if the mining systems discussed herein (and/or server systems associated with the mining systems) determine that a specific component (e.g., a fan or hashboard or PSU or control board) has been maintained or replaced or repaired at a specific average frequency (e.g., every 2 years) in the past, the mining systems discussed herein (and/or server systems associated with the mining systems) can predictively order a replacement instance of the specific component, and/or other components that might be needed for the repair, replacement, and/or maintenance, to arrive by a time predicted based on that frequency. The mining systems discussed herein (and/or server systems associated with the mining systems) can further determine trends in how that frequency changes over time. For instance, if a climate of a region that the mining systems are located in changes over time and the components of the mining systems start to require more frequent repair, replacement, and/or maintenance, then the predictive ordering can be accelerated, or vice versa.

In some implementations, the mining systems are associated with payment flows different from traditional flows such that the payment of components is through mining earnings and in digital currency (e.g., Bitcoin or another cryptocurrency).

The traditional mining systems suffer from several issues. For example, the traditional mining systems are not optimized for power/hash-rate density. In other words, the current hash-rate density per linear foot of rack space leaves opportunity for improvement. The current miner form factor has not changed for many generations and is not ideal for industrial scale mining. Second, there is limited infrastructure compatibility, where new miners are typically designed only for certain power distribution units (PDU), or for three-phase power, this makes them incompatible with older infrastructure; and can require the replacement of PDU infrastructure and new wiring. Third, there is lack of operational flexibility as existing mining hardware offer very limited flexibility, with hash-rate output and power consumption fixed at pre-determined operating points, impacting miners' ability to operate their fleets for maximum profitability. Fourth, miners building new infrastructure have to buy new, state-of-the-art mining hardware to align with new infrastructure, often resulting in overpayment for efficiency, resulting in lower returns—thus being overall less open to upgrades. Fourth, there are also high upgrade & deployment costs: hashboard mining hardware (PSU, fans, chassis) needlessly repurchased every 2-4 years, resulting in wasted capital expenditure. Costs are further pronounced with high maintenance costs and significant shipping, removal and deployment costs where the full miner is replaced every upgrade cycle. Key components (hashboard, control board) are generally not readily accessible on-rack, and other such issues makes removal of key components needlessly complex. Finally, traditional mining systems also have phase imbalance issues. For instance, individual miners going down results in phase imbalances in single-phase infrastructure, leading to a risk of costly infrastructure failure, resulting in derating of infrastructure, and lowering utilization.

The aforementioned phase imbalance between supplied power and input power can lead to an inability to scale the power of operational miners to match inoperative miners. In some examples, with this phase imbalance, when one miner goes down it can affect the balance of all three phases, whether a board (e.g., of a mining system) is lost or goes down completely. Remaining miners on the other phases can be unable to scale their power to offset the power that has been lost. In some examples, the mining systems discussed herein (and/or server systems associated with the mining systems) provide backward compatibility with multiple power infrastructures by matching power phases with the input power. For instance, in some examples, a number of power inputs to the mining system is based on a number of phases of a power source that the plurality of mining systems receives power from. In some implementations, the mining system has three power supplies per miner. Each Power Supply Unit (PSU) is plugged into a separate phase in the PSU. If a hashboard goes down or a miner draws less power, the power draw is evenly distributed amongst all three phases. This allows miners to utilize a greater amount of power in their facility.

In some implementations, the PSU is dynamically configured to plug into n phases, where n=1, . . . 3. This resolves the power imbalance (e.g., matching of the power phases with the input power), providing a technical improvement by improving reliability of the mining systems, preventing damage to the mining systems, and improving backup power functioning in mining systems. For example, by reusing the chassis, PSU and fans only the hashboards are replaced from generation to generation, This allows the mining system to pass the savings on to the miners and reduce a significant amount of e-waste, shipping and operational downtime. By designing the mining system in a modular fashion and be easily serviceable, it save times on operations and maintenance in facilities. Further, Increased power density and cooling, allowing miners to save on per square ft build-out costs. Additionally, by allowing miners to purchase and deploy a certain number of hashboards per miner, it maximizes their capital and allows them to run the miner at the most cost-efficient and energy-efficient settings.

Systems and methods are disclosed for managing a mining system. In a first method, a first system identifies, based on contextual data associated with a mining system, that an alert is to be output about a component of the mining system. The component is one of a plurality of components of the mining system. The first system selects, based on the identification of the component, an indicator of a plurality of indicators to activate based on the indicator corresponding to the component. Each of the plurality of indicators corresponds to at least one of the plurality of components. The mining system includes the plurality of indicators. The first system activates the indicator to output the alert about the component.

In a second method, a second system predicts, based on contextual data associated with an environment that a mining system is in, that a condition is to occur during a time period. The condition is predicted to affect availability of a resource by the mining system. The second system configures the mining system to predictively switch from a first configuration before the time period to a second configuration during the time period. The second configuration is operable to use the resource differently than the first configuration. The second system predictively switches the mining system from the first configuration to the second configuration in response to initiation of the time period.

Various aspects of the application will be described with respect to the figures.

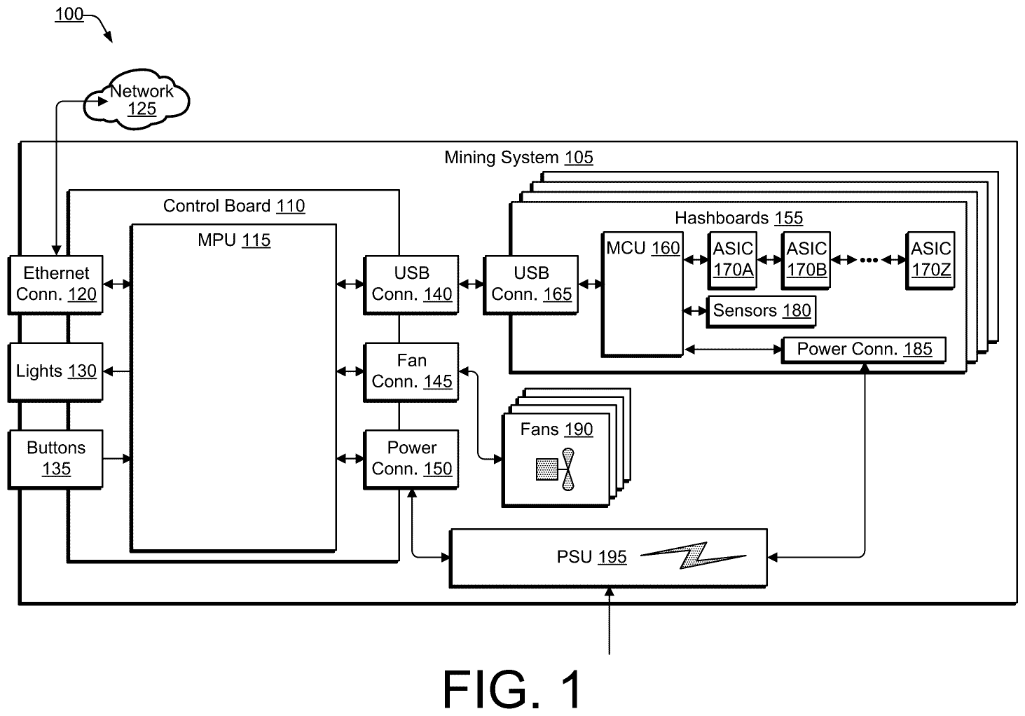

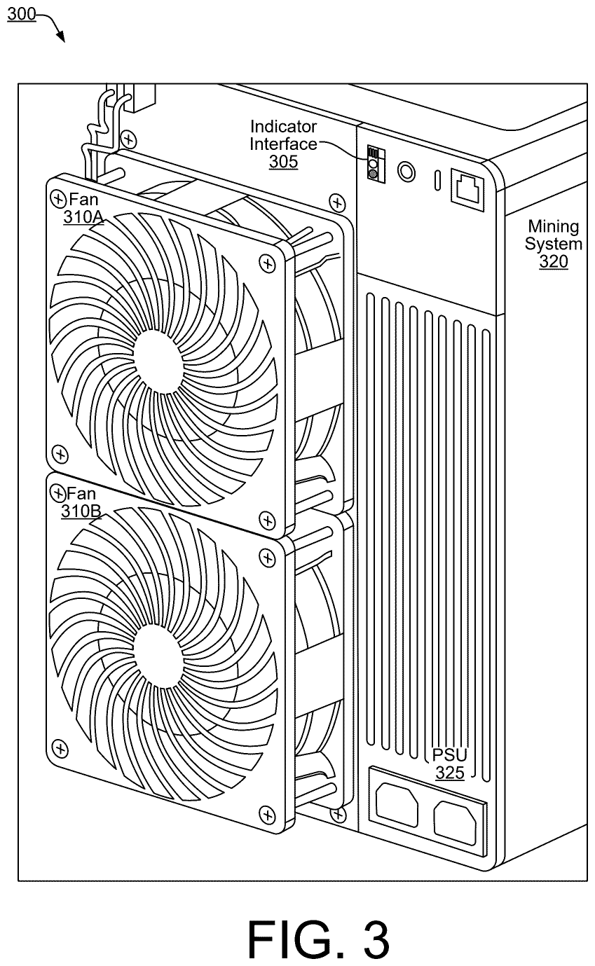

FIG. 1 is a block diagram 100 illustrating an example of a mining system 105 that includes one control board 110, three hashboards 155, four fans 190, and a power supply unit (PSU 195). The PSU 195 can receive power from an external power source, such as a power cable coupled to a power outlet (e.g., AC power (220V/110V)). The one control board 110 can include a micro-processor unit (MPU 115). The control board 110 can be coupled to a network 125 (e.g., the Internet), in some examples via an ethernet connection 120 and/or a wireless communication interface (e.g., wi-fi and/or wireless local area network (WLAN)). The control board 110 (e.g., the MPU 115) can be coupled to lights 130, which may for include indicator lights that can be used to indicate potential issues with the mining system 105 or component(s) thereof (e.g., see the indicator interface 305 of FIG. 3). The control board 110 (e.g., the MPU 115) can be coupled to buttons 135, which may be used to receive inputs at the one control board 110, for instance to reconfigure the mining system 105, reboot the mining system 105, shut down the mining system 105, reconfigure the three hashboards 155, or a combination thereof. The control board 110 (e.g., the MPU 115) can be coupled to the fans 190 through fan connectors 145. The one control board 110 can include a coupling or connection (a power connector 150) through which the one control board 110 receives power from the PSU 195. In some examples, the fans 190 receive power from the PSU 195 directly. In some examples, the fans 190 receive power from the PSU 195 indirectly, for instance passed by the one control board 110 through the fan connectors 145.

Each of the three hashboards 155 includes a coupling or connection, such as a USB connector 165, to a corresponding coupling or connection, such as a USB connector 140, of the one control board 110. Each of the three hashboards 155 includes a coupling or connection (a power connector 185) through which the hashboards 155 receive power from the PSU 195. Each of the three hashboards 155 also includes its own micro-controller unit (MCU) 160 and multiple mining application-specific integrated circuits (ASICs), labeled ASIC 170A, ASIC 170B, and so forth, until ASIC 170Z. In an illustrative example, the ASICs are 3 nm ASICs, 5 nm ASICs, BZM2 ASICs, or a combination thereof. In an illustrative example, each hashboard includes 100 ASICs. In some examples, each hashboard can include more or fewer ASICs. In some examples, the three hashboards 155 include sensor(s) 180, such as temperature sensor(s) (e.g., sensing temperatures of each of the ASICs 170A-170Z individually, sensing temperatures of groups of the ASICs 170A-170Z, sensing temperatures of the hashboards 155, sensing temperatures elsewhere in the mining system 105), airflow sensors (e.g., pressure, flow, and/or other aspects of air blown through the mining system 105 by the fans 190), fluid flow sensors (e.g., pressure, flow, and/or other aspects of fluids and/or liquids moved through the mining system 105 by the fans 190), power monitoring sensors (e.g., monitoring voltage, current, resistance, power, and/or other characteristics of power from the PSU 195), other sensors discussed herein, or a combination thereof. In an illustrative example, the mining system 105 includes three hashboards 155. In some examples, the mining system 105 can include more or fewer three hashboards 155. In some examples, the MCU 160 of a hashboard allocates various hashing calculations among the various ASICs 170A-170Z of the hashboard. In some examples, the one control board 110 (e.g., the MPU 115) allocates various hashing calculations among the various hashboards 155, and/or among the various ASICs 170A-170Z of the various hashboards 155.

In some examples, the mining system 105 includes various features and/or improvements. For instance, in some examples, the mining system 105 includes power tuning, allowing users to achieve the balance between efficiency and power control. In some examples, the mining system 105 includes upgradable firmware, for instance allowing remote upgrades and/or fast turnaround. The mining system 105 can perform mining, for instance unlocking new blocks and receiving cryptocurrency (e.g., Bitcoin) as reward(s). In some examples, the mining system 105 can have a preset configuration that includes predetermined optimized settings to operate the hashboards 155 at conditions associated with the location at which the mining system 105 will be set up. In some examples, the mining system 105 can use a Representational State Transfer (REST) Application Programming Interface (API), providing flexibility for developers to customize their applications. In some examples, the mining system 105 can use a web-based or app-based user interface (UI), provide a control and status interface to manage the hashboard 155, the fans 190, the one control board 110, the PSU 195, and/or other aspects of the mining system 105.

In some examples, a mining system can be cooled using liquid-based immersion cooling, for instance using tubes that carry liquid(s) to and/or from various mining system(s) to cool the mining system(s).

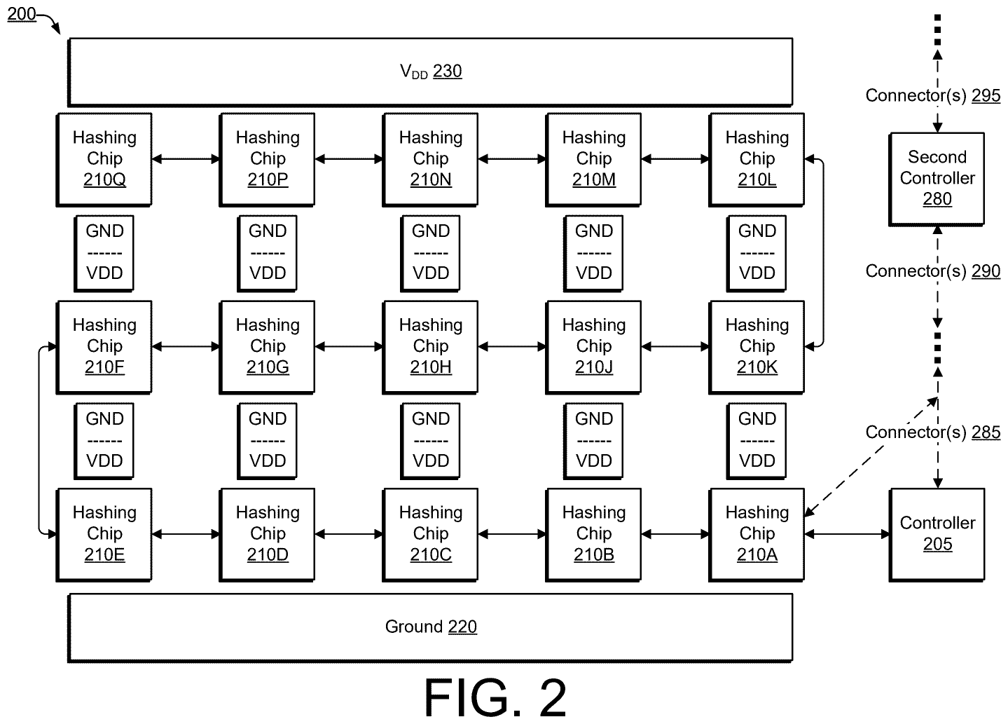

FIG. 2 is a block diagram illustrating an architecture of a mining hashboard. The architecture 200 include (as an example) fifteen hashing chips 210A-210Q. In some examples, the hashing management architecture 200 can be referred to as mining hashboards. The mining hashboard may also be referred to as a circuit board. The hashing management architecture 200 can be an example of an architecture of one of the three hashboards 155 of the block diagram 100. The hashing chips 210A-210Q are examples of the ASICs 170A-170Z.

The hashing chips 210A-210Q are coupled to a voltage (VDD)) 230 and to ground (Gnd) 220, thus receiving power. The voltage (VDD) 230 and/or the ground (Gnd) 220 can be part of the PSU 195 and/or the power connector 185, in some examples. The hashing management architecture 200 includes a controller 205 that can likewise be coupled to voltage (VDD) 230 and ground (Gnd) 220, thus receiving power. The controller 205 can be an example of the MCU 160 of the three hashboards 155. The hashing chips 210A-210Q receive instructions from the controller 205, which may for instance instruct the hashing chips 210A-210Q to perform certain hashing operations, thus apportioning hashing calculations among the hashing chips 210A-210Q. The controller 205 can send the instructions through the daisy chain to reach each of the various hashing chips 210A-210Q. The hashing chips 210A-210Q send data (e.g., computed hash digest(s)) back to the controller 205, for instance through other hashing chips of the hashing chips 210A-210Q along the daisy chain. The controller 205 is coupled to the hashing chips 210A-210Q, which are coupled to one another in a daisy chain (e.g., daisy chain arrangement and/or daisy chain configuration). For instance, the controller 205 is coupled to the hashing chip 210A, the hashing chip 210A is coupled to the hashing chip 210B, the hashing chip 210B is coupled to the hashing chip 210C, and so forth, with the hashing chip 210P is coupled to the hashing chip 210Q at the end of the daisy chain. The controller 205 can be referred to as a microcontroller, a microcontroller unit (MCU), a processor, a computing system, or a combination thereof.

In some examples, the hashing management architecture 200 can include additional hashing chips beyond the fifteen hashing chips 210A-210Q illustrated in FIG. 2. For instance, in some examples, additional hashing chips may be added between the controller 205 and the hashing chip 210A, after the hashing chip 210Q (e.g., in an additional row of hashing chips coupled to hashing chip 210Q similarly to how hashing chips 210E-210F are coupled), in between any two hashing chips of the hashing chips 210A-210Q, or a combination thereof. Likewise, one or more hashing chips of the hashing chips 210A-210Q can be omitted or removed from the hashing management architecture 200.

The hashing management architecture 200 include one or more connectors between each pair of adjacent hashing chips (e.g., between hashing chips 210A-210B, between hashing chips 210B-210C, and so forth) and between the controller 205 and the hashing chip 210A. The connectors of FIG. 2 are illustrated as double-sided arrows, with each double-sided arrow representing, one or more two-directional connectors, one or more single-directional connectors, or combinations thereof.

In some examples, the hashing chips 210A-210Q can be referred to as mining ASICs, chips, hash ASICs, hashing ASICs, hash dies, hash cores, hash chips, hashing dies, hashing cores, hashing chips, mining dies, mining cores, mining chips, ASICs, dies, cores, chips, or a combination thereof. In some examples, the hashing chips 210A-210Q can be coupled to one another. In some examples, instructions meant for a target hashing chip may pass through one or more other hashing chips before reaching the target hashing chip. In some examples, results (e.g., of mining and/or hashing calculations) performed by a specific hashing chip may pass through one or more other hashing chips before reaching the controller 205.

In some examples, the controller 205 can instruct different hashing chips 210A-210Q to generate hashes for different ranges of nonces, so that the mining computations can be parallelized across different hashing chips of the hashing chips 210A-210Q, increasing efficiency of hashing computations and/or mining computations. In some examples, the controller 205 can instruct different hashing chips to generate hashes for different sets of data altogether (e.g., associated with different transaction(s) and/or different blocks), so that the hashing computations and/or mining computations can be parallelized across the different hashing chips, increasing efficiency of hashing computations and/or mining computations. In some examples, the controller 205 can apportion different mining and/or hashing calculations across the different hashing chips based on characteristics (e.g., measured temperature) of the different hashing chips 210A-210Q, for instance instructing some hashing chips (e.g., those at a lower temperature or that are more powerful) to perform more mining and/or hashing calculations while instructing other hashing chips (e.g., those at a higher temperature or that are less powerful) to perform fewer mining and/or hashing calculations.

In some examples, the mining hashboard in the hashing management architecture 200 can include connector(s) 285, such as ports, plugs, wires, wireless communication interface(s), other connectors, or combinations thereof. In some examples, the hashing management architecture 200 can include a second controller 280 that is separate from the controller 205, and in some cases that is separate from the mining hashboard in the hashing management architecture 200. The second controller 280 can be on a control board that is separate from the mining hashboard in the hashing management architecture 200. In some examples, the hashing management architecture 200 includes the control board that the second controller 280 is on. For instance, the hashing management architecture 200 can be an example of the mining system 105, including the one control board 110 and the three hashboards 155. In some examples, the second controller 280 and/or the control board (that includes the second controller 280) includes connector(s) 290, such as ports, plugs, wires, wireless communication interface(s), other connectors, or combinations thereof. The connector(s) 285 of the mining hashboard can couple (e.g., in a wired or wireless fashion) to the connector(s) 290 of the second controller 280 and/or the control board (that includes the second controller 280). For instance, the second controller 280 can be an example of the one control board 110 and/or the MPU 115. The connector(s) 285 can be examples of the USB connector 140. The connector(s) 290 can be examples of the USB connector 165.

In some examples, instructions from the second controller 280 to the controller 205 and/or the hashing chips 210A-210Q can be sent by the 280, conveyed by the connector(s) 290 and/or the connector(s) 285, and received by the controller 205 and/or the hashing chips 210A-210Q. Results of the hashing computations and/or mining computations can be output from the hashing chips 210A-210Q and/or the controller 205, conveyed by the connector(s) 285 and/or the connector(s) 290, and received by the second controller 280. In some examples, the second controller 280 and/or the control board (that includes the second controller 280) includes other connector(s) 295. In some examples, the connector(s) 295 can couple the second controller 280 and/or the control board (that includes the second controller 280) to other mining hashboards, to a power supply (e.g., to the voltage (VDD)) 230 and/or to ground (Gnd) 220), to a third controller (e.g., that can also control aspect(s) of the performance of the hashing calculations), or a combination thereof.

In some examples, the connector(s) 285 of the mining hashboard include at least one connector that is coupled to the controller 205, so the controller 205 conveys communications between the mining hashboard and the second controller 280. This can provide a benefit in that the controller 205 can parse and/or interpret instructions from the second controller 280 for the hashing chips 210A-210Q, and/or can arrange instructions (from the second controller 280 and/or from the controller 205 itself) in an optimal order, improving efficiency of the hashing management architecture 200. In some examples, the connector(s) 285 of the mining hashboard include at least one connector that is coupled to at least one of the hashing chips 210A-210Q directly (e.g., hashing chip 210A), bypassing the controller 205. This can provide a benefit by allowing the second controller 280 to exert independent control over the hashing chips 210A-210Q without interference from the controller 205 (e.g., if the controller 205 is compromised or damaged), improving security, reliability, and flexibility of the hashing management architecture 200.

In some examples, a first aspect of performance of the hashing calculations (controlled by the controller 205) controls aspects that are specific to the mining hashboard that the controller 205 and the hashing chips 210A-210Q are located on, while the second aspect of performance of the hashing calculations (controlled by the second controller 280) controls aspects of both the mining hashboard (that the controller 205 and the hashing chips 210A-210Q are located on) and other mining hashboards (separate from the specific mining hashboard) that the second controller 280 (and/or its control board) is also coupled to (e.g., via the connector(s) 295).

FIG. 3 is an isometric view diagram 300 illustrating a mining system 320 with two fans and an indicator interface 305 visible. A top fan 310A and a bottom fan 310B of the mining system 320 are visible, and represent examples of the fans 190. A PSU 325 of the mining system 320 is also visible, and represents an example of the PSU 195. Users care about reducing and/or maintaining the heat output of their mining system 320. When problems arise, a user wants to easily be able to diagnose and resolve them. It is important to have reliable miners that won't flake out or take days to repair. It is also important to be able to quickly diagnose issues and/or identify which repairs need to be undertaken, which can be aided by the indicator interface 305. In some examples, the mining system 320 can be referred to herein as a mining device, a miner system, a miner device, or a miner.

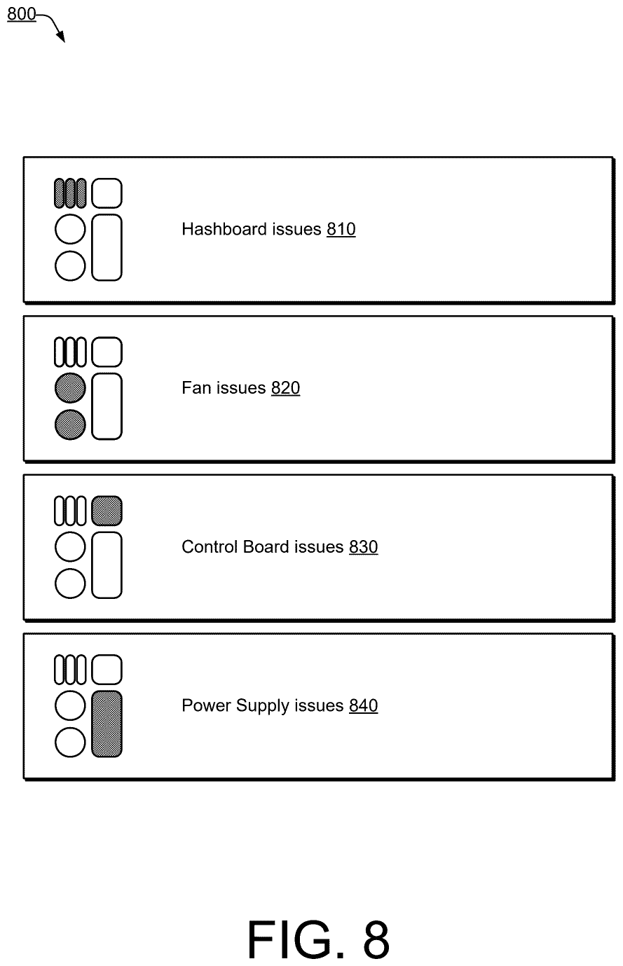

The indicator interface 305 of the mining system allows for easy diagnosis of issues as discussed further, for instance by indicating which component(s) of the mining system have issues to be resolved, require repairs, require replacement, require maintenance, and the like. For instance, per the legend 800 in FIG. 8, the indicator interface 305 of FIG. 3 indicates an issue with the bottom fan 310B, since all of the indicator lights in the indicator interface 305 are illuminated in green except for the bottom-left round indicator that is illuminated in red and represents the bottom fan (of the two fans). The different indicators of the indicator interface 305 may be shaped like, and arranged similarly to, the mining system itself.

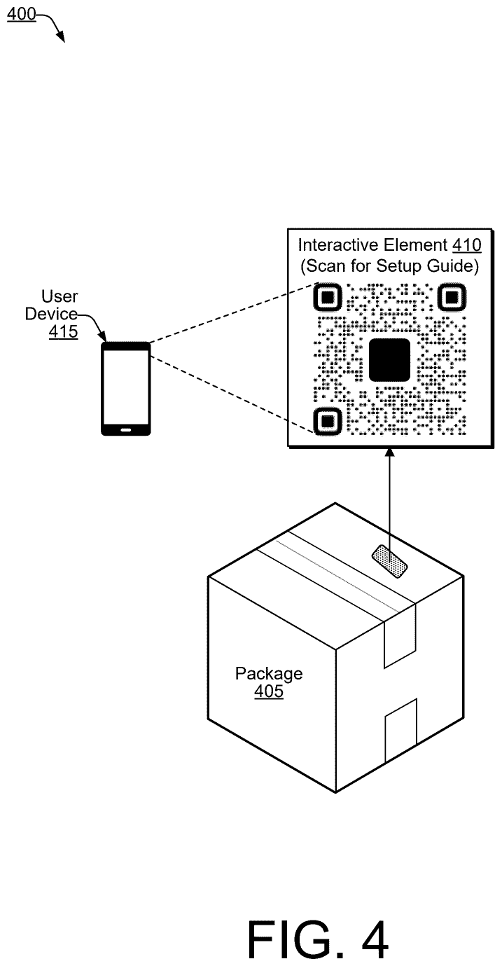

In an exemplary workflow, a first user acquires five mining systems. Instead of paying the full amount up front, the first user elects to pay back over time with the bitcoin that he mines. A few days before his miners are set to arrive, the first user gets an email that has instructions and details on how to install and set up his miners. When his miners are delivered, he sees that each mining rig is packaged in a box with a handle so it's easier to lift and maneuver. An example of the packaging is illustrated in FIG. 4.

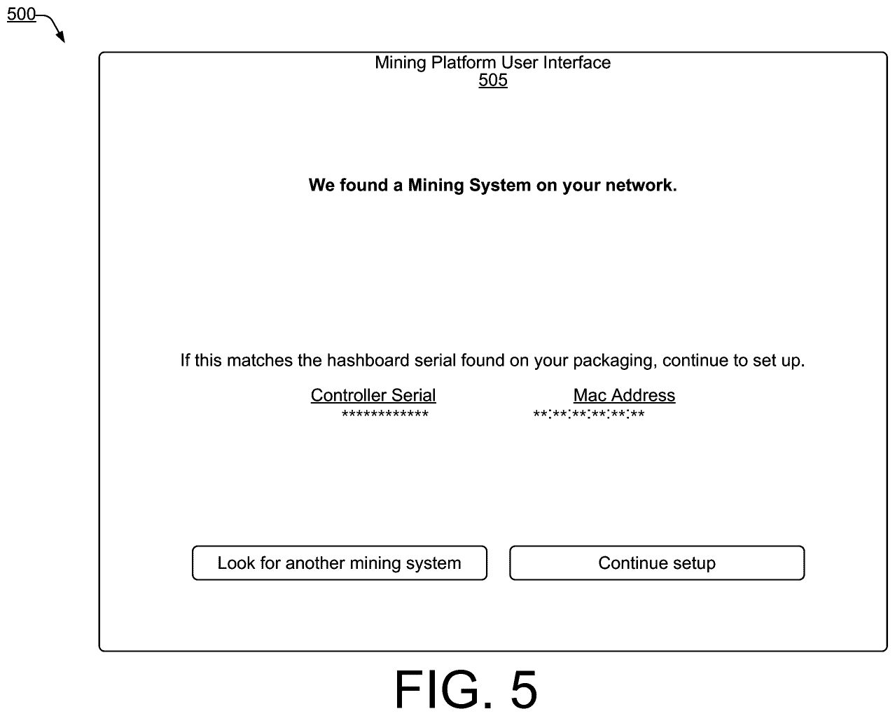

FIG. 4 is a diagram 400 illustrating a package 405 for a mining system in a closed state. The package 405 can includes box, poly mailers, and/or a welcome package. The box includes a setup guide with an interactive element 410 (e.g., a barcode, a 2D matrix barcode such as a quick response (QR) code, another type of optical glyph, an NFC tag, an RFID tag, another type of short-range wireless transceiver, or a combination thereof). The first user can use their user device 415 to interact with the interactive element 410 (e.g., scan the optical glyph as illustrated in FIG. 4) to identify a URL or other pointer to a setup guide for the mining system(s). The first user opens up a miner and scans the setup guide QR code which directs the first user to instructions on how to set up the mining system(s), for instance as illustrated further in FIG. 5. In some examples, the package 405 that the mining systems were initially shipped in can be re-used to ship the mining systems back for repairs, for instance, if a more complex repair is needed. The durable package 405 is designed to be modular and reusable so she can use the box lid and included polymailers to repack the hashboard for transport.

FIG. 5 is a user interface diagram 500 illustrating a notification indicating detection of a mining system on a network. The interaction with the interactive element 410 can lead to the notification, shown as a mining platform user interface 505, which can identify any mining system(s) connected to the first user's network (e.g., to the same network as the user device is connected to). Once plugged in, the software recognizes a new miner on his network and prompts the first user to set it up. The first user adds a name, location, and rack position to the miner and then connects to his mining pool.

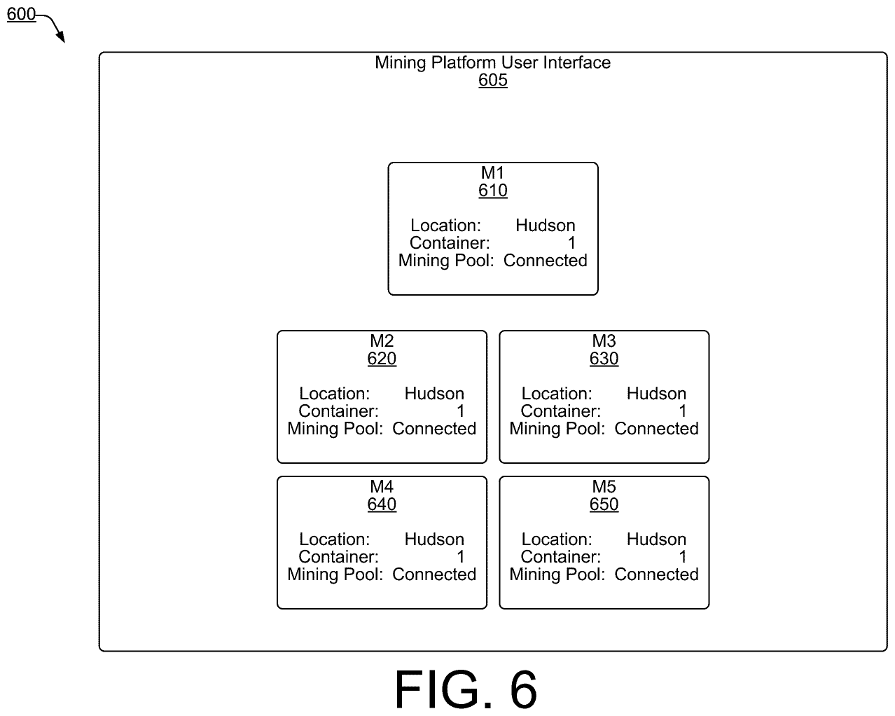

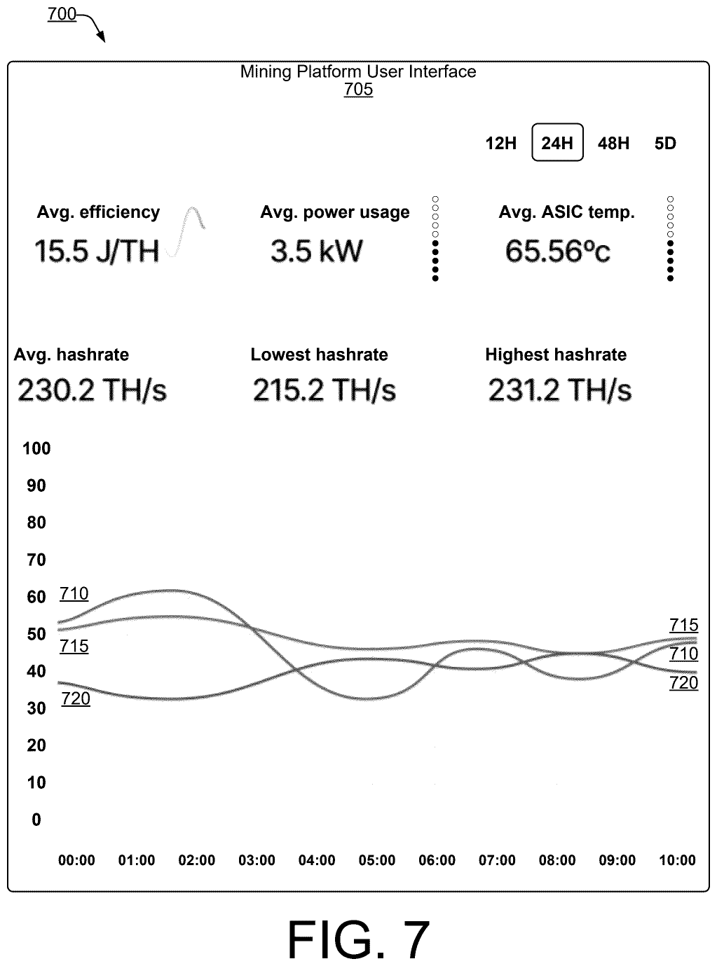

FIG. 6 is a user interface diagram 600 illustrating status information for multiple mining systems on a network. In a mining platform user interface 605 of FIG. 6, the mining systems in FIG. 6 are named M1 610, M2 620, M3 630, M4 640, and M5 650, and the status information includes locations, container(s), and/or whether or not the mining system is connected to a mining pool. The status information is an example of what the first user might see after connecting the new mining system(s) to his or her mining pool. After the first miner is set up, the first user can automatically apply the same configurations to the rest of his fleet or pool. After the first user plugs in their devices, the first user sees there's a dashboard that helps them monitor the mining system(s). An example of the dashboard is illustrated in the mining platform user interface 705 of FIG. 7.

FIG. 7 is a user interface diagram 700 illustrating graphed hashrate (efficiency) over time, and other statistics, for multiple hashboards of a mining system. The different curves on the graph (e.g., curve 710, curve 715, curve 720) in the mining platform user interface 705 represent different mining systems and/or different hashboards of a mining system. The statistics can also include power usage, ASIC temperature, and lowest hashrate, highest hashrate, average hashrate, or a combination thereof.

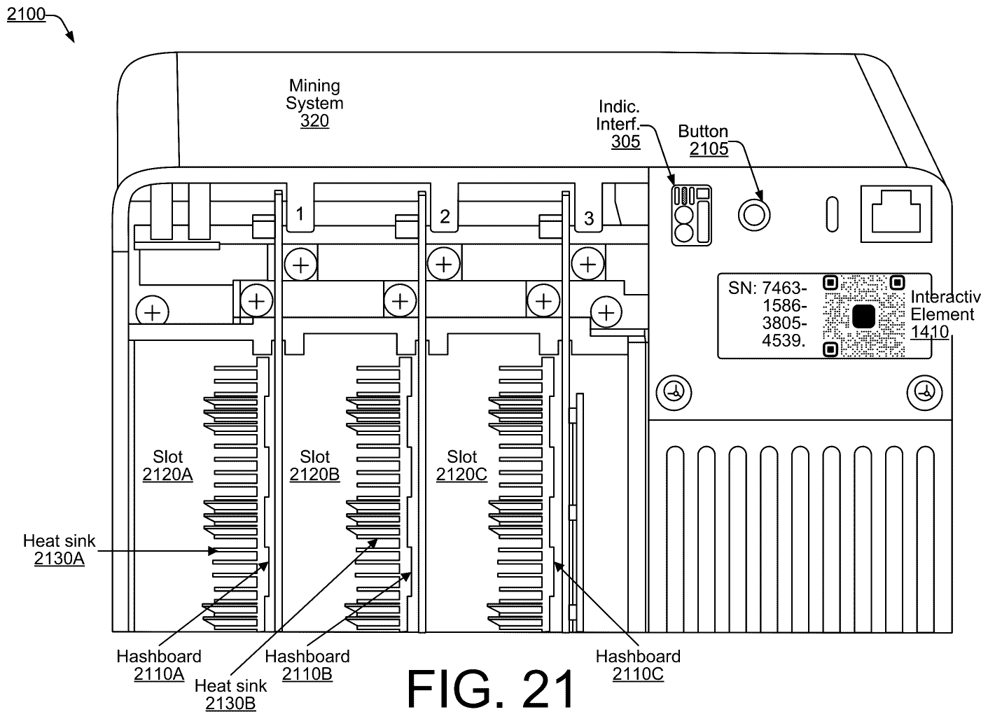

FIG. 8 is a conceptual diagram illustrating a legend 800 for light indicators of an indicator interface of a mining system. Different types of components (e.g., hashboard, fan, control board, and/or power supply) have differently-shaped indicators, and in some cases, differently-colored indicators. The positions of the indicators in the indicator interface 305 can match (or at least be based on) the positions of the components in the mining system. The shapes of the indicators in the indicator interface 305 can match (or at least be based on) the shapes of the components they represent. For instance, in an illustrative example, hashboard issues 810 are indicated in the indicator interface 305 by illuminating one or more of a set of lights shaped like parallel lines, representing parallel hashboards in slots in the mining system 105 (e.g., see hashboards 2110A-2110C in slots 2120A-2120C in FIG. 21). Fan issues 820 are indicated in the indicator interface 305 by illuminating one or more of a set of lights shaped like circles, representing fans (e.g., top fan 310A, bottom fan 310B, top fan 2610A, bottom fan 2610B) of the mining system 105. Control board issues 830 are indicated in the indicator interface 305 by illuminating a light shaped like a square or rectangle, representing a control board (e.g., control board 110, second controller 280, control board 2630) of the mining system 105. Power supply issues 840 are indicated in the indicator interface 305 by illuminating a light shaped like a large rectangle, representing a power supply (e.g., PSU 195, voltage (VDD)) 230, ground (Gnd) 220, PSU 325) of the mining system 105.

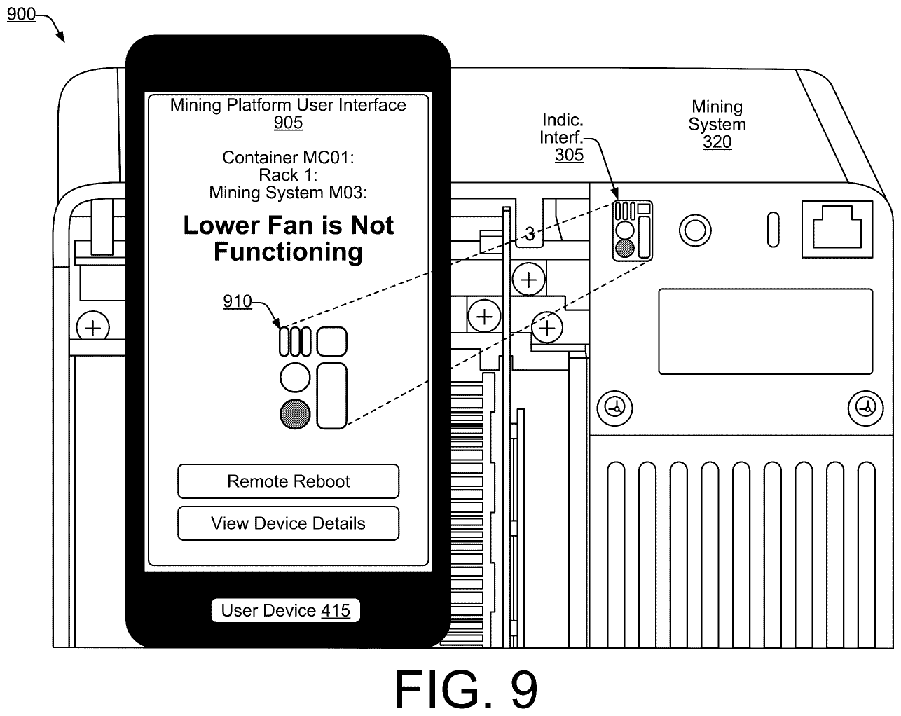

FIG. 9 is a user interface diagram 900 illustrating an alert on a user device indicating that a fan of a mining system is not functioning and providing options to remotely reboot the mining system and/or view details of the mining system. The alert is illustrated in the form of a mining platform user interface 905 displayed on the their user device 415. In an illustrative example, the first user receives an alert to their user device 415 (e.g., phone or other mobile device) that one of their mining rigs has stopped working. The first user fires up a mining system management app and sees that one of their miners' fan has stopped working. The app on the user device 415 includes an indicator interface 910 that mimics what the indicator interface 305 of the mining system 320 is showing, which makes it easy to diagnose issues in person or on the go. For instance, the indicator interface 305 and the indicator interface 910 show fan issues 820 with the bottom fan 310B, based on one of the circular lights representing the bottom fan 310B being lit.

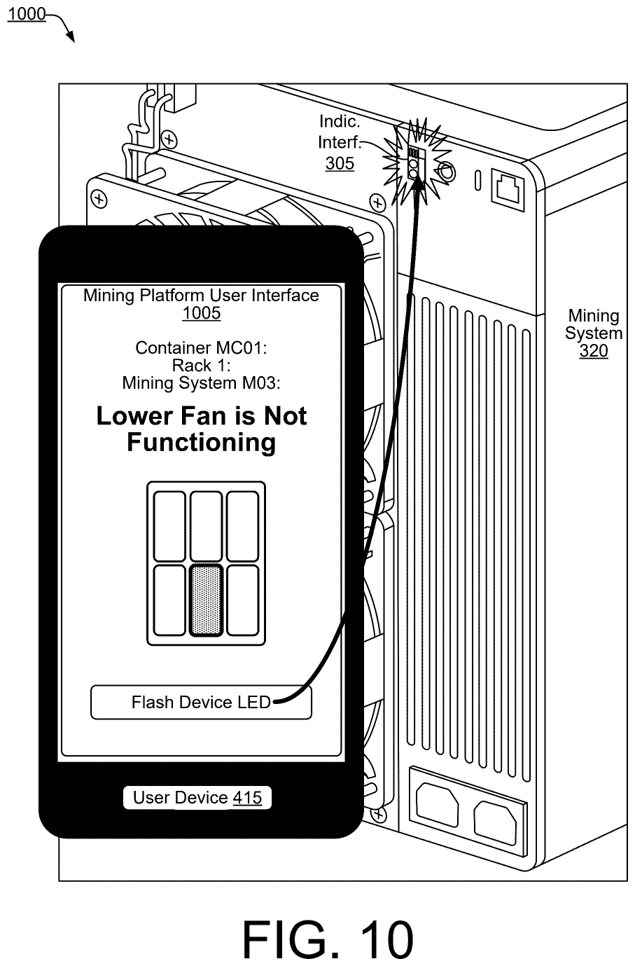

The alert is illustrated in FIG. 9 on the user device 415 of the first user, and identifies that a fan is not functioning. The indicator interface 305 of the mining system is shown, both as part of the mining platform user interface 905 on the user device (e.g., as the indicator interface 910) and a part of the indicator interface 305 on the mining system 320 itself. The alert of the mining platform user interface 905 includes buttons allowing the first user to remotely reboot the mining system and/or view details of the mining system. If the reboot doesn't help, the app can provide instructions for the user to locate, repair, and/or replace the fan, for instance as illustrated in FIG. 10. For instance, if the first user has never fixed the mining device before, the companion app can help the first user every step of the way.

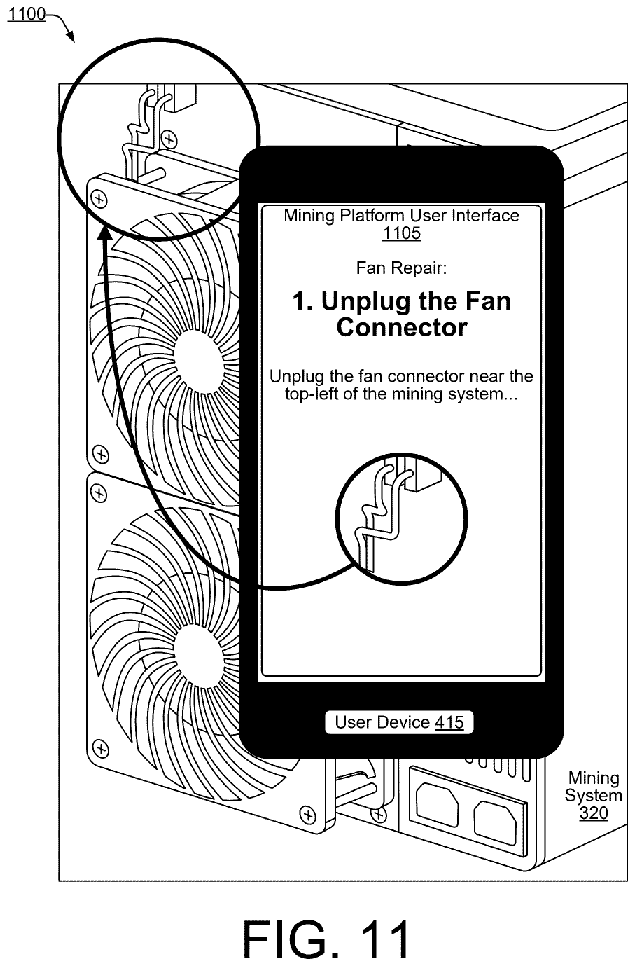

FIG. 10 is a user interface diagram 1000 illustrating an interface (mining platform user interface 1005) on a user device 415 indicating which particular mining device of a set of mining devices on a rack has a non-functional fan, with an indication that light(s) of a light indicator (e.g., the indicator interface 305) of the particular mining device is flashing. The first user can use the app to help find the broken mining system 320. In addition to a map of the mining systems, she can tap a button to instantly flash the lights (e.g., LEDs) of the indicator interface 305 (and/or another light-based interface) on the mining system 320. For instance, the mining platform user interface 1005 in FIG. 10 includes a graphic highlighting which mining system 320 in the rack (e.g., shown as a 3×2 arrangement of six mining systems) is the mining system 320 that has the issue, and can cause the lights of the indicator interface 305 of the mining system in question (e.g., all of the indicator lights or a subset) to illuminate and/or blink in a particular color (e.g., red, orange, yellow, green, blue, purple) to help the first user locate the mining system 320. The app can help the first user repair the fan further as in FIG. 11.

FIG. 11 is a user interface diagram 1100 illustrating an interface (mining platform user interface 1105) on a user device 415 indicating instructions to repair or replace a non-functional fan in a mining system 320. The instructions can include easy-to-read repair instructions for miners. The first user can follow these step-by-step instructions to remove the fans and get the device back online in just a matter of minutes. For instance, the interface in FIG. 11 indicates that one step is to unplug the fan connector.

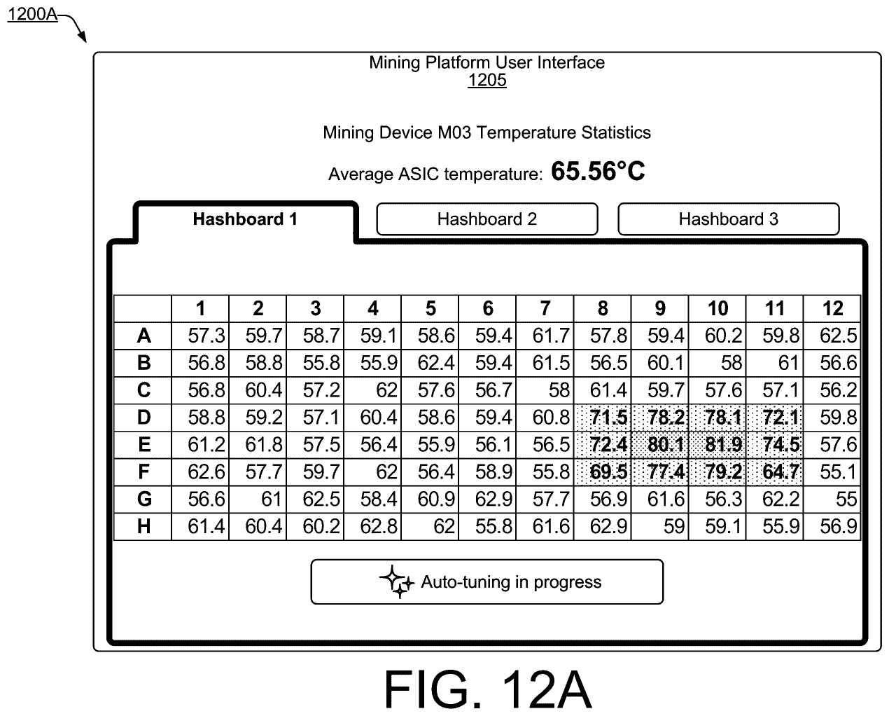

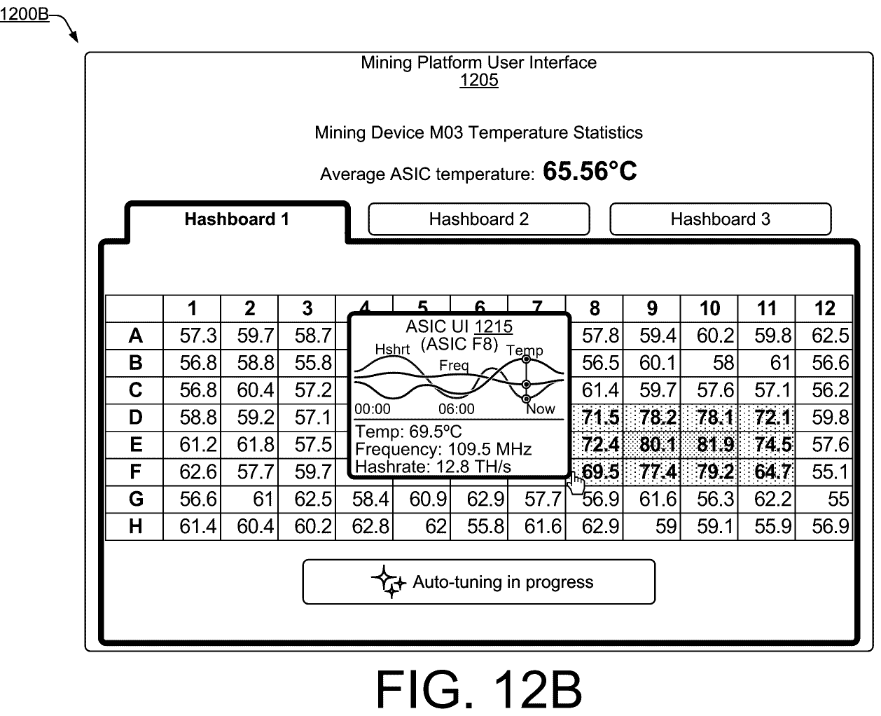

FIG. 12A is a user interface diagram 1200A illustrating an interface (mining platform user interface 1205) on a user device indicating ASIC temperatures for multiple hashboards of a mining system. The mining platform user interface 1205 lets the first user stay in the loop wherever they is, allowing the first user to keep an eye on energy levels and reboot their miners on the go in seconds. The mining platform user interface 1205 shows temperatures of the different mining ASICs of different hashboards (identified as hashboard 1, hashboard 2, and hashboard 3) of the mining systems, for instance. In some examples, the mining systems 320 discussed herein are highly efficient and can auto regulate their own hashrate(s) based on energy needs, thereby reducing energy draw (and thus energy costs) while maximizing mining. The temperatures are illustrated in a table that can mirror the arrangement of the ASICs on the hashboard (e.g., as in the hashing management architecture 200).

The table can be shown as a heatmap. For instance, the cells of a majority of the table of the mining platform user interface 1205 have a white background, indicating temperatures below a threshold (e.g., less than 64 degrees). However, a set of ASICs (from D8 to F11) that have temperatures greater than the threshold but under a second threshold (e.g., exceeding 64 degrees but less than 80 degrees) are shown as shaded in a light shading pattern in the table of the mining platform user interface 1205. Two ASICs (E9 and E10) that have temperatures greater than the second threshold (e.g., exceeding 80 degrees) are shown as shaded in a darker shading pattern in the table of the mining platform user interface 1205. In some cases, different colors (e.g., purple, blue, green, yellow, orange, and/or red) can be used in place of the different shading patterns shown in the heatmap of the table of mining platform user interface 1205.

In some examples, the first user can further integrate the mining systems with a payment service (e.g., Cash App). The first user can thus automatically convert some of their bitcoin into fiat currency, for free, so that they can pay their bills without having to worry about losing money on fees

Compared to a third-party mining system, the mining systems discussed herein can, in some examples, ensure that mining operations are smooth and efficient across multiple mining sites, and to ensure that mining systems are operational and well-maintained. For instance, the mining systems disclosed herein are modular, making it easier to swap out pieces and repair broken miners to lower repair costs, minimize downtime, and reduce the need to replace parts. The mining systems disclosed herein can improve reliability by operating parameters of a distributed grid (e.g., energy grid), for instance based on conditions such as weather, local power draw, and the like. The mining systems disclosed herein feature powerful software that masks complexity, amplifies efficiencies, and ultimately puts control in users' hands. The mining systems disclosed herein are energy-efficient. The mining systems disclosed herein provide control over energy consumption via an AutoTune feature that adjusts energy consumption and/or mining system configuration (e.g., configuration(s) 5336) based on predicted patterns weather, predicted spikes in energy usage locally, and the like.

In some examples, the systems and methods disclosed herein include an interface on a user device (e.g., user device 415) for tracking delivery of, and initiating configuration of, mining systems. In an illustrative example, a second user orders seventy-two mining systems, and uses a dashboard to track his orders and start setup and configuration of the mining systems. While the second user waits for their miners to arrive, the second user starts to get his operation ready for the new miners by setting up locations, containers, and miners. The second user starts with locations and sees suggestions based on their order history.

In some examples, the systems and methods disclosed herein include an interface on a user device for configuring mining locations and/or creating a new mining location. In an illustrative example, an interface can list mining locations, for instance including Embu, Kisumu, Mombasa, and Nairobi. In some examples, such an the interface can show certain locations from this list as having mining systems en route. While the second user waits for their miners to arrive, the second user starts to get their operation ready for the new miners by setting up locations, containers, and miners.

FIG. 12B is a user interface diagram illustrating an interface (ASIC user interface 1215) on a user device with detailed information for a specific ASIC (ASIC F8), overlaid over the interface (mining platform user interface 1205) indicating ASIC temperatures for multiple hashboards of the mining system. For instance, in FIG. 12B, a cursor (representing a user's mouse, touchscreen touch input, and/or hover input) hovers over, clicks on, and/or touches a box representing a particular ASIC (ASIC F8) in the heatmap of the mining platform user interface 1205. An ASIC user interface 1215 for the ASIC F8 appears, overlaid over the mining platform user interface 1205. The ASIC user interface 1215 identifies the current temperature (69.5° C.) of ASIC F8, the current frequency (109.5 MHz) of ASIC F8, and the current hashrate (12.8 TH/s) of ASIC F8. The ASIC user interface 1215 also includes a graph that tracks the temperature, frequency, and the hashrate of ASIC F8 over time.

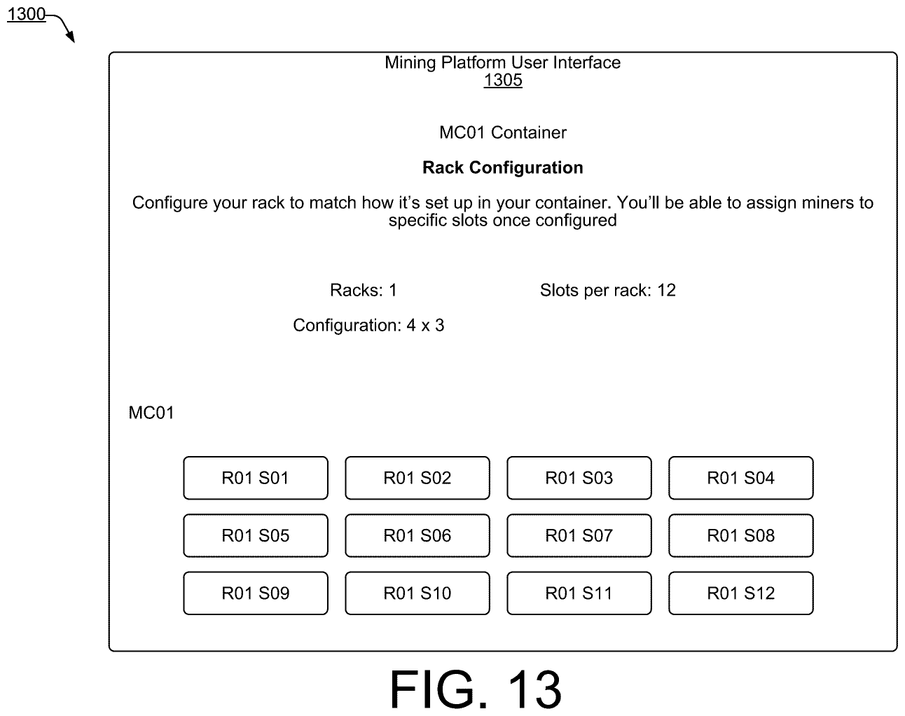

FIG. 13 is a user interface diagram 1300 illustrating an interface (mining platform user interface 1305) on a user device for setting and/or modifying a configuration of a rack of mining systems. The second user adds racks and/or containers to their location. As the second user sets up their containers, the second user configures how many mining systems are in each rack, how many racks are in each container, and how the mining systems, the racks, and the containers are organized. This helps organize the mining systems for the second user and the second user's team to help them easily locate miners down the road. For instance, the interface of FIG. 13 identifies that each rack has twelve slots for mining systems arranged in a 4×3 configuration.

In some examples, the systems and methods disclosed herein include an interface on a user device for setting up, configuring, and/or monitoring mining systems. Now that the second user's racks and containers are set up, the second user starts to configure each miner. The second user is able to bulk configure the cooling and mining pool details for each miner so that the machine only needs to be plugged in to start mining. For instance, an interface can be used to allow configuration and/or tracking of mac addresses, names, mining pools, position(s), and/or cooling systems used (or to be used) for each of the mining systems.

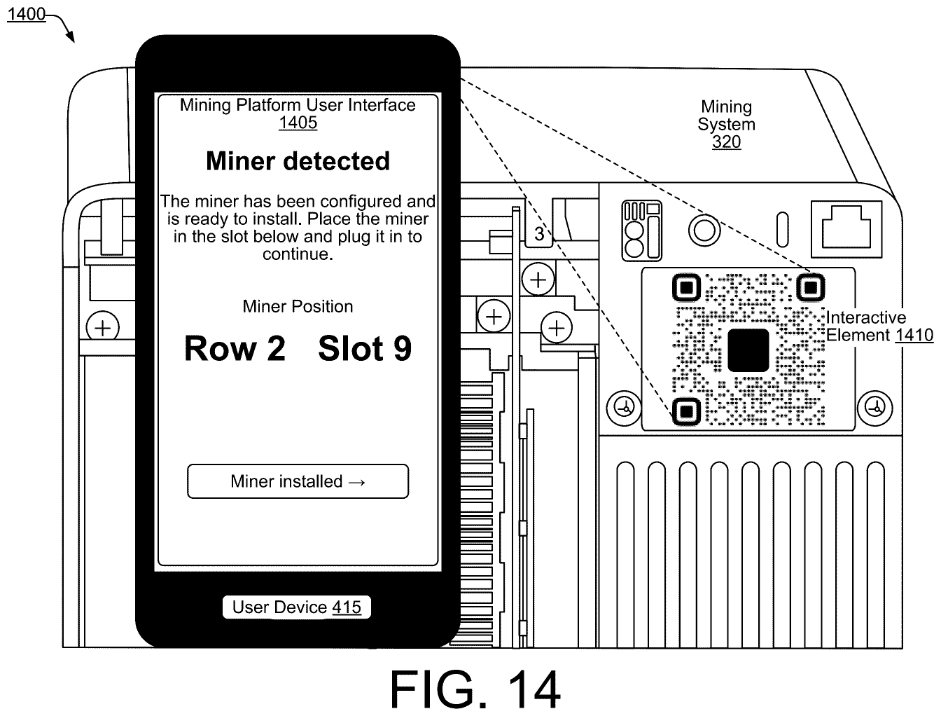

FIG. 14 is a user interface diagram 1400 illustrating an interface (mining platform user interface 1405) initiated based on an interaction between a user device 415 and an interactive element 1410 of a mining system that detects the mining system for installation, configuration, and/or monitoring. Once the mining systems arrive, the second user can install each of the mining system(s) in their assigned position. The second user can scans the interactive element 1410 (e.g., QR code) on the front of the mining system 320 using the camera of the user device 415. The information encoded in the interactive element 1410 (e.g., optically encoded in the QR code) indicates which row and slot the mining system is to be placed into, or links to information (e.g., a webpage or a page in an app) that indicates which row and slot the mining system is to be placed into.

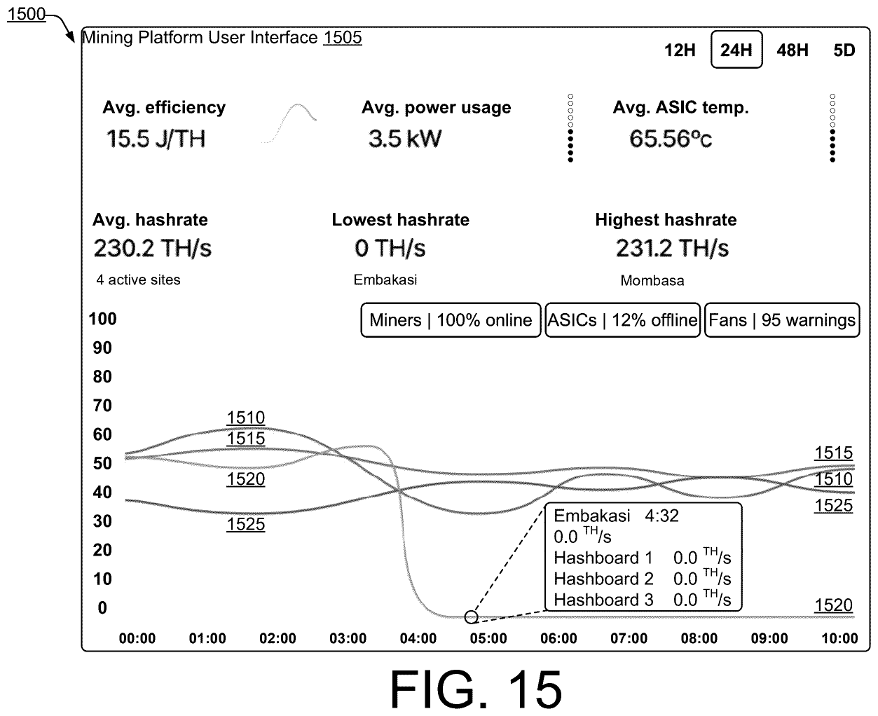

FIG. 15 is a user interface diagram 1500 illustrating graphed hashrate (in TH/s) and/or efficiency (in J/TH) over time, and other statistics, for multiple mining systems. These statistics are shown in a mining platform user interface 1505. The second user, for instance, can track diagnostics for the installed mining systems using the mining platform user interface 1505. Different curves on the graph (e.g., curve 1510, curve 1515, and curve 1520) in the diagram 1500 represent different locations. For instance, the curve 1515 with the highest hashrate (2312 TH/s) represents mining system(s) in the Mombasa location, while the curve 1520 with the lowest hashrate (0 TH/s) represents mining system(s) in the Embakasi location. In an illustrative example, the second user notices that one of their locations-Embakasi, indicated by the curve 1520 on the graph-experienced a drop in efficiency overnight.

The diagram 1500 also includes an alert indicating that the hashrate and/or efficiency of a specific mining system has dropped to zero at 4:32 AM. The second user can click, tap, or hover over the curve 1520 for the alert with more information about the drop in efficiency. The second user notes that the alert identifies that the issue is at the Embakasi site (represented by the curve 1520). The alert indicates that all three hashboards of the mining system in question at the Embakasi site (represented by the curve 1520) have a hashrate of zero TH/s as of 4:32 AM.

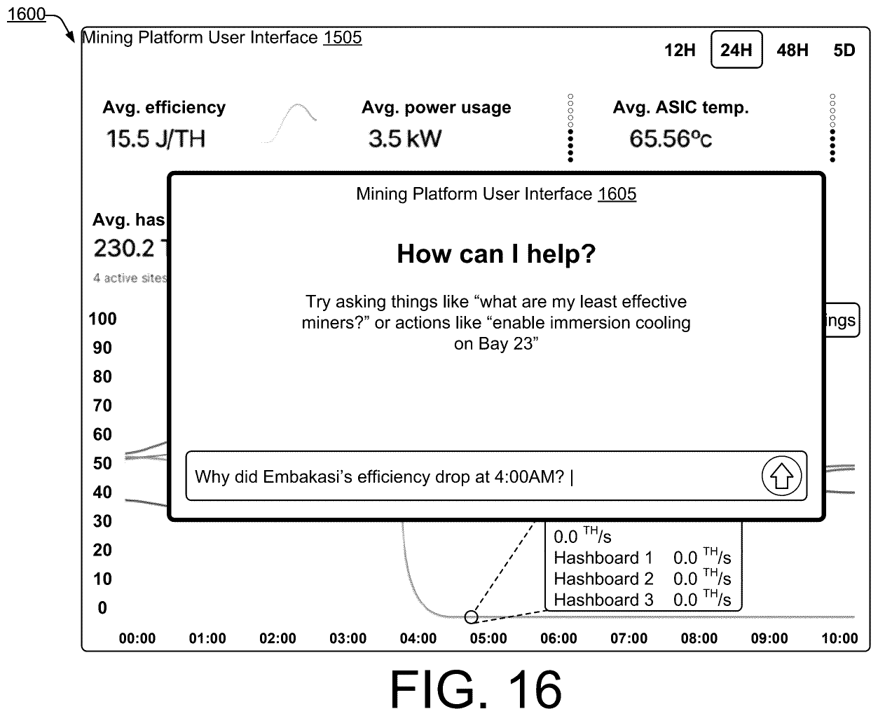

FIG. 16 is the user interface diagram 1600 illustrating the graphed hashrate and/or efficiency over time of FIG. 15, along with a natural language interface (mining platform user interface 1605) through which a user input is received asking for help in troubleshooting the drop in hashrate and/or efficiency of the specific mining system starting around 4:00 AM. The input from the second user is received into the natural language interface (mining platform user interface 1605), for instance asking “why did Embakasi's efficiency drop at 4:00 AM?”

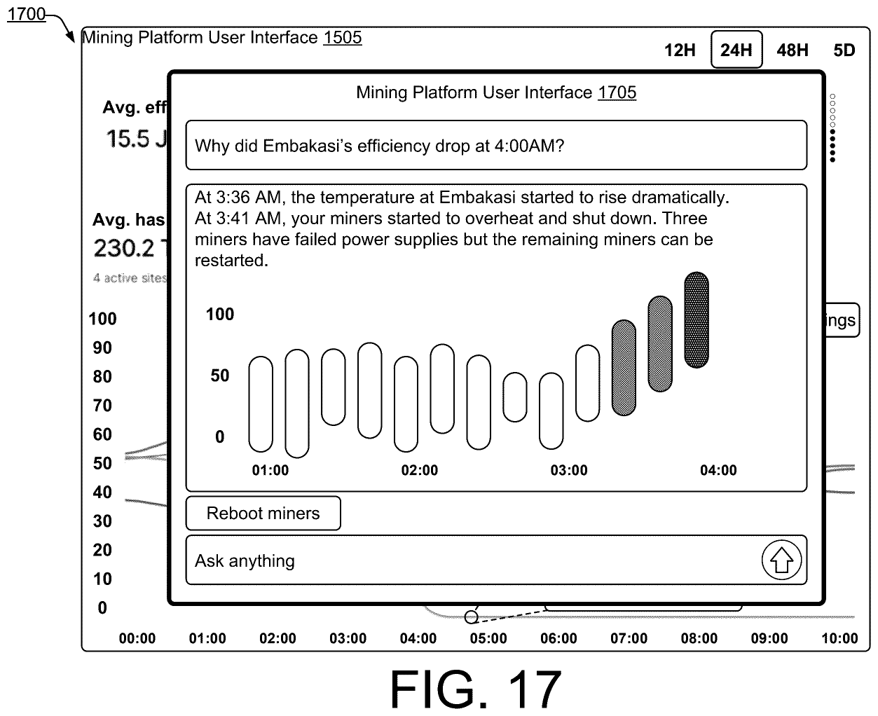

FIG. 17 is the user interface diagram 1700 illustrating the graphed hashrate and/or efficiency over time of FIG. 15 and FIG. 16, along with the natural language interface (mining platform user interface 1705) with a response to the user input indicating a dramatic rise in temperature of the specific mining system starting around 3:36 AM and overheating starting at 3:41 AM. The mining platform user interface 1705 can be an updated version of the mining platform user interface 1605, with a response to the “why did Embakasi's efficiency drop at 4:00 AM?” question. In response to the input to the natural language interface (in the mining platform user interface 1605), the natural language interface (mining platform user interface 1705) responds with the response indicating the dramatic rise in temperature of the specific mining system starting around 3:36 AM and overheating starting at 3:41 AM. The response indicates that three miners have failed power supplies but the remaining miners can be restarted to resolve the issue. This represents a human-centric readout of what happened at the Embakasi site along with contextual actions that help the second user resolve the issue or dive deeper into troubleshooting. The response in the mining platform user interface 1705 can represent an example of issue(s) 5334 and/or alert(s) 5340 identified using ML model(s) 5325. In some example, the response in the mining platform user interface 1705 is generated at least partially using a large language model (LLM) to be conversationally responsive to the question input into the mining platform user interface 1605.

In some examples, the response is generated by one or more trained machine learning (ML) model(s) of the natural language interface, such as one or more large language model(s). In some examples, the trained ML model(s) can retrieve information about the mining systems via retrieval-augmented generation (RAG).

In some examples, the graphed hashrate and/or efficiency over time (as in FIGS. 15-17) can be updated to show that the mining system(s) in Embakasi has/have started back up, for insurance with the curve 1520 gradually increasing in hashrate and/or efficiency to be once again above zero. In some examples, the second user is able to remotely reboot all of their functioning miners in the diagram 1500, and starts to see they're immediately warming up and hashing again as illustrated in the uptick in the curve 1520 after the situation shown in the graph of FIG. 15.

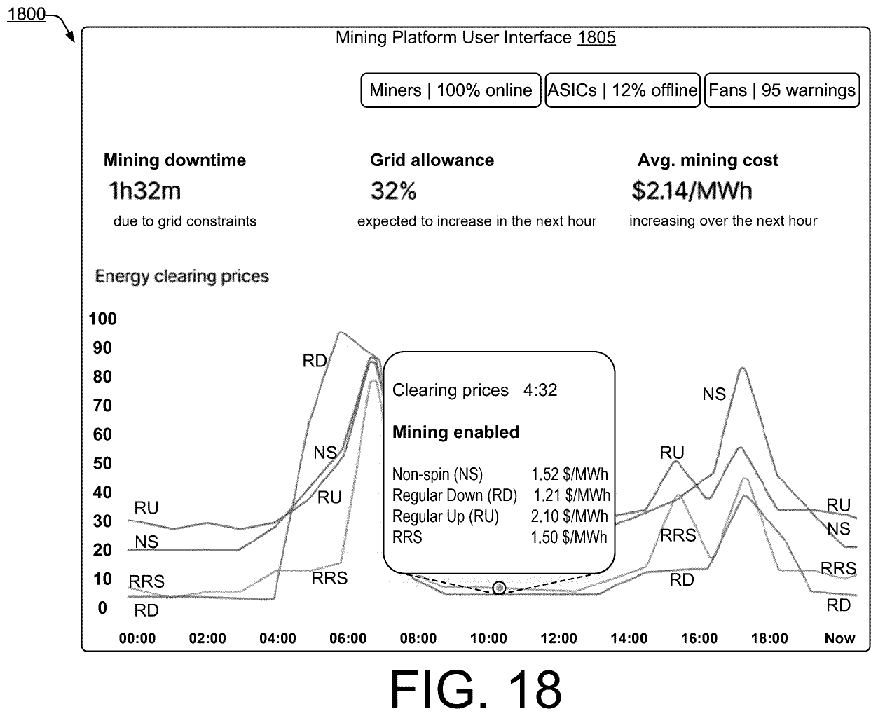

FIG. 18 is a user interface diagram 1800 illustrating graphed energy usage over time, indicators of energy clearing prices, and other statistics, for multiple mining systems. The mining platform user interface 1805 provides statistics for mining downtime due to (e.g., caused by and/or predicted from) electrical grid constraints and any expected or predicted changes thereto, grid allowance and any expected or predicted changes thereto (e.g., expected increase or decrease in a coming time period such as in the next hour), average mining cost (e.g., calculated based on cost of electricity) and any expected or predicted changes thereto, energy clearing prices and any expected or predicted changes thereto, or a combination thereof. In some examples, tracked statistics can include statistics such as hashrate, efficiency, and how many mining systems are up, need attention, are paused, are down, are in repairs, are in deployment, and/or are undergoing maintenance at any time. A notification in FIG. 18 identifies that mining is enabled and provides prices (based on energy prices) for non-spin (e.g., Non-Spinning Reserves (NSRS)), regular down (e.g., spun down), regular up (e.g., spun up), and RRS (e.g., Responsive Reserve Service (RRS)).

In an illustrative example, the second user can use the interface of FIG. 18 to check in on the energy usage in a specific location (e.g., mining facility), such as Imoshoro, before an expected storm. The interface receives data (e.g., directly or indirectly) from the energy grid so the second user can get real time metrics on energy usage alongside their mining performance data.

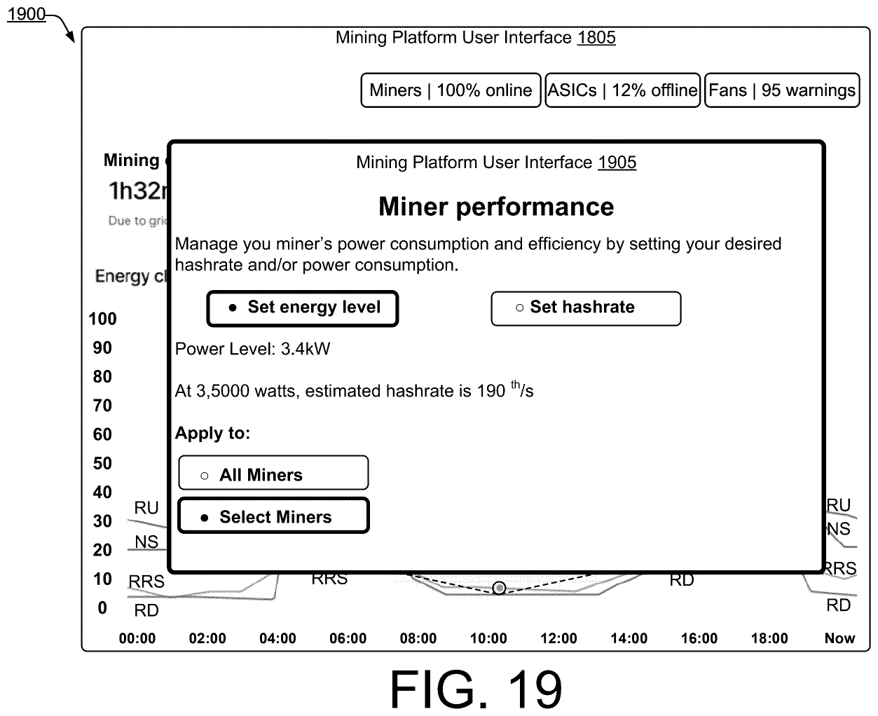

FIG. 19 is the user interface diagram 1900 illustrating graphed energy usage over time, along with an interface to set or adjust a configuration of one or more mining systems (e.g., setting or adjusting energy level, hashrate, and/or other settings). The interface of FIG. 19 includes the mining platform user interface 1805 (with the graphs and statistics) of FIG. 18, with an additional window (mining platform user interface 1905) for setting, configuring, and/or reconfiguring mining performance by mining systems. The energy controls that the second user has access to with the mining platform user interface 1905 enable the second user to easily fine tune their consumption, per miner. This mining platform user interface 1905 provides granularity and fine-tuning capabilities and is a technical improvement over interfaces in which machines can only be turned on or off remotely. For instance, the mining platform user interface 1905 allows for setting, configuring, and/or reconfiguring energy levels and/or hashrates for specific mining systems, groups thereof, and/or components thereof.

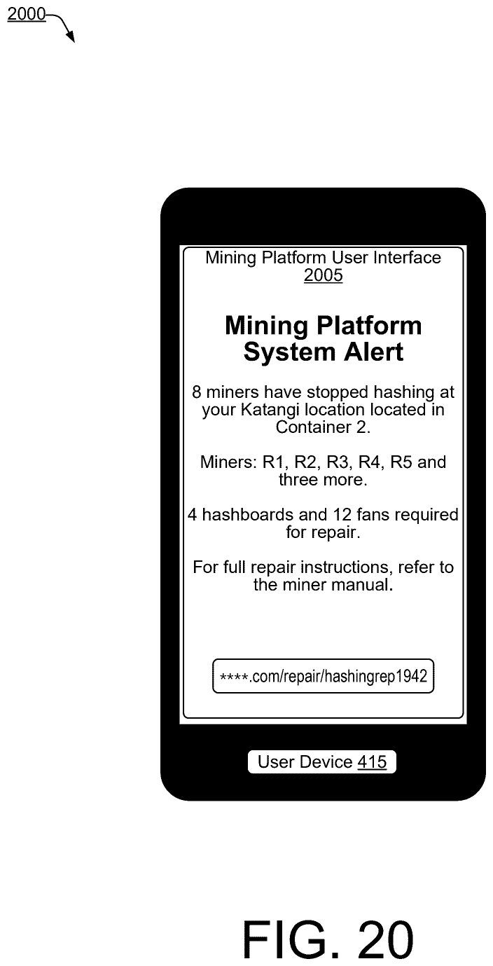

FIG. 20 is a user interface diagram 2000 illustrating an alert identifying that eight mining systems (R1, R2, R3, R4, R5, and three more) have stopped hashing, a location of the eight mining systems (Katangi, Container 2), and components to be repaired (four hashboards and twelve fans). The alert (mining platform user interface 2005) is received at the user device 415 and can help the second user to rapidly stay informed and diagnose and fix issues that the second user sees as they visits remote mining rigs. Because internet connectivity can be inconsistent, the second user can configure the system to send them multiple types of alerts, including SMS, MMS, email, in-app notifications, or combinations thereof. The alert can, in some examples, be the view that is presented to the second user by the app on the second user's user device. For instance, in an illustrative example, the second user checks a less detailed alert (e.g., a text message or email) on their user device 415, taps a link in that alert that opens the app, and sees more details about the miners in the mining platform user interface 2005 of FIG. 20. The mining platform user interface 2005 of FIG. 20 also includes a link to the manual and/or to repair instructions for the mining system(s), which the second user can tap to identify more detailed instructions for how to repair the mining devices, the tools and parts they needs to repair the device, and the like. Because of how remote certain mining systems can be, this information is helpful for the second user to gather parts ahead of time so they can fix multiple miners at once upon arriving at the location(s) of the mining systems. In some examples, the alert (mining platform user interface 2005) of FIG. 20 is an example of the alert(s) 5340.

FIG. 21 is a isometric diagram 2100 illustrating a view of one side of a mining system 320 (.g., a front of the mining device), showing three hashboards (hashboard 2110A in slot 2120A, hashboard 2110B in slot 2120B, and hashboard 2110C in slot 2120C), an indicator interface 305, a diagnostic action button 2505 (e.g., an example of the buttons 135), several ports (e.g., for power and/or network connection(s)), and an interactive element (e.g., QR code). Each of the hashboards 2110A-2110C has a corresponding heat sink on it, with a heat sink 2130A on the hashboard 2110A, a heat sink 2130B on the hashboard 2110B, and a heat sink 2130C on the hashboard 2110C.

As the second user walks through the rack of miners, the second user can easily see the offline rig because of the lights 130 (e.g., LEDs) on the front of the mining system 320 (in the indicator interface 305). The lights 130 (of the indicator interface 305) are designed to indicate what part needs repair, for instance as indicated in the legend 800. In this case, the second user needs to replace the 2nd hashboard 2110B (labeled “2”) in the middle. To indicate this, of the three indicator lights that represent the three hashboards, only the middle indicator light is illuminated in red (illustrated as the middle indicator light being filled in with a shaded pattern), with the other indicator lights illuminated in green (illustrated as the other indicators being filled in with white). The three hashboards 2110A-2110C themselves are also visible in FIG. 21, as circuit boards with heatsinks 2130A-2130C mounted on one or both sides, inserted into slots 2120A-2120C in the housing of the mining system 320. In some examples, the diagnostic action button 2105 (which is one of the buttons 135) can cause the indicator interface 305 to identify which component needs attention (e.g., repair, replacement, maintenance, or another action) via color (e.g., illumination in red or another color), blinking or flashing of the lights of the indicator interface 305, or a combination thereof.

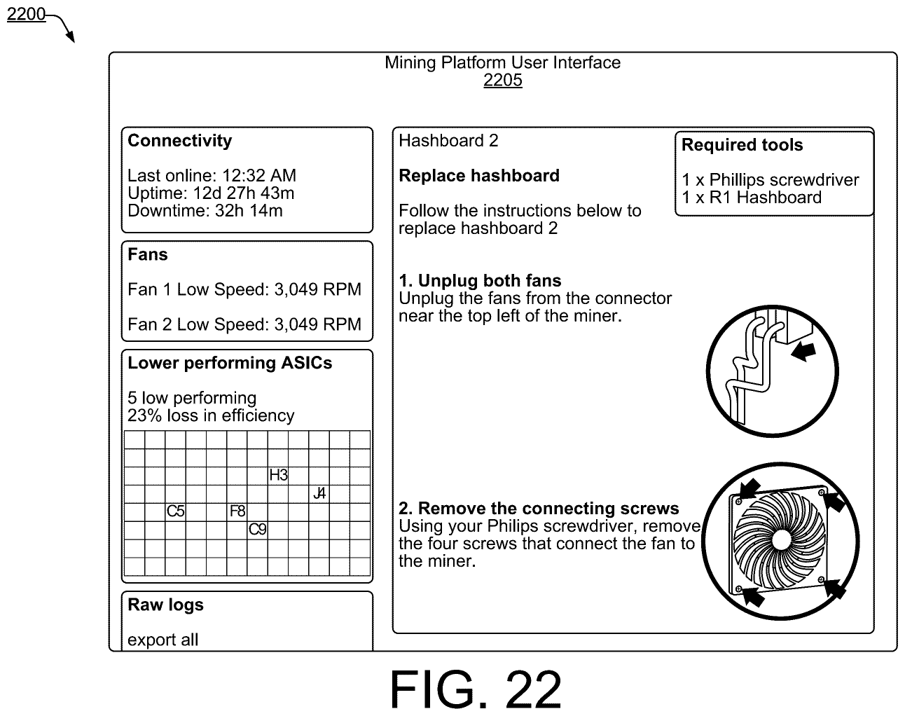

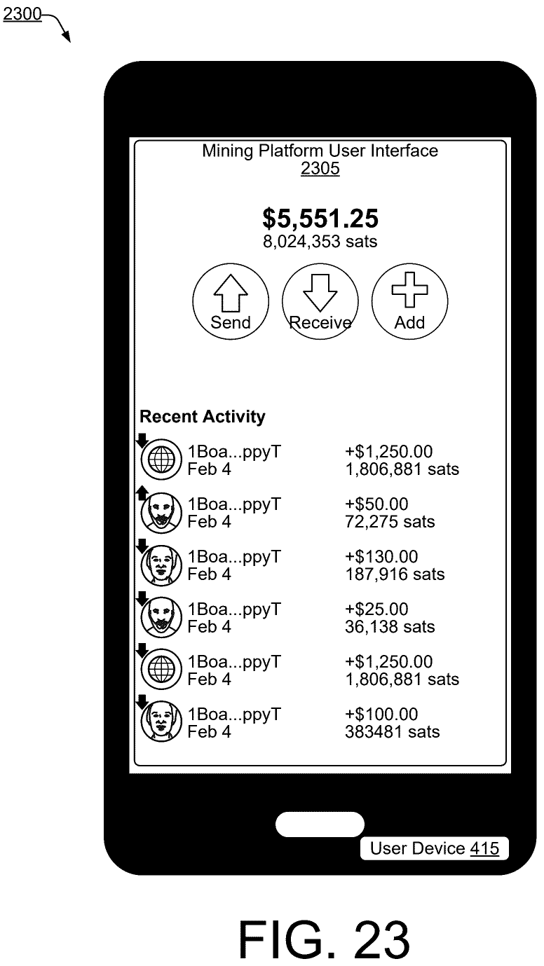

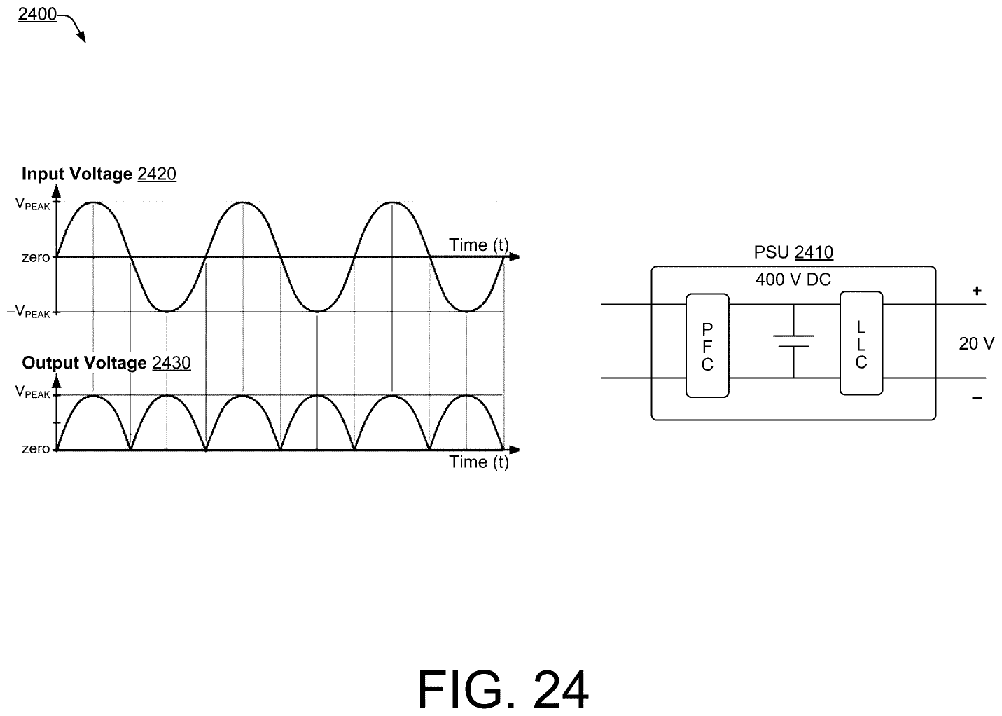

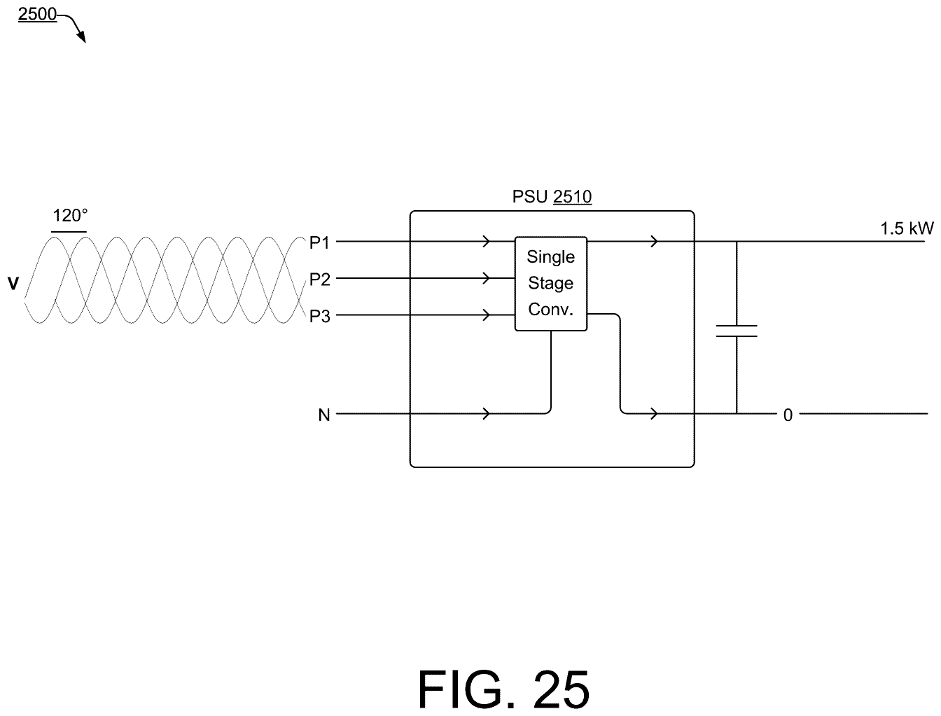

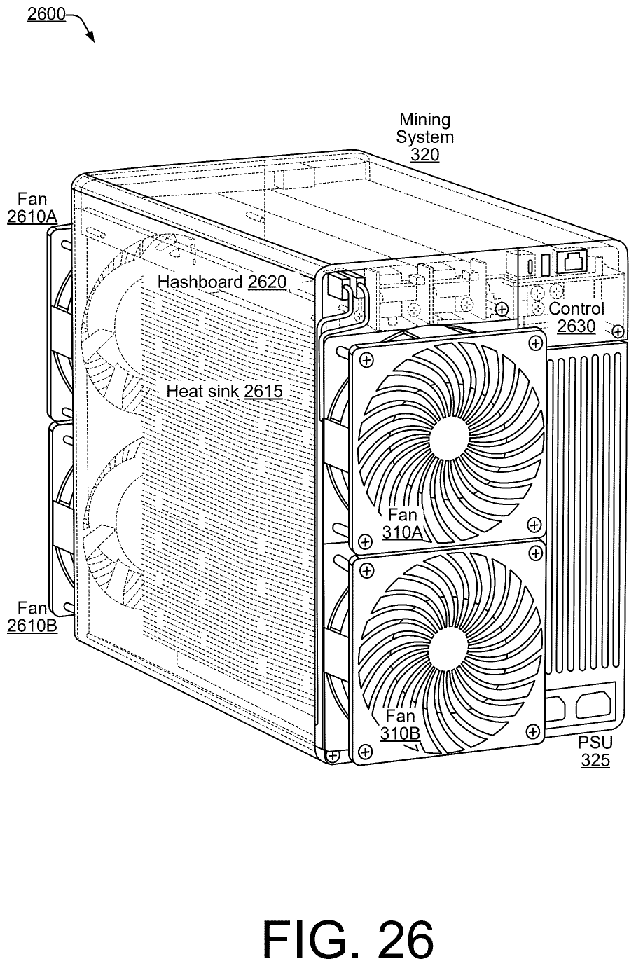

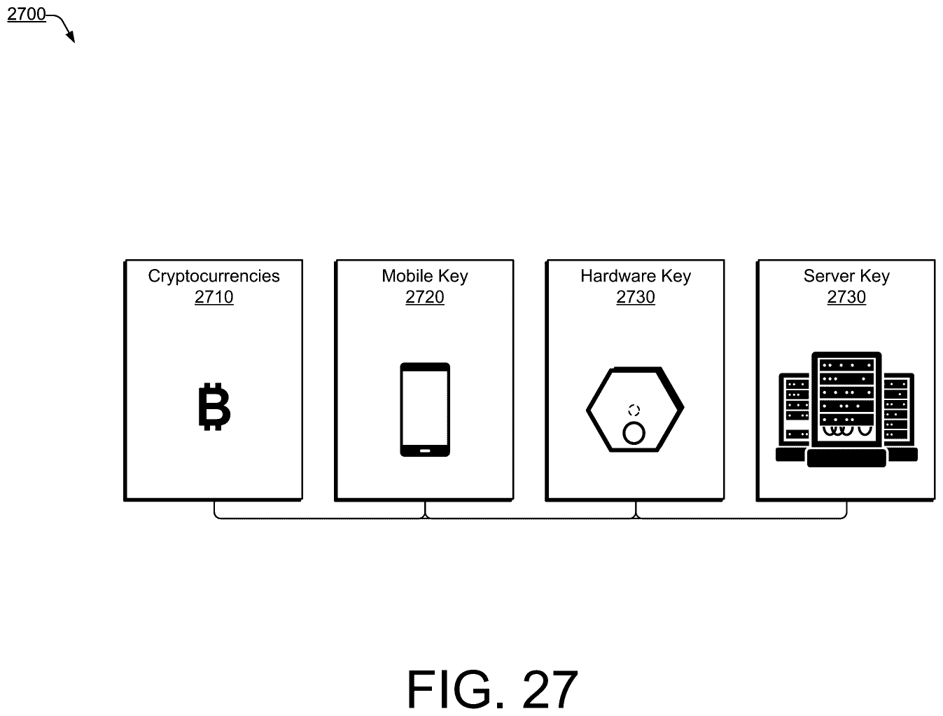

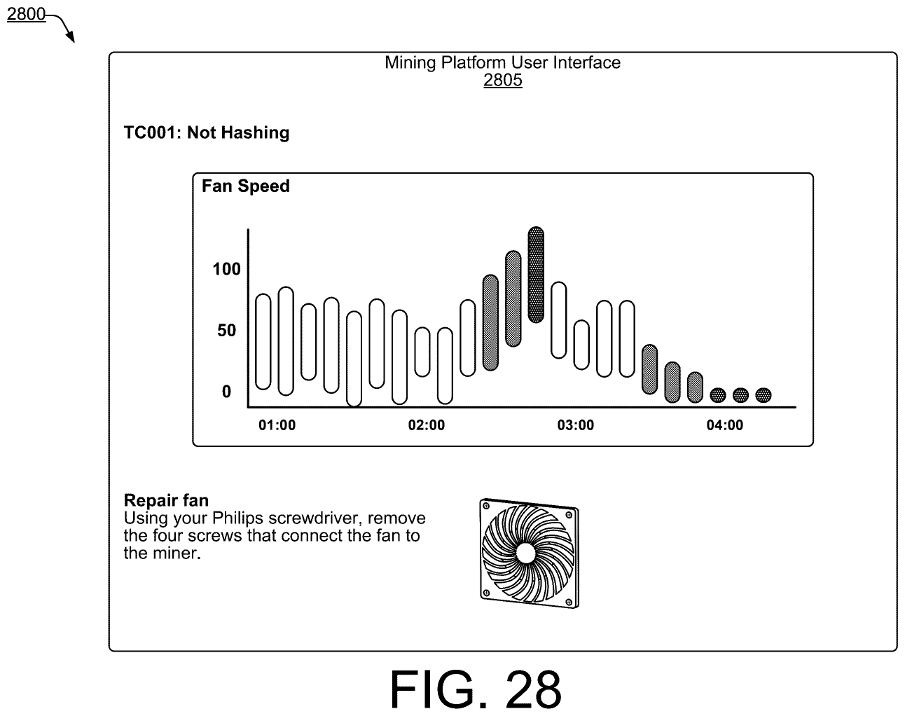

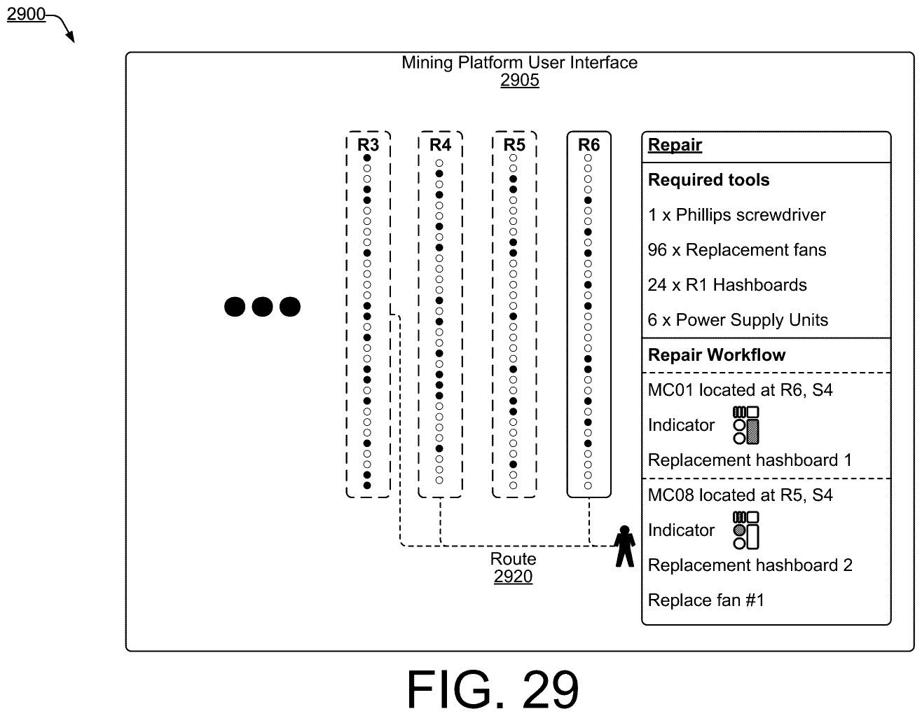

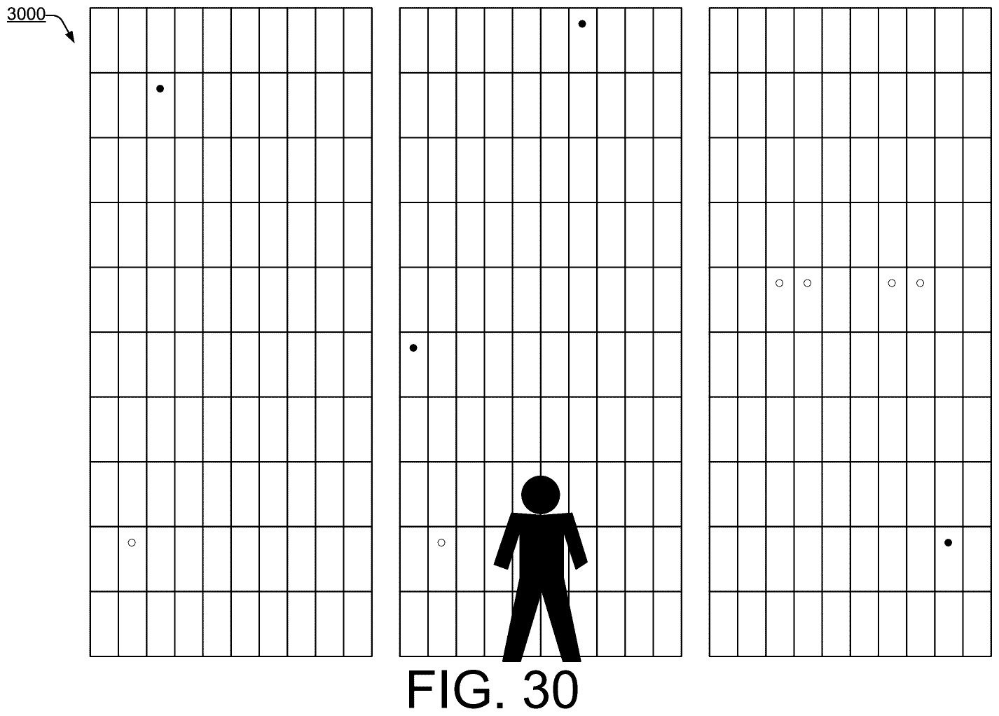

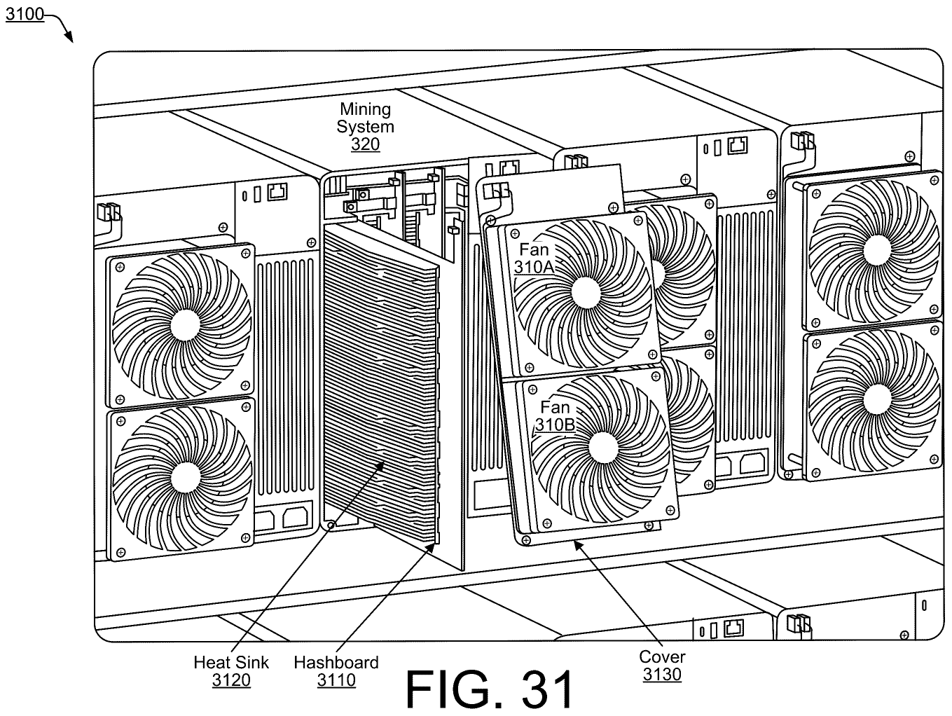

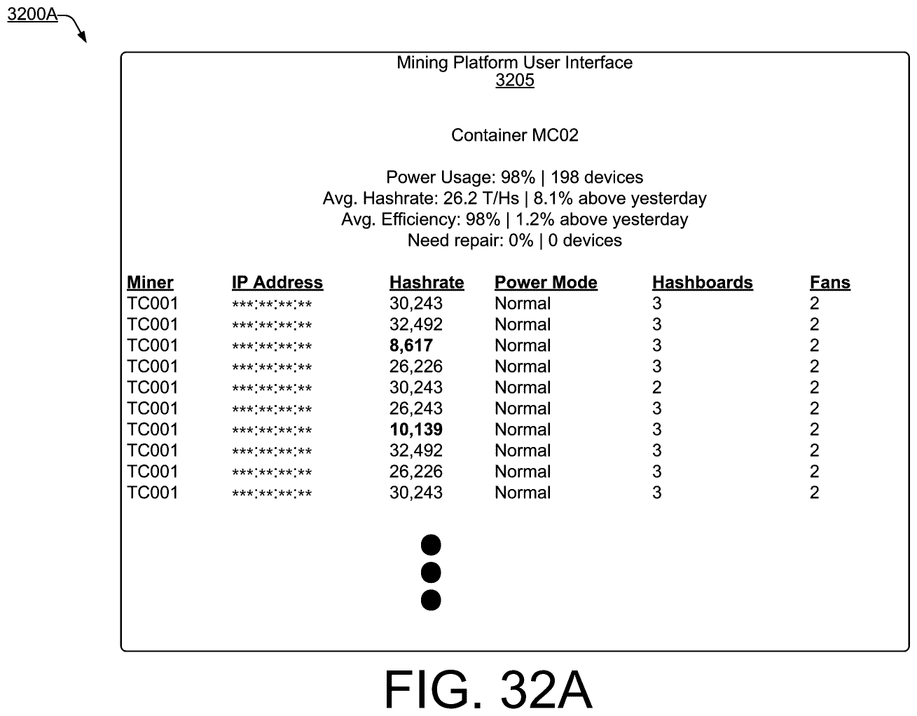

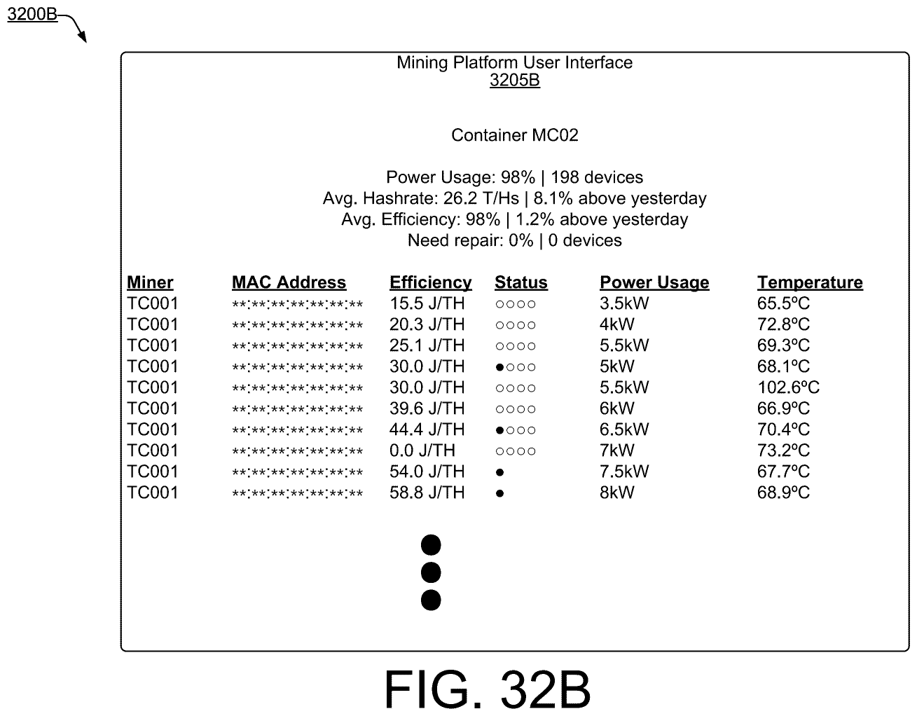

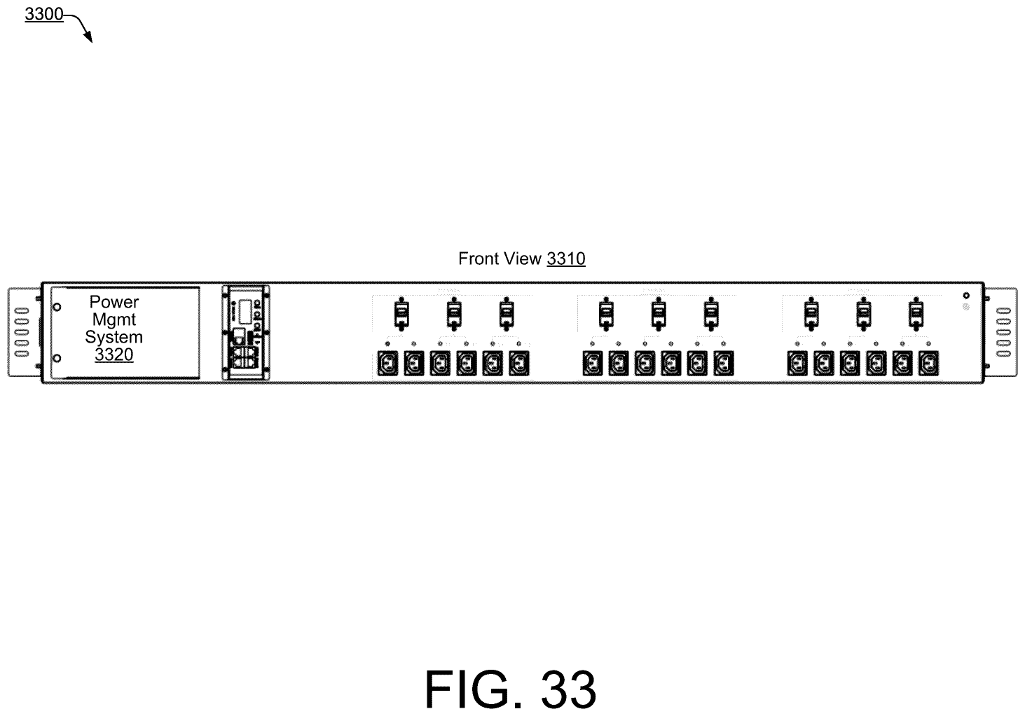

In some examples, the side of the mining system 320 that is illustrated in FIG. 21 can be the front of the mining system, facing the user while the user faces the mining system 320 that is mounted on the rack. In this way, the hashboards 2110A-2110C or other components can be easily removed from the slots 2120A-2120C, like books on a bookshelf. This also help the mining systems 320 themselves to be more easily removed from the racks and/or installed on the racks in an easy and convenient way, also like books on a bookshelf. In some examples, the second user can scan the interactive element 1410 (e.g., QR code) of the mining system (or otherwise interact with the interactive element 1410 of the mining system) to access more information about the mining system 320 and/or any tasks needed to repair, replace, or perform maintenance on any component(s) of the mining system 320, as in the interface (mining platform user interface 2205) of FIG. 22.

FIG. 22 is a user interface diagram 2200 illustrating an interface (mining platform user interface 2205) with instructions for replacing a hashboard, along with various mining system statistics. In an illustrative example, the second user scans the QR code on the mining system of FIG. 21. After scanning the interactive element 1410 (e.g., QR code) illustrated in FIG. 21 with a user device (e.g., user device 415), the second user sees (e.g., on the user device 415) the mining platform user interface 2205 showing diagnostics and details about the mining system 320. The mining platform user interface 2205 presents at-a-glance information around what components are underperforming along with simple steps to repair the mining system 320 via the interface of FIG. 22. For instance, the mining platform user interface 2205 shows the second user how to unplug and remove both fans before replacing the defective hashboard 2110B, identifies what tools are required for the repair, and identifies statistics. The statistics include last offline, uptime, downtime, fan speeds, which ASICs have low performance (e.g., below a threshold) (e.g., ASICS C5, F8, C9, H3, and J4), a percentage loss in efficiency (e.g., due the low-performing ASICs and/or the defective hashboard).

In some examples, the mining systems disclosed herein (e.g., mining system 320) provide reliability, for instance being designed to withstand dust and harsh conditions and to be easy to repair in the rare case they do need to be fixed. The mining management system disclosed herein (e.g., including the various mining platform user interfaces disclosed herein) not only lets users (e.g., the first user or second user disclosed herein) stay on top of their operations from anywhere in the world, but also give users unprecedented control of every container, miner, and chip. The packaging and shipping processes disclosed herein allow the mining systems to be shipped in a more cost efficient way greatly reduces users' overall operational costs. In some examples, off-grid miners who are focused on stranded energy, can configure an entire mining rig from that includes miners, computers, and so forth, all packaged in a highly durable and secure container.

FIG. 23 is a user interface diagram 2300 illustrating an interface for making payments (e.g., based on cryptocurrencies mined using the mining systems). In an illustrative example, the second user uses a payment service's payroll capabilities in conjunction with the mining pool to send and/or receive cryptocurrency amounts (e.g., bitcoin amounts), and/or fiat currency equivalents, directly to their employee's accounts and/or cryptocurrency wallets on a regular cadence (e.g., every month). In some examples, the cryptocurrency wallets can be secured using key devices, such as Bitkey® devices, such as those illustrated in FIG. 27.

FIG. 24 is a circuit diagram 2400 illustrating a potential power supply unit (PSU 2410) architecture with correction units. In an illustrative example, the PSU 2410 includes one single-phase 200-240V, and 4500 W power supply that converts incoming mains (input voltage 2420) (e.g., single phase power) into a low voltage, high current power rail (output voltage 2430) (e.g., 20V or 3 KWcurrent) to be used by 3 hashboards. But, in such a mechanism, the power (e.g., in the output voltage 2430) drops to zero at various points, thus failing to provide power at all times. To solve this, an energy storage subsystem (e.g., one or more batteries and/or capacitors) stores the energy during the “low” times, with the energy storage subsystem (e.g., the one or more batteries and/or capacitors) also being powered by several inductors. The power factor correction (PFC) converter converts the AC into 400 V smooth DC, and an inductor-inductor-capacitor (LLC) converter converts to 20V. For three phases, there is lost opportunity and several components needed for each phase to provide smooth power. However, in some examples, the single-phase nature of the PSU results in extra costs related to energy storage and PFC stage sizing. The PSU 2410 can be an example of the PSU 195.

FIG. 25 is a circuit diagram 2500 illustrating a PSU 2510 architecture for hashboards with a smaller footprint than traditional PSUs. The PSU 2510 architecture can solve the power imbalance issues with a three phase supply, in accordance with some examples. In an illustrative example, a software component can dynamically pull the power based on the balance. In another illustrative example, each hashboard has an embedded, on-board power supply with appropriate certifications where the power supply unit operates on three phase power (where voltage is never zero). In some examples, the PSU 2510 is a 3-phase (ex: 415 VAC) nominal input natively at 1500 W. This removes or reduces the need for PSU energy storage and removes or reduces the Power-Factor-Correction (PFC) conversion stage, making PSU ˜50% smaller and/or cheaper on a size and/or power basis. The nature of the hashboard allows further cost savings by using the PCB heavy copper as the transformer windings (planar transformers). In some examples, the power supply coupled to the hash board (either on the hashboard or connected communicatively) results in about 95% efficiency in a single stage power supply, which represents an improvement in efficiency compared to traditional PSUs. Further, the PSU fans in traditional embodiments are eliminated: the main fans now cool the power supply components as well as the ASICs. This improved PSU 2510 and configuration provides improved flexibility, since any amount of hashboards in a rack can be powered directly by 415 VAC 3-phase without any power imbalance. In this manner, there is continuous power, and the PSU 2510 can be attached to the hashboard (or another portion of a mining system) or assembled on top of the hashboard (or another portion of a mining system) in a modular way. In some examples, the PSU 2510 can generate continuous power through a 3-phase system by essentially staggering the 3-phase input to generate a smooth output. In some examples, the PSU 2510 also gets rid of the multiple capacitors and/or inductors in single phase PSUs such as the PSU 2410, shrinking the PSU 2510 relative to the PSU 2410 and allowing the PSU 2510 to be put on the hashboard itself, in some cases.

The PSU 2510 can be an example of the PSU 195.

FIG. 26 is an isometric diagram 2600 illustrating a mining system 320 with a housing through which internal components are visible. The housing is used to illustrate components of the mining system 320 that might otherwise be hidden by the housing, such as a heat sink 2615 on the surface of a hashboard 2620 that is within the mining system 320. The hashboard 2620 an example of one of the hashboards 155. A control board 2630 is also visible through the housing of the mining system 320. The control board 2630 may be an example of the control board 110. In some examples, the housing of the mining system 320 is at least partially transparent or translucent in at least some areas to help a user see any potential issues within the mining system 320, such as dust accumulating within the mining system 320. In some examples, the housing is at least partially opaque in at least some areas.

As shown in FIG. 26, in some examples, a mining system may include an anterior set of fans (e.g., top fan 310A, bottom fan 310B) and a posterior set of fans (top fan 2610A, bottom fan 2610B).

FIG. 27 is a block diagram 2700 illustrating a multi-key system for accessing a cryptocurrency wallet. For instance, a user's cryptocurrencies (e.g., Bitcoin) can be protected by a combination of a mobile key 2720 (e.g., on the user device 415, a phone, and/or other type of mobile device), a hardware key 2730 (e.g., a BitKey® or key on another type of hardware wallet device), a server key 2730 (e.g., on a server associated with a payment service), or a combination thereof. This combination of keys can help keep the user's cryptocurrencies 2710 safe.

In some examples, the systems and methods disclosed herein include an interface for mapping a set of mining systems across a mining facility. In an illustrative example, a third user orders a set of mining systems (e.g., mining system 320). When the mining systems (e.g., mining system 320) arrive onsite, the third user and their team unbox the crate of miners. The third user can preconfigure the miners with their rack positions, per the third user's desired specifications, so each palette is organized by installation location. This makes it easy for the third user and their team to wheel dozens of mining systems (e.g., mining system 320) at a time and install them in a breeze. After they've been installed, the third user needs to confirm the physical location of every mining system (e.g., mining system 320) in the mining facility. After entering the rack ID, the third user walks down the aisle of mining systems (e.g., mining system 320), scanning the on-device interactive elements 1410 (e.g., QR codes) as they go.

In some examples, the systems and methods disclosed herein include an interface for mapping racks of mining systems across the mining facility. Once all racks have been scanned, an interface can create and show a digital mapping for the third user and their team. This mapping is accessible on the dashboard and helps the third user's technicians easily locate devices when they need repair.

In some examples, the systems and methods disclosed herein include an interface for monitoring statistics and configurations for multiple mining systems. In an illustrative example, the third user can be doing daily diagnostics, and can see, through such an interface, that one hundred and twenty-three of their miners have stopped hashing. One hundred and twenty-one of those are their old third-party mining devices, and two are the new mining systems that the third user installed more recently.

In an illustrative example, an interface may show an alert indicating that a third-party miner stopped hashing thirty-two minutes ago. When the third user goes to diagnose what's happening with his old third-party mining devices, all they can see is that the old third-party mining devices aren't hashing. This is because older third-party devices can only provide transient notifications on devices over the air. To see a full log of errors, the third user needs to plug directly into the device or load up a secure digital (SD) card with historical logs. On the other hand, the mining systems disclosed herein can automatically provide, and update, logs of information in real-time (or near real-time) as the mining systems operate.

FIG. 28 is a user interface diagram 2800 illustrating an interface (mining platform user interface 2805) for monitoring statistics and configurations for multiple mining systems, including an alert indicating that a specific mining system is not hashing, tracking fan speed over time for the specific mining system, and identifying how to repair the specific mining system. When the third user goes to diagnose some of the newly installed mining systems, the third user is relieved because they can see both diagnostic data about the mining system's historical performance (e.g., fan speed, hashrate, efficiency) as well as repair instructions, all in the mining platform user interface 2805 and/or related interface(s).

FIG. 29 is a user interface diagram 2900 illustrating an interface (mining platform user interface 2905) for monitoring statuses of large numbers of mining systems, and identifying tools and workflows for repairing one or more of the mining systems. Now that the third user has a sense of what needs to be done, they starts a repair and sees that the new mining systems are helping their team move faster by anticipating their needs. The mining platform user interface 2905 of FIG. 29 shows an optimized route 2920 for repairs, based on what needs fixing, along with how many fans and hashboards the third user needs to bring out from inventory to complete the repairs.

FIG. 30 is a diagram 3000 illustrating a user standing in front of racks of mining systems, with indicator interfaces of specific mining systems being illuminated to alert the user about the specific mining systems. For instance, the user shown in FIG. 30 can walk up to the first rack, and can easily locate the miner that the user needs to fix first by using the device's lights 130 (e.g., indicator interface 305). Some of the lights are shown as a white circle, for instance representing one color that can represent one type of issue (e.g., hashboard issues 810, fan issues 820, control board issues 830, or power supply issues 840). Some of the lights are shown as a black circle, for instance representing one color that can represent another type of issue (e.g., hashboard issues 810, fan issues 820, control board issues 830, or power supply issues 840).

In some examples, the systems and methods disclosed herein include an indicator interface of a specific mining system (within a rack of mining systems) indicating a status of the specific mining system. By simply removing the front cover, the third user able to swap out the PSU, reboot the machine, and confirm that the device is up and running.

FIG. 31 is a diagram 3100 illustrating a removal of fans and a hashboard from a mining system (e.g., as part of a repair or component replacement). The third user then goes to another set of mining system that require their hashboards to be replaced, including the mining system 320. Because of how the mining systems (including the mining system 320) are designed (e.g., with the fans 310A-310B, hashboards, and/or other components accessible from the front and facing the user while the mining systems are mounted on the rack), the third user can take the front plate cover 3130 off (e.g., with a screwdriver), remove a hashboard 3110 (with its heat sink 3120), and replace the hashboard 3110 with a new hashboard, all while the mining system 320 is still on the rack. The hashboard 3110 is an example of the hashboards 155 and/or the hashboards 2110A-2110C.

In some examples, the systems and methods disclosed herein include an indicator interface (e.g., indicator interface 305) of a specific mining system (within a rack of mining systems) using a light color (e.g., red) to indicate a status of the specific mining system. The third user sees that one of the mining systems needs a closer inspection based on the lights in the indicator interface 305 being lit up in a specific color (e.g., red, orange, yellow, green, blue, or purple) to represent a specific issue, so they lifts it off of the rack to take it back to the lab. The handle is cool to the touch even though it was recently hashing and makes it easier to lift the rig off the rack. In some examples, the user pressing a button (e.g., buttons 135, diagnostic action button 2105) on the mining system 320 changes the indicator interface 305 from being all illuminated in a single color (e.g., to make finding the issue from a distance in a large array of mining systems easier) to illuminating a more detailed lighting pattern representing specific issues, as in the lighting patterns illustrated in the legend 800 of FIG. 8.

FIG. 32A is a user interface diagram 3200A illustrating an interface (mining platform user interface 3205A) for monitoring statistics and configurations for multiple mining systems. After the third user is finished with the repairs, they sees that his container is fully operational and there are no outstanding repairs, for instance via the mining platform user interface 3205A of FIG. 32A. This is a stark difference from when they used the older third-party machines where repairs would take days. For each mining system, the mining platform user interface 3205A identifies a type or model of the mining system (e.g., “TC001”), an IP address of the mining system, a hashrate of the mining system, a power mode of the mining system, a number of hashboard of the mining system, and a number of fans of the mining system. The mining platform user interface 3205 highlights two of the hashrates with bold text based on those hashrates being below a threshold (e.g., below 15,000 TH/s).

In some examples, the systems and methods disclosed herein include an interface for monitoring statuses of multiple mining ASICs in a grid-based interface based on the grid-based arrangement of the mining ASICs in a hashboard (e.g., as in the mining platform user interface 1205 of FIGS. 12A-12B). The broken hashboards can be sent back to the control lab where a technician can connect directly to the hashboard and see the problematic ASICs, for instance via a user interface like the mining platform user interface 1205. Instead of individually testing every ASIC chip, like is done with older third-party hashboards, these hashboards have labeled ASIC coordinates for easy wayfinding.

In some examples, the systems and methods disclosed herein include an interface identifying release of a firmware update for the mining systems. The third user receives a message via a user interface about a new firmware update. The message can indicate that the firmware update improves the hashrate, reduces fan reliability issues, or otherwise fixes issue(s) and/or improves performance of the mining system. The update notes can include test results from real-world testing.

In some examples, the systems and methods disclosed herein include an interface for monitoring statuses of firmware updates for multiple mining systems. The third user is able to test the firmware on a few devices (mining systems) by installing the update from a dashboard interface. After the third user successfully confirms that the new firmware indeed hits all the advertised metrics, they goes to the dashboard and updates the firmware for the rest of the miners remotely.

Cryptocurrency mining systems (e.g., Bitcoin miners), regardless of their size or complexity, share a few core painpoints: purchasing, logistics, total cost of ownership, and control. Miners also have unique needs. Operators who use miners need tools that are straightforward, simple, and effective, such as the tools disclosed herein. Such tools can help give them time back and provide accuracy and reliability at scale, and can anticipate needs at scale to reduce inefficiencies.

Traditional third-party mining systems suffer from infrastructure constraints and are not optimized for density. They have an inefficient electrical design, are not immersion optimized, and are not optimized for companies that build infrastructure.

Rackspace density is dictated by mining system designs. However, now that racks are standardized, the sizes of mining systems should fit in the spots in the racks. The mining systems disclosed herein fit in the spots on such racks.

FIG. 32B is a user interface diagram 3200B illustrating an interface (mining platform user interface 3205B) for monitoring additional statistics and configurations for multiple mining systems. The mining platform user interface 3205B is a variant of the mining platform user interface 3205A that includes different information than what is shown in the mining platform user interface 3205A, As discussed above, the information that the mining platform user interface 3205A identifies for each mining system includes IP address, hashrate, power mode, number of hashboards, and number of fans. The information that the mining platform user interface 3205B identifies for each mining system includes MAC address, efficiency, status, power usage, and temperature.

The status indicator indicates which mining systems are functioning properly, and/or which components of each mining system are functioning properly. For instance, the first, second, third, fifth, sixth, and eighth mining systems each have an indicator with four white circles, indicating that all components of these mining systems are functioning properly. The ninth and tenth mining systems each have an indicator with one black circle, indicating that these mining systems are not functioning properly as a whole. The fourth and sixth mining systems each have an indicator with one black circle and three white circles, indicating that for these mining systems, one component (or type of component) is not functioning properly, but that three other components (or types of components) are functioning properly. For instance, in a first illustrative example, the status indicator for the fourth and sixth mining systems (with one black circle and three white circles) can indicate that, for each of these mining systems, three hashboards are functioning properly, and one hashboard is malfunctioning. In a second illustrative example, the status indicator for the fourth and sixth mining systems (with one black circle and three white circles) can indicate that, for each of these mining systems, three fans are functioning properly, and one fan is malfunctioning. In a third illustrative example, the status indicator for the fourth and sixth mining systems (with one black circle and three white circles) can indicate that, for each of these mining systems, three types of components (e.g., hashboards, power supply units, and control board) are functioning properly, and one type of component (e.g., fans) is malfunctioning. In some examples, the status indicators can be paired with messages explaining any issues or errors. Such messages may state, for example “Hashboard 3 overheating,” “Mining System requires cleaning,” “Fan 2 requires repair,” “Power Supply Unit Failure,” “Control Board requires replacement,” and the like.

In some examples, the mining platform user interface 3205A and/or the mining platform user interface 3205B can be modified to include graphs for any of the metrics or statistics that are shown, for instance to track those metrics or statistics over time. For instance, the mining platform user interface 3205A and/or the mining platform user interface 3205B can be modified to include graphs that track, over time, any of: hashrate, efficiency, status, power usage, and/or temperature.

FIG. 33 is a diagram 3300 illustrating connectors of a power management system 3320 for one or more mining systems. In some examples, certain mining system maintain compatibility with the older power infrastructure and layouts. Traditional third-party mining systems can have an inefficient electrical design. For instance, phase imbalance is a significant issue with single phase miners. In some examples, certain mining systems that address power supply issues and/or phase imbalance issues can lose backward compatibility with traditional power infrastructure and layouts.

Single-phase power refers to a two-wire alternating current (AC) power circuit. Three-phase power refers to a three-wire AC power circuit with each phase ac signal being one hundred twenty (120) degrees apart, electrically. Compared to a single-phase power supply, a three-phase power supply better accommodates higher loads.

In some examples, having three-phase power and a single power supply can result lack of a reliable backup power source. In an illustrative example, in the power management system 3320 illustrated in FIG. 33, nine sockets (associated with mining system(s)) are illustrated as plugged into a single-phase power, as opposed to being plugged into a three-phase power that is split into three. Having power supply that aligns with socket system—for instance, a three-socket system aligned with a three-phase power supply—improves the reliability of the power supply system to the mining system(s) by matching the phases with the input power.

In an illustrative example, mining systems can include 6 of 8 plugs per phase, causing a phase imbalance—a significant issue with single-phase miners that can, in some cases, lead to an inability to scale the power of miners to match miners with issues.

FIG. 34 is a diagram 3400 illustrating an architecture of a power management system 3420 for one or more mining systems. The power management system 3420 in the diagram 3400 can be a power distribution unit (PDU) and/or a power supply unit (PSU) with 8 plugs per phase. In the diagram 3400, the L1, L2, and L3 lines each represent a line coming from a panel (e.g., of a mining system). This can represent a phase imbalance. For instance, with this phase imbalance, when one miner goes down it can affect the balance of all three phases, whether a board (e.g., of a mining system) is lost or goes down completely. Remaining miners on the other phases can be unable to scale their power to offset the power that has been lost. The power management system 3420 can be an example of the power management system 3320.

In some examples, triple harmonics created by phase imbalances are a significant cause and/or reason for failures in cables, transformers, and/or switchgear breaker. This can generate excessive heat in equipment and cables, which can cause derating factors to go bad.

FIG. 35 is a circuit diagram illustrating a power supply control circuitry 3500 shown implemented on a hashboard in association with at least one hash ASIC 3510. In an illustrative example, the Phase Locked Loop (PLL) on the hashboard Phase-Locked Loop (PLL) is a feedback system that forces a voltage-controlled oscillator (VCO) to replicate and track the frequency and phase at the input when in lock. In some examples, the power supply control circuitry is a control system allowing one oscillator to track with another, and as such, can keep the ASICs on the hashboard in sync. In some examples, instead of the error amplifier driving a transistor, the error amplifier drives the VCO for a PLL circuit so when the frequency goes up and down that drives the load, it automatically checks itself against the reference voltage in a low dropout regulator fashion. In traditional systems, a single controller outside the hashboard controls the one or more PLLs to remain in concert, instead in the embodiments described herein, the ASIC internally can leverage the internal power supply control circuitry shown in FIG. 35 and allows ASICs can balance themselves. In this way, the PLL's clock or VCO is then used as a “plant” that sets the frequency of the core, and automatically compensate with respect to the other ASICs on the hashboard. In some examples, the power supply control circuitry 3500 makes the ASIC 3510 more self-reliant by making PLLs more self-reliant instead of being controlled by an off-board controller. To achieve this, the power supply control circuitry 3500 includes low dropout regulator (LDO) or a similar structure to drive the PLLs and keep in sync.

FIG. 36 is an image 3600 illustrating fluid flow direction 3610 and airflow direction 3620 for a hashboard 2620 of a mining system 320 in an immersion application. Some traditional mining systems are not immersion optimized, unlike the mining system 320. For instance, certain traditional mining systems have an angled edge at the front of their heat sink 2615 where the incoming ambient air enters (see airflow direction 3620 arrow) and ASIC density is highest. This can be one of the biggest issues when installing these miners in immersion. The fluid travels in the opposite direction (see fluid flow direction 3610 arrow), and its thermal capacity when it reaches the top of the heat sink 3615 is reduced as a result.

The heat sink 3615 of one of the hashboards of the image 3600 is clearly visible in FIG. 36. The hashboards include advanced mining ASICs, combined with tightly integrated hardware and software, to increases overall mining efficiency, reduce overall energy usage, and outperform hashrate on compared to third-party devices. The mining systems are able to work closely with every local energy grid to ensure that they're using this precious resource in the most efficient way possible.

In some examples, the heatsink itself can be optimized for air cooling as well as immersion cooling. In an immersion application, a more turbulent flow can provide improved cooling. This is because, in immersion cooling, breaking the boundary layer in the oil helps proper heat transfer to occur.

In some examples, mining systems can be arranged for immersion into a liquid coolant, with handles included on the mining systems (e.g., arranged to extend from a surface of a liquid coolant) for installation and/or removal from immersion. In some examples, due to the immersion issues, a mining system can be placed upside down, so fluid flow direction 3630 aligns with airflow direction 3620. The handles can be installed so that the miner can be inserted into and out of the fluid coolant easily. However, unless the components of the mining system are arranged correctly (e.g., as in the mining system 320), the mining systems being placed in immersion upside-down can cause users have to pull out a live miner to unplug it to service it, which is inconvenient, can take up a lot of time, and can cause problems with the mining systems.

FIG. 37 includes a line diagram 3700 illustrating the anterior side of the modular mining system 3720 configured for immersion and a line diagram 3750 illustrating the posterior side of the modular mining system 3720. The modular mining system 3720 is illustrated as including three sockets 3730 (e.g., power inputs) for power, aligning with three phases of a three-phase power supply. In some examples, the modular mining system 3720 includes six, nine, or twelve sockets 3730 (e.g., power inputs for power, aligning with three phases of a three-phase power supply (as each of these is a multiple of three). FIG. 38 includes a line diagram 3800 illustrating the top or bottom side of the modular mining system 3720 configured for immersion and a line diagram 3850 illustrating an isometric view of the modular mining system 3720. In some examples, the modular mining system 3720 of FIG. 37 and FIG. 38 is a variant of the mining system 320 of FIG. 36, with additional fans and/or turbines added to assist with flow of liquid coolant over the hashboards and/or control boards.

In some examples, the modular mining system 3720 of FIG. 37 and FIG. 38 has a width of 390 mm, a height of 290 mm, and a depth of 400 mm. In some examples, the modular mining system of FIG. 37 and FIG. 38 has a PSU box that is attached and that is detachable based on PSU and cooling requirements, and that fits with rack dimensions and spaces for mining systems within racks.

In some examples, the modular mining system 3720 (and/or the mining system 320) includes evenly laid out mining ASICs on its PCB(s) (e.g., hashboards), agnostic to fluid flow direction (e.g., no need to turn it upside down use special cable and adaptors to get correct fluid flow like some traditional miners). The modular mining system 3720 includes handles to lift and lower the modular mining system 3720 into tanks (e.g., immersion tanks). In some examples, the modular mining system 3720 fits into racks designed for traditional mining systems. In some examples, the modular mining system 3720 includes an aluminum PCB to allow for higher fluid temperatures and save cost on cooling equipment.

In some examples, the modular mining system 3720 has more efficient power usage than traditional mining systems. In an illustrative example, the modular mining system 3720 runs at 96 kw @ 12 kw per miner 5600TH. A more traditional mining system runs less efficiently, at 63 kw @ 3.5 kw per miner 3600TH, with only 6 out of 8 plugs are currently per phase for the traditional miners due to the imbalance issue.

In some examples, the modular mining system 3720 uses 9.44 KW per foot of rack space and 506TH per foot of rack space. In some examples, the traditional mining system is less efficient, using 5.47 KW per foot of rack space and 312TH per foot of rack space. In some examples, the modular mining system 3720 uses 66% less network equipment and cabling. In some examples, the modular mining system 3720 has the ability to use all ports on PDU and keep phases balanced. In some examples, the modular mining system 3720 requires no bill of materials-just hashboards, make upgrading cheaper and easier.

In some examples, the modular mining system is optimized for companies that build infrastructure. In some examples, the modular mining system can be upgraded over time. In some examples, for the modular mining system, as users add hashboards, the hashrate goes up and also gets more efficient. In some examples, the modular mining system can be overclocked or underclocked, adjusting hashrate by 1-3%. In some examples, underclocking leaves power stranded at the plug. In some cases, with a Managed Mining Program (MMP), a board is added when needed and resulting in more efficient and increased hashrate, while utilizing all the power the facility was designed for. In some examples, there is no need to pay upfront for the most efficient hashrate. Users can pay for the most profitable hashrate and make it more efficient over time. In some examples, users can upgrade the modular mining system(s) over time.

In some examples, heat dissipation from a mining system can be improved by running the mining system in an immersion tank filled with a liquid coolant (e.g., dielectric oil). In an illustrative example, the immersion tank can be a 150 kw tank with 32 S19xp's @ 140 TH and a 10 Degree Temp Delta at 4,480 TH. The immersion tank can fit, and the power supply can support, different amounts of a different mining systems, for instance based on the dimensions of the mining systems. The immersion tank can provide heat removal from the mining systems

FIG. 39 is an exploded perspective view diagram illustrating a mining system 3900 with a housing 3905, six fans 3910, one control board 3195, nine hashboards 3920 and corresponding heat sinks 3925, three power supply units 3930 (PSUs), and three input/output modules 3935 (IO modules). The mining system 3900 is similar to the mining system 320, but can house more nine hashboards 3920 (with their corresponding corresponding heat sinks 3925), more three power supply units 3930, and more input/output modules 3935 than the mining system 320.

The fans 3910 can include, and/or can be an example of, the fans 190, the fans 310A-310B, the fans 2610A-2610B, and/or another fan discussed herein. The control board 3915 can include, and/or can be an example of, the one control board 110, the controller 205, the second controller 280, the control board 2630, and/or another control board discussed herein. The hashboards 3920 can include, and/or can be an example of, the three hashboards 155, the hashboard of the hashing management architecture 200, the hashboards 2110A-2110C, the hashboard 2620, the hashboard 3110, and/or another hashboard discussed herein. The heat sinks 3925 can include, and/or can be an example of, the heat sinks 2130A-2130C, the heat sink 2615, the heat sink 3120, and/or another heat sink discussed herein. The three power supply units 3930 can include, and/or can be an example of, the PSU 195, a PSU corresponding to the voltage (VDD) 230, the PSU 325, the power management system 3320, the power management system 3420, and/or another PSU or power management system discussed herein. The three power supply units 3930, can include, and/or can be an example of, the ethernet connection 120, the lights 130, the buttons 135, the USB connector 140, the fan connectors 145, the power connector 150, input(s) (e.g., ports) into the fans 190, the indicator interface 305, the diagnostic action button 2105, a keypad, a display, a touchscreen, another input device discussed herein, and/or another output device discussed herein.

FIG. 40 is another exploded perspective view diagram 4000 illustrating the mining system 3900 of FIG. 39, with the housing 3905 separated into three components. The exploded perspective view diagram 4000 of FIG. 40 illustrates the mining system 3900 from a different perspective than is illustrated in FIG. 39, but also illustrates the housing 3905, the six fans 3910, the control board 3195, the nine hashboards 3920 and the corresponding heat sinks 3925, the three power supply units 3930 (PSUs), and the three input/output modules 3935 (IO modules).

In the exploded perspective view diagram 4000 of FIG. 40, the housing 3905 is split into a first piece 4005 that includes a base and two walls (side walls that are parallel to one another and that are both perpendicular to the base) of the housing 3905, a second piece 4010 that includes a rear wall or posterior wall (that is perpendicular to the side walls and to the base), and a third piece 4015 that includes a roof or ceiling or lid (that is perpendicular to the walls and parallel to the base).

FIG. 41 is a perspective view diagram 4100 illustrating the mining system 3900 of FIG. 39 with a set 4105 of two of the fans 3910, a hashboard 4110 (of the hashboards 3920), a corresponding heat sink 4115 (of the heat sinks 3925), a power supply unit 4130 (of the three power supply units 3930), and an input/output module 4135 (of the output modules 3935) removed. The perspective view diagram 4100 shows how the various components of the mining system 3900 (also illustrated in FIGS. 39 and 40) fit into or onto the housing 3905. For instance, the six fans 3910 fit onto one side of the housing 3905, essentially forming part of a front wall or anterior wall of the housing 3905. The nine hashboards 3920, the corresponding heat sinks 3925, and the three power supply units 3930 fit into the housing 3905. In some examples, a portion of the three power supply units 3930 forms part of a front wall or anterior wall of the housing 3905, for instance so that plug points, ports, indicator lights, or other input/output devices of the three power supply units 3930 are accessible from the front of the mining system 3900. The output modules 3935 also form part of a front wall or anterior wall of the housing 3905, so that any ports, indicator lights, buttons, and/or other input/output devices of the output modules 3935 are accessible from the front of the mining system 3900.

FIG. 42 is a perspective view diagram 4200 illustrating the mining system 3900 of FIG. 39 with the six fans 3910 removed. The perspective view diagram 4200 is also helpful to show how the various components of the mining system 3900 (also illustrated in FIGS. 39 and 40) fit into or onto the housing 3905. In the perspective view diagram 4200 of the mining system 3900, the power supply units 3930 are illustrated as including power connectors. In the perspective view diagram 4200 of the mining system 3900, the output modules 3935 are illustrated as including network connectors (e.g., ethernet connection 120). It should be understood that the mining system 3900 can alternately or additionally include other types of connectors, inputs, and/or outputs, such as any discussed herein.

FIG. 43 is a user interface diagram 4300 illustrating an interface (mining platform user interface 4305) for mapping a mining system to a slot in a facility. The mining platform user interface 4305 includes a grid representing an array of mining systems, each labeled with a letter from A to D (representing rows in the array) and a number from 1 to 6 (representing columns in the array). This, the array includes twenty-four mining systems, labeled from A1 (in the top-left corner) to D6 (in the bottom-right corner).

The mining platform user interface 4305 highlights system A1 in the array (with a rounded rectangle circling A1). The mining platform user interface 4305 includes a message identifying “slot A1,” allowing the user to “map the miner in this slot.” The mining platform user interface 4305 includes an instruction to “press the power button three times on the miner in this slot to map its position.” The mining platform can map a mining system (e.g., mining system 320, mining system 3900) to the A1 slot in the array once the mining system receives three button presses to a power button (e.g., buttons 135, diagnostic action button 2105).

FIG. 44 is a perspective view diagram 4400 illustrating a set of mining systems 4420A-4420D that each include short-range wireless transceiver(s) 4430A-4430D for communicating with one another and/or with nearby user device(s). The short-range wireless transceiver(s) 4430A-4430D can send and/or receive signals (e.g., wireless signals) wirelessly using a short-range wireless communication protocol, such as Bluetooth®, near field communications (NFC), radio frequency identification (RFID), NearLink®, Wi-Fi, low-power wide-area network (LPWAN), personal area network (PAN), ultra-wideband (UWB) radio, another type of short-range wireless communication protocol, or a combination thereof.

Each of the mining systems 4420A-4420D can be, for instance, a mining system 320, a modular mining system 3720, a mining system 3900, and/or any other type of mining system discussed herein. Each of the short-range wireless transceiver(s) 4430A-4430D can include at least one receiver, at least one transmitter (e.g., beacon), and/or at least one transceiver. The short-range wireless transceiver(s) 4430A of the mining system 4420A can send (e.g., directly send) a wireless signal to any other devices within range (e.g., within wireless signal transmission range) of the short-range wireless transceiver(s) 4430A, for instance to the short-range wireless transceiver(s) 4430B-4430D of the mining systems 4420B-4420D, and/or to short-range wireless transceiver(s) of a user device (e.g., user device 415) that is nearby. This can be used to help guide a user to a particular mining system, for instance if the mining system needs a repair of component(s), a replacement of component(s), and/or maintenance. For instance, the mining system 4420A can instruct other nearby mining systems (e.g., the mining systems 4420B-4420D) to indicate toward the mining system 4420A with the lights (e.g., lights 130, indicator interface 305) of these other mining systems, as illustrated in FIG. 45.

In some examples, different mining systems in a mining platform (e.g., different mining systems of the mining systems 4420A-4420D) can be different models of mining system (e.g., mining system 320, modular mining system 3720, and mining system 3900), can have different configurations and/or different quantities of hashboards, of hashing chips (ASICs) per hashboard, and the like. In some examples, some hashboards can include ninety (90) hashing chips (ASICs). In some examples, some hashboards can include one hundred twenty (120) hashing chips (ASICs).

In some examples, mining systems can communicate with one another and/or with a mining platform system to identify hot spots in a mining facility. For instance, in some examples, a specific portion of a mining facility (e.g., the northwest corner) is hotter than the rest of the mining facility, as determined based on measurements by the temperature sensors of a number of mining systems (e.g., and/or other temperature sensors in the mining facility). In such cases, the mining systems and/or mining platform system can automatically instruct the mining systems in the hot spot to run their cooling systems (e.g., their fans) more strongly (e.g., at a higher fan speed) to cool the mining systems in those areas more.

FIG. 45 is a diagram 4500 illustrating a user standing in front of racks of mining systems, with indicator interfaces of specific mining systems being illuminated to directionally indicate a specific mining system 4505 that the user is to manage (e.g., perform a repair, replacement, or maintenance on). The mining system 4505 that the user is to manage is fully illuminated, for instance illuminating all four of its set of lights (e.g., lights 130, indicator interface 305) as indicated by a set of four black circles. All mining systems that are within three rows of the mining system 4505 and within seven columns of the mining system 4505 are illuminated to directionally point toward the mining system 4505.

For instance, all of the mining systems above the mining system 4505 within that area have their respective bottom lights illuminated (as indicated by black circle(s) toward the bottoms of those devices), while all of the mining systems below the mining system 4505 within that area have their respective top lights illuminated (as indicated by black circle(s) toward the tops of those devices). The mining systems in the same row as the mining system 4505 have their middle light(s) illuminated, illustrated as two black circles in the middle of those mining systems. Of the mining systems above the mining system 4505, the mining systems in the row directly above the mining system 4505 have the two lower lights (nearest the mining system 4505) illuminated to indicate that they are closer to the mining system 4505, while the mining systems in the rows further above the mining system 4505 have only the (single) bottom light (nearest the mining system 4505) illuminated to indicate that they are farther from the mining system 4505. Similarly, of the mining systems below the mining system 4505, the mining systems in the row directly below the mining system 4505 have the two upper lights (nearest the mining system 4505) illuminated to indicate that they are closer to the mining system 4505, while the mining systems in the rows further below the mining system 4505 have only the (single) top light (nearest the mining system 4505) illuminated to indicate that they are farther from the mining system 4505.

The directional lighting indication system illustrated in the diagram 4500 of FIG. 45 can be modified depending on the arrangement and/or capabilities of lights on the mining systems in the array of mining systems. For instance, in the diagram 4500 of FIG. 45, the mining systems each have a column of four lights, arranged vertically. If the mining systems instead or additionally include a row of lights arranged horizontally, the lights on each mining system can point toward left or right toward the mining system 4505 (e.g., by illuminating the leftmost or rightmost light(s)) the same way that the lights in the diagram 4500 point up or down toward the mining system 4505 (by the top or bottom light(s)). For instance, mining systems to the right of the mining system 4505 can illuminate their leftmost light(s) to point the user toward the mining system 4505, and mining systems to the left of the mining system 4505 can illuminate their rightmost light(s) to point the user toward the mining system 4505.

Furthermore, if the mining systems have a display or an array of lights, the mining systems near the mining system 4505 can illuminate lights in the corners of the display or an array of lights to point toward the mining system 4505. For instance, if a nearby mining system is below and to the right of the mining system 4505, the nearby mining system can illuminate its upper-left light(s) to point toward the mining system 4505. Alternately or additionally, if the mining systems have a display or an array of lights, the mining systems near the mining system 4505 can display arrows pointing toward the mining system 4505 using their respective displays or arrays of lights.

In some examples, the lights can be illuminated in an animated fashion. For instance, if a nearby mining system is below the mining system 4505, rather than statically illuminating its top light(s) to point toward the mining system 4505, the nearby mining system can illuminate its lights in an animated and/or dynamic pattern that sequentially illuminates the lights of the nearby mining system from the light that is furthest from the mining system 4505 (e.g., the bottom light) to the light that is closest to the mining system 4505 (e.g., the top light).

In some examples, the lights can be illuminated in different colors to indicate how close a nearby mining system is to the mining system 4505. For instance, the lights can be used as a heatmap, with mining systems that are closest to the mining system 4505 illuminating their lights using a color that is on one end of the color spectrum (or a subset thereof) (e.g., red), with mining systems that are farthest from the mining system 4505 illuminating their lights using a color that is on the opposite end of the color spectrum (or a subset thereof) (e.g., blue or violet), and with systems in between using the colors in between those opposite ends of the color spectrum depending on how close or far they are from the mining system 4505.

In some examples, the mining system 4505 can communicate with the mining systems near the mining system 4505 to instruct those nearby mining systems to use their lights to indicate toward the mining system 4505 as discussed herein. In some examples, the mining system 4505 can use short-range wireless transceiver(s) (e.g., short-range wireless transceiver(s) 4430A-4430D) of the mining system 4505 to communicate wirelessly with short-range wireless transceiver(s) (e.g., short-range wireless transceiver(s) 4430A-4430D) of the nearby mining systems to send instructions to the nearby mining systems. In some examples, the mining system 4505 can use a wired connection interface (e.g., of wires running along and/or through a rack upon which the mining systems are mounted) of the mining system 4505 to communicate with wired connection interfaces of the nearby mining systems to send instructions to the nearby mining systems to instruct those nearby mining systems to use their lights to indicate toward the mining system 4505 as discussed herein.

In some examples, another system (e.g., another mining system, or a mining platform system in charge of the mining platform) can instruct the nearby mining systems near the mining system 4505 to use their lights to indicate toward the mining system 4505 as discussed herein. For instance, in some examples, the mining system 4505 may be defective or disabled, and therefore unable to communicate with the other mining systems. In this scenario, the other system may detect that the mining system 4505 is not responding, or is not working (e.g., hashrate has dropped to zero), and can send instructions to the nearby mining systems, either through wired interface(s) (e.g., ethernet connection 120) and/or wireless interface(s) (e.g., short-range wireless transceiver(s) 4430A-4430D), to instruct those nearby mining systems to use their lights to indicate toward the mining system 4505 as discussed herein.

In some examples, other means can be used (in addition to or instead of the lights discussed herein) to indicate the mining system 4505 to make the mining system 4505 easier to find in an array of mining systems. For instance, in some examples, a speaker on the mining system 4505 can emit a sound (e.g., noise, music, and/or voice) to help a user locate the mining system 4505. In some examples, one or more nearby mining systems that are near the mining system 4505 can use their respective speakers to emit the sound (e.g., noise, music, and/or voice) to help a user locate the mining system 4505, for instance if the mining system 4505 is malfunctioning or disabled, and therefore unable to emit the sound itself.

In some examples, instructions may be sent (e.g., by the mining system 4505, a mining platform system, or another system) to a user device (e.g., user device 415) to illuminate light(s) and/or display(s) of the user device to direct the user toward the mining system 4505. In some examples, the instructions can cause the user device to display an arrow, or lights in a direction of the mining system 4505. In some examples, the instructions can cause the user device to display a user interface such as the mining platform user interface 4605 of FIG. 46.

FIG. 46 is a user interface diagram 4600 illustrating an interface (mining platform user interface 4605) on a user device 415 that provides information about a specific mining system and helps a user find the specific mining system using a camera view overlay 4610 and/or a map 4615. The mining platform user interface 4605 identifies that a specific mining system, referred to as Miner 23 requires a new fan. The mining platform user interface 4605 identifies a hashrate (230.2 TH/s), efficiency (15.5 J/TH), power usage, and temperature of Miner 23.

The user device 415, and/or a mining platform system, receives image data captured by camera(s) of the user device 415, and modifies the image data to generate modified image data displayed in the camera view overlay 4610 of the mining platform user interface 4605. The camera view overlay 4610 is a modified view from the camera of the user device 415, modified to highlight the location of Miner 23, and to show walking directions (via a shaded arrow) to Miner 23. The same view as illustrated in the camera view overlay 4610 is visible behind the interactive element 410, without the overlaid elements highlighting the location of Miner 23 and showing walking directions (via a shaded arrow) to Miner 23.

The user device 415, and/or a mining platform system, receives location data associated with the user device 415. The location data may be based on Global Navigation Satellite System (GNSS) data (e.g., global positioning system (GPS) data) and/or location triangulation based on wireless communication(s) with the short-range wireless transceiver(s) (e.g., short-range wireless transceiver(s) 4430A-4430D) of the nearby mining systems. The user device 415, and/or a mining platform system, uses the location data, along with data indicating locations of the various mining systems, to generate a map 4615 showing the location of the user device 415 (shown as a person icon) relative to the various racks of mining systems, with each rack illustrated as a shaded rectangle. The location of the user device 415 may be the location of the user holding the user device 415. The rectangle representing the rack that includes Miner 23 is shaded with a darker shading pattern than the other rectangles representing the other racks. A circle is illustrated indicating the location of Miner 23 within its rack. A shaded arrow represents walking directions from the current location of the user device 415 (and/or user) to Miner 23. In some examples, the mining platform user interface 4605 may also include written directions (and/or may play spoken directions) from the current location of the user device 415 (and/or user) to Miner 23. For instance, such directions can state “walk forward 15 feet, turn left, walk forward for 3 feet, and look up at a 30 degree angle to see Miner 23.”

FIG. 47A is a side view diagram illustrating a hashboard 4705 with a heatsink 4710A that has a uniform thickness. FIG. 47B is a side view diagram illustrating a hashboard 4705 with a heatsink 4710B that has a varying thickness and a curved shape. FIG. 47C is a side view diagram illustrating a hashboard 4705 with a heatsink 4710C that has a varying thickness and a stair-stepped shape.

The hashboard 4705 can include, and/or can be an example of, the hashboards 155, the hashboard of the hashing management architecture 200, the hashboards 2110A-2110C, the hashboard 2620, the hashboard 3110, the hashboards 3920, and/or another hashboard discussed herein. The heatsinks 4710A-4710C can include, and/or can be an example of, the heat sinks 2130A-2130C, the heat sink 2615, the heat sink 3120, the heat sinks 3925, and/or another heat sink discussed herein.

The heatsink 4710A having uniform thickness can help with fitting the hashboard 4705 and the heatsink 4710A into a slot cleanly, minimizing empty space. The heatsink having varied thickness, as in the heatsink 4710B and the heatsink 4710C, can help dissipate more heat from certain parts of the hashboard 4705 (e.g., areas that tend to heat up such as areas that include the controller 205 and/or clusters of hashing chips 210A-210Q and/or ASICs). For instance, a heatsink can be thicker (e.g., have longer fins) over areas of the hashboard 4705 that have certain components that tend to heat up more, and can be thinner (e.g., have shorter fins) over areas of the hashboard 4705 that tend to heat up less. This can help keep the temperature of the hashboard 4705 lower overall, and/or more uniform.

The heat sinks 2130A-2130C are examples of a heatsink with a stair-stepped shape, as in the heatsink 4710C. For instance, the heat sinks 2130A-2130C are illustrated as having certain fins be longer than other fins, in a discrete or stair-stepped fashion as in the heatsink 4710C rather than a curvsed or continuous fashion as in the heatsink 4710B.

The heat sink 2615 is an example of a heatsink with a curved shape, as in the heatsink 4710B. For instance, the fins of the heat sink 2615 are illustrated as being longer toward the back of the mining system 310 (e.g., closer to the fans 2610A-2610B) and shorter toward the front of the mining system 310 (e.g., closer to the fans 310A-310B), with a continuous or curved progression between.

The heat sink 3120 is illustrated as a combination of the continuous or curved shape of the heatsink 4710B, with certain discrete or stair-stepped variations in thickness as well, as in the heatsink 4710C.

FIG. 48 is an isometric diagram 4800 illustrating actuation of the fans (e.g., fans 310A-310B and/or fans 2610A-2610B) of a mining system 320 to expel dust from an interior of the mining system 320 to an exterior of the mining system 320. The dust is illustrated as a set of shaded starburst-shaped particles, with a first subset in the interior of the mining system 320 (labeled as interior dust 4810 particles) and a second a subset outside of the mining system 320 (labeled as exterior dust 4820 particles).

In some examples, the mining system 320 (or a mining platform system that manages the mining system 320) can identify when the mining system 320 is dirty. For instance, the mining system 320 (or the mining platform system) can track how much power is going to the fans of the mining system 320 (e.g., the fans 310A-310B and/or the fans 2610A-2610B), and can track temperature reduction (or lack thereof) relative to fan power. If power going to the fans is above a threshold, but temperature reduction remains below a threshold, the mining system 320 can be determined to be dirty (e.g., having interior dust 4810).

In some examples, in response to identifying that the mining system 320 is dirty (e.g., having interior dust 4810), the mining system 320 (or the mining platform system) can reverse the fan direction (e.g., by reversing the polarity of power flowing to the fans) and/or can increase the fan speed of the fans (e.g., by increasing the amount of power flowing to the fans) to perform a cleaning cycle in which the fans expel the interior dust 4810 from the interior of the mining system 320 to an exterior of the mining system 320 (to become exterior dust 4820). In some examples, while the mining system 320 is performing its cleaning cycle (and in some cases for a predetermined time afterward), the mining system 320 (and/or the mining platform system) can communicate with other nearby mining systems, for instance wirelessly (e.g., short-range wireless transceiver(s) 4430A-4430D) or through a wired interface (e.g., ethernet connection 120), to instruct the nearby mining systems to disable their fans temporarily (or reverse fan direction) to keep the exterior dust 4820 from being sucked up into the interior(s) of the nearby mining systems.

In some examples, the mining system 320 (or the mining platform system) can test the mining system 320 again (e.g., by comparing the power going to the fans and the temperature drop to respective thresholds) a predetermined amount of time (e.g., a predetermined number of minutes) after the cleaning cycle. If the mining system 320 is determined to still be dirty (e.g., temperature drop is still below threshold), the mining system 320 (or the mining platform system) can initiate one or more additional cleaning cycles, for instance until the mining system 320 (or the mining platform system) determines that the mining system 320 is clean (e.g., temperature drop meets or exceeds the threshold). In some examples, if the mining system 320 (or the mining platform system) causes the mining system 320 to perform at least a predetermined number of cleaning cycles, and the mining system 320 is still determined to be dirty, the mining system 320 (or the mining platform system) can send a request to the user device 415 to have a user clean the mining system 320, maintain the mining system 320, repair the mining system 320 (e.g., repair the fan(s) of the mining system 320), and/or replace component(s) (e.g., fan(s)) of the mining system 320. In this way, the mining system 320 (or the mining platform system) can self-diagnose the issue (the interior dust 4810) and attempt to fix this issue (of interior dust 4810) itself, one or more times, before requesting help from the user via the user device 415. This can provide an improvement in that the mining system 320 ultimately requires less maintenance, and can fix certain issues itself.

FIG. 49 is a user interface diagram 4900 illustrating an interface (mining platform user interface 4905) on a user device that provides information about multiple phases corresponding to one or more mining systems. The mining platform user interface 4905 identifies a hashrate (230.2 TH/s), which is also tracked over time in a graph 4910. The mining platform user interface 4905 also identifies an efficiency (15.5 J/TH), a power usage (3.5 kW), and a temperature (65.5° C.).

The mining platform user interface 4905 also identifies per-phase power usage and utilization for three phases, labeled phase 1, phase 2, and phase 3, respectively. In the mining platform user interface 4905, all three phases have power usage of 4.0 kW, and 100% utilization. In a first illustrative example, the three phases (in the mining platform user interface 4905) can represent phases corresponding to three power supply units of a single mining system, as in the three power supply units 3930 of the mining system 3900. In a second illustrative example, the three phases (in the mining platform user interface 4905) can represent phases corresponding to three different mining systems (e.g., mining system 320) that each have a single power supply (e.g., PSU 325). In a third illustrative example, the three phases (in the mining platform user interface 4905) can represent sets of hashboards that are spread across one or more mining systems.

FIG. 50 is a user interface diagram 5000 illustrating an interface (mining platform user interface 5005) on a user device that provides information about rebalancing between multiple phases corresponding to one or more mining systems. As in the mining platform user interface 4905 of FIG. 49, the mining platform user interface 5005 of FIG. 50 identifies a hashrate (230.2 TH/s), which is also tracked over time in a graph 5010. The mining platform user interface 5005 also identifies an efficiency (15.5 J/TH), a power usage (3.5 kW), and a temperature (65.5° C.).

Similarly to the mining platform user interface 4905 of FIG. 49, the mining platform user interface 5005 of FIG. 50 also identifies per-phase power usage and utilization for three phases, labeled phase 1, phase 2, and phase 3, respectively. In the mining platform user interface 5005, phase 1 has power usage of 1.6 kW and 40% utilization, phase 2 has power usage of 4.3 kW and 120% utilization, and phase 3 has power usage of 4.2 kW and 110% utilization. As discussed above with respect to FIG. 49, the three phases can represent different PSUs in a mining device, different mining devices, different sets of hashboards spread across one or more mining devices, and the like. The mining platform user interface 5005 identifies that phase balancing is in progress, and includes a bar chart tracking relative power usage and/or utilization, along with a target power usage and/or utilization.

FIG. 51 is a circuit diagram illustrating a data filtering architecture 5100. The data filtering architecture 5100 can be used with, and/or can be part of, a mining system, such as the mining system 105, the hashing management architecture 200, the mining system 320, the modular mining system 3720, mining system 3900, any other mining system discussed herein, or a combination thereof.

In some examples, the circuitry of the mining system uses a synchronous communication protocol (e.g., S-LINK), with its S-LINK logic relying on an external clock source for data sampling and processing. Consequently, the S-LINK decoding logic can be susceptible to glitches on the synchronizing clock (SCLK) signal.

To overcome this issue, the circuitry of the mining system can perform data filtering using the data filtering architecture 5100. The data filtering architecture 5100 includes filter components with filter logic for both the S-LINK data (e.g., see filters 5110, 5115, 5125, and 5130) and clock source (e.g., see filters 5105, 5120), ensuring that any glitches on the data and clock lines can be filtered out. The design utilizes a phase lock loop (PLL) clock or divided-down PLL clock to oversample both data and clock signals, regenerating a glitch-free data path and clock path for the chip to process. The PLL clock can be divided by 2, 4, 8, or 16, or can be used at its original speed.

The glitchless filter is capable of removing glitches that are equal or less than a single clock period of the oversampling clock, (e.g., the following glitch within 4 samples can be removed by the filter: 0010, 0100, 1011, 1101). In some examples, the data and clock can experience only minimal delays compared to the original half cycle of the S-LINK clock, for instance with a delay of 4 clock cycles of the divided-down PLL clock, with the gained glitch removal capability being more important than any the delays.

In some examples, the oversampling clock is at least 8 times faster than the S-LINK clock (SCLKI_B) speed. The frequency of the oversampling clock can be flexible, as long as it maintains at least 8 times the S-LINK clock speed and can tolerate frequency variations during sampling. When the oversampling clock is set to 8 times the frequency of the S-LINK clock, it has the strongest ability to remove glitches.

FIG. 52 is a flow diagram illustrating a process 5200 for job assignment. The process 5200 can be performed by a mining system, such as the mining system 105, the hashing management architecture 200, the mining system 320, the modular mining system 3720, mining system 3900, any other mining system discussed herein, or a combination thereof.

In some examples, the circuitry of the mining system supports version rolling on host. The host can construct a suitable header and perform one SHA256 hash to generate the midstate, then the host will send the midstate and the remainder of the header to an ASIC of the mining system to do the second SHA256 hash by iterating the nonce field and time field. If there is a valid nonce found that meets the target, it can be updated to the Nonce Buff with its corresponding parameters, such as version ID, time, and nonce.

At operation 5205, the control board (e.g., one control board 110) sends work to secure hash algorithm (SHA) cores of the hashboard(s) (e.g., hashboards 155) and/or the hashing chips (e.g., ASICs 170A-170Z). In some examples, assigning a job without on-chip version rolling to mining system circuitry is achieved by configuring its corresponding registers to the correct values. Setting the registers to the correct values can include, for instance, resetting the registers, setting configurations for the cores and/or registers, clearing the registers, setting the registers to the appropriate values (e.g., which may be calculated based on PLL speed, timestamp, configuration, and/or work type), setting a version (e.g., in a register), setting a target (e.g., in a register), and/or assigning version rolling (e.g., in register(s)).

At operation 5210, each of the SHA cores calculates nonces, including a first nonce and a second nonce. In some examples, once the on-chip version rolling work is sent to the SHA cores, the SHA cores perform the hashing calculations internally to find the right nonce which makes the hash result of the bitcoin header below the target. In some examples, the mining system circuitry has 378 quad-cores for hash calculations.

In some examples, when a nonce is found (e.g., calculated), it will be sent to a buffer or set of registers (e.g., on a first-in first-out (FIFO) basis) for the SHA engine to check the integrity of the returned nonce.

At operation 5215, the SHA engine checks the integrity of the nonce. Once the returned nonce is verified by the SHA engine as a valid nonce, at operation 5220, the SHA engine pushes the nonce package into a buffer (referred to in FIG. 52 as “nowNonceBuff”) and store it in the nowNonceBuff buffer. In some examples, the nowNonceBuff can store up to 5 of the on-chip version rolling nonces. When nonce_update or new work is assigned, nonces are copied to NonceBuff to be read out.

In some examples, the nonces in the nowNonceBuff are updated to the NonceBuff register under either of the two scenarios: 1. A nonce buff update command is issued, or 2. a new on chip version rolling work is issued.

In some examples, when a nonce is updated to the NonceBuff register (reg_NonceBuff), it can be read by the controller via S-LINK interface by sending a read command to the corresponding register. At operation 5225, the when next work comes in, nowNonceBuff pushes its value to reg_NonceBuff, and its own value is erased or a register nonce update is issued. At operation 5230, the S-LINK issues a read command to read values stored in reg_NonceBuff.

FIG. 53 is a block diagram illustrating an example of a machine learning system 5300 for training, use of, and/or updating of one or more machine learning model(s) 5325 that are used to analyze mining systems. In some examples, the machine learning model(s) 5325 process input(s) 5305 to generate and/or update score(s) 5332 for various miners and/or components, diagnosing and/or predicting issue(s) 5334 for various miners and/or components, generating and/or updating configuration(s) 5336 (e.g., settings, options) for various miners and/or components, identifying and/or predicting what repair(s) 5338 are needed and/or what might be needed to perform the repair(s) 5338, generating alert(s) 5340 (e.g., notifying user(s) about score(s) 5332, issue(s) 5334, configuration(s) 5336, and/or repair(s) 5338), generating retrieval augmented generation (RAG) query(s) 5342 to retrieve further information 5310 from data store(s) 5370 to use as input(s) 5305, to generate other 5344 content, or a combination thereof. The machine learning (ML) system 5300 includes an ML engine 5320 that generates, trains, uses, and/or updates one or more ML model(s) 5325. In some examples, the mining systems disclosed herein, the mobile devices disclosed herein, and/or the servers disclosed herein, can store, run, includes, and/or access the ML system 5300, the ML engine 5320, the ML model(s) 5325, the feedback engine(s) 5345, and/or the data store(s) 5370, or vice versa.

The ML model(s) 5325 can include, for instance, one or more neural network(s) (NN(s)), one or more convolutional NN(s) (CNN(s)), one or more time delay NN(s) (TDNN(s)), one or more deep network(s) (DN(s)), one or more autoencoder(s) (AE(s)), one or more variational autoencoder(s) (VAE(s)), one or more deep belief net(s) (DBN(s)), one or more recurrent NN(s) (RNN(s)), one or more generative adversarial network(s) (GAN(s)), one or more conditional GAN(s) (cGAN(s)), one or more feed-forward network(s), one or more network(s) having fully connected layers, one or more support vector machine(s) (SVM(s)), one or more random forest(s) (RF), one or more computer vision (CV) system(s), one or more autoregressive (AR) model(s), one or more Sequence-to-Sequence (Seq2Seq) model(s), one or more large language model(s) (LLM(s)), one or more deep learning system(s), one or more classifier(s), one or more transformer(s), or a combination thereof. In examples where the ML model(s) 5325 include LLMs, the LLMs can include, for instance, a Generative Pre-Trained Transformer (GPT) (e.g., GPT-2, GPT-3, GPT-3.5, GPT-4, etc.), DaVinci or a variant thereof, an LLM using Massachusetts Institute of Technology (MIT)® langchain, Pathways Language Model (PaLM), Large Language Model Meta® AI (LLaMA), Language Model for Dialogue Applications (LaMDA), Bidirectional Encoder Representations from Transformers (BERT), Falcon (e.g., 40B, 7B, 1B), Orca, Phi-1, StableLM, variant(s) of any of the previously-listed LLMs, or a combination thereof.

Within FIG. 53, a graphic representing the ML model(s) 5325 illustrates a set of circles connected to one another. Each of the circles can represent a node, a neuron, a perceptron, a layer, a portion thereof, or a combination thereof. The circles are arranged in columns. The leftmost column of white circles represent an input layer. The rightmost column of white circles represent an output layer. Two columns of shaded circled between the leftmost column of white circles and the rightmost column of white circles each represent hidden layers. An ML model can include more or fewer hidden layers than the two illustrated, but includes at least one hidden layer. In some examples, the layers and/or nodes represent interconnected filters, and information associated with the filters is shared among the different layers with each layer retaining information as the information is processed. The lines between nodes can represent node-to-node interconnections along which information is shared. The lines between nodes can also represent weights (e.g., numeric weights) between nodes, which can be tuned, updated, added, and/or removed as the ML model(s) 5325 are trained and/or updated. In some cases, certain nodes (e.g., nodes of a hidden layer) can transform the information of each input node by applying activation functions (e.g., filters) to this information, for instance applying convolutional functions, downscaling, upscaling, data transformation, and/or any other suitable functions.

In some examples, the ML model(s) 5325 can include a feed-forward network, in which case there are no feedback connections where outputs of the network are fed back into itself. In some cases, the ML model(s) 5325 can include a recurrent neural network, which can have loops that allow information to be carried across nodes while reading in input. In some cases, the network can include a convolutional neural network, which may not link every node in one layer to every other node in the next layer.

One or more input(s) 5305 can be provided to the ML model(s) 5325. The ML model(s) 5325 can be trained by the ML engine 5320 (e.g., based on training data 5360) to generate one or more output(s) 5330. In some examples, the input(s) 5305 include information 5310. The information 5310 can include, for instance, information from the sensors 180, information indicated in the indicator interface 305, information from the data store(s) 5370 (e.g., queried using RAG query(s) 5342 or otherwise), temperatures, power usage, efficiency, hashrate, fan speed, coolant temperature, coolant flow rate, energy clearing prices, uptime, downtime, mining costs, cryptocurrency amount(s) mined, transaction(s) conducted with cryptocurrencies (mined using the mining systems or otherwise), a listing of which ASICs and/or hashboards and/or miners are online vs. offline, any of the previously-listed measures on a per-ASIC basis, any of the previously-listed measures on a per-hashboard basis, any of the previously-listed measures on a per-mining system basis, any of the previously-listed measures on a per-rack basis, any of the previously-listed measures on a per-container basis, any of the previously-listed measures on a per-facility basis, or a combination thereof.

The output(s) 5330 that ML model(s) 5325 generate by processing the input(s) 5305 (e.g., the information 5310 and/or the previous output(s) 5315) can include score(s) 5332, issue(s) 5334, configuration(s) 5336, repair(s) 5338, alert(s) 5340, RAG query(s) 5342, and/or other 5344. The score(s) 5332 can include, for instance, scores indicating how well (or poorly) a given mining system, hashboard, ASIC, fan, power supply, or control board is operating. The issue(s) 5334 can include issues with a given mining system, hashboard, ASIC, fan, power supply, control board, other component, or a combination thereof. In some cases, the ML model(s) 5325 can diagnose or predict issue(s) 5334 that are not yet apparent otherwise, for instance based on patterns and/or trends detected in temperature, power usage, hashrate, and/or other parameters. The configuration(s) 5336 can include settings, options, and/or other types of configurations for a given mining system, hashboard, ASIC, fan, power supply, control board, other component, or a combination thereof. The repair(s) 5338 can identify what repair(s) are needed (e.g., based on the issue(s) 5334 determined to currently be present), can predict what repair(s) will be needed (e.g., based on the issue(s) 5334 predicted to occur), can identify and/or predict how to perform the repair(s) (e.g., with instructions and/or workflows based on manual(s) associated with the mining systems and/or components), can identify and/or predict what tools and/or parts may be needed for the repair(s) (e.g., as in the interfaces of FIGS. 22 and 29), can identify and/or predict that a self-cleaning cycle (e.g., as in the cleaning cycle of FIG. 48) is helpful or will be helpful, can identify and/or predict that phase rebalancing (e.g., as in the phase rebalancing of FIG. 50) is helpful or will be helpful, can identify and/or predict other repair-related information, or a combination thereof. The alert(s) 5340 can notifying user(s) about score(s) 5332, issue(s) 5334, configuration(s) 5336, and/or repair(s) 5338, as in the mining platform user interface 505, the mining platform user interface 605, the mining platform user interface 705, the mining platform user interface 905, the mining platform user interface 1005, the mining platform user interface 1105, the mining platform user interface 1205, the mining platform user interface 1305, the mining platform user interface 1405, the mining platform user interface 1505, the mining platform user interface 1605, the mining platform user interface 1705, the mining platform user interface 1805, the mining platform user interface 1905, the mining platform user interface 2005, the mining platform user interface 2205, the mining platform user interface 2305, the mining platform user interface 2805, the mining platform user interface 2905, the mining platform user interface 3205, other user interfaces discussed herein, or a combination thereof. In some examples, the alert(s) 5340 can be conversationally responsive to prompt(s) in the information 5310, for instance as illustrated in the mining platform user interface 1605 and/or the mining platform user interface mining platform user interface 1705. In some examples, the alert(s) 5340 can include commands to one or more mining systems or related components, for instance to indicate toward another mining system (e.g., as in FIG. 45), to initiate a cleaning cycle (e.g., as in FIG. 48), to initiate phase rebalancing (e.g., as in FIG. 50), to adjust (e.g., increase or decrease) fan speed, to set (e.g., maintain or reverse) fan direction, to cause the mining system to emit a sound, to perform another action discussed herein, or a combination thereof.

The RAG query(s) 5342 can identify something in the input(s) 5305 about which the data store(s) 5370 includes additional information, and fashions a query for the data store(s) 5370 to retrieve the additional information from the data store(s) 5370. For instance, if the information 5310 references a specific model of mining system, the RAG query(s) 5342 can include one or more queries of the data store(s) 5370 for additional information about the specific model of mining system, for instance to retrieve its components, configurations, settings, firmware updates, ranges of optimal operating parameters (e.g., temperature, fan speed, hashrate, etc.), or a combination thereof. The additional information retrieved from the data store(s) 5370 using the RAG query(s) 5342 can be used as part of the input(s) 5305 (e.g., as part of the information 5310 and/or part of the previous output(s) 5315) for further passes of data processing by the ML model(s) 5325. The output(s) 5330 can also include other 5344 content as discussed herein.

The ML model(s) 5325 can generate the output(s) 5330 based on the information 5310 and/or other types of input(s) 5305 (e.g., previous output(s) 5315).

In some examples, certain output(s) 5330 (e.g., the score(s) 5332, the issue(s) 5334, the configuration(s) 5336, the repair(s) 5338, the alert(s) 5340, the RAG query(s) 5342, the other 5344 content) can be used as part of the input(s) 5305 to the ML model(s) 5325 (e.g., as part of previous output(s) 5315) for identifying other output(s) 5330 (e.g., the score(s) 5332, the issue(s) 5334, the configuration(s) 5336, the repair(s) 5338, the alert(s) 5340, the RAG query(s) 5342, the other 5344 content). For instance, in an illustrative example, the score(s) 5332 can be used, as previous output(s) 5315, to determine the issue(s) 5334, the configuration(s) 5336, the repair(s) 5338, the alert(s) 5340, the RAG query(s) 5342, the other 5344 content. In some examples, at least some of the previous output(s) 5315 in the input(s) 5305 represent previously-identified instances of some of the output(s) 5330 that are input into the ML model(s) 5325 to generate other types of the output(s) 5330. In some examples, based on receipt of the input(s) 5305, the ML model(s) 5325 can select the output(s) 5330 from a list of possible outputs, for instance by ranking the list of possible outputs by likelihood, probability, and/or confidence based on the input(s) 5305. In some examples, based on receipt of the input(s) 5305, the ML model(s) 5325 can identify the output(s) 5330 at least in part using generative artificial intelligence (AI) content generation techniques, for instance using an LLM to generate custom text and/or graphics identifying the output(s) 5330. In some examples, the LLM-based output(s) 5330 are conversationally responsive to a prompt in the input(s) 5305 (e.g., in the information 5310 and/or in the previous output(s) 5315).

In some examples, the ML system repeats the process illustrated in FIG. 53 multiple times to generate the output(s) 5330 in multiple passes, using some of the output(s) 5330 from earlier passes as some of the input(s) 5305 in later passes (e.g., as some of the previous output(s) 5315). For instance, in an illustrative example, in a first pass, the ML model(s) 5325 can identify the score(s) 5332 based on input of the information 5310 into the ML model(s) 5325. In a second pass, the ML model(s) 5325 can identify the issue(s) 5334 based on input of the information 5310 and the previous output(s) 5315 (that includes the score(s) 5332 from the first pass) into the ML model(s) 5325. In a third pass, the ML model(s) 5325 can identify the configuration(s) 5336 based on input of the information 5310 and the previous output(s) 5315 (that includes the score(s) 5332 from the first pass and/or the issue(s) 5334 from the second pass) into the ML model(s) 5325. In a fourth pass, the ML model(s) 5325 can identify the repair(s) 5338 based on input of the information 5310 and the previous output(s) 5315 (that includes the score(s) 5332 from the first pass, the issue(s) 5334 from the second pass, and/or the configuration(s) 5336 from the third pass) into the ML model(s) 5325. In a fifth pass, the ML model(s) 5325 can identify the alert(s) 5340 based on input of the information 5310 and the previous output(s) 5315 (that includes the score(s) 5332 from the first pass, the issue(s) 5334 from the second pass, the configuration(s) 5336 from the third pass, and/or the repair(s) 5338 from the fourth pass) into the ML model(s) 5325. In a sixth pass, the ML model(s) 5325 can identify the query(s) 5342 based on input of the information 5310 and the previous output(s) 5315 (that includes the score(s) 5332 from the first pass, the issue(s) 5334 from the second pass, the configuration(s) 5336 from the third pass, the repair(s) 5338 from the fourth pass, and/or the alert(s) 5340 from the fifth pass) into the ML model(s) 5325. In a seventh pass, the ML model(s) 5325 can identify the other 5344 content based on input of the information 5310 and the previous output(s) 5315 (that includes the score(s) 5332 from the first pass, the issue(s) 5334 from the second pass, the configuration(s) 5336 from the third pass, the repair(s) 5338 from the fourth pass, the alert(s) 5340 from the fifth pass, and/or the query(s) 5342 from the sixth pass) into the ML model(s) 5325.

In some examples, the ML system includes one or more feedback engine(s) 5345 that generate and/or provide feedback 5350 about the output(s) 5330. In some examples, the feedback 5350 indicates how well the output(s) 5330 align to corresponding expected output(s), how well the output(s) 5330 serve their intended purpose, or a combination thereof. In some examples, the feedback engine(s) 5345 include loss function(s), reward model(s) (e.g., other ML model(s) that are used to score the output(s) 5330), discriminator(s), error function(s) (e.g., in back-propagation), user interface feedback received via a user interface from a user, or a combination thereof. In some examples, the feedback 5350 can include one or more alignment score(s) that score a level of alignment between the output(s) 5330 and the expected output(s) and/or intended purpose.

The ML engine 5320 of the ML system can update (further train) the ML model(s) 5325 based on the feedback 5350 to perform an update 5355 (e.g., further training) of the ML model(s) 5325 based on the feedback 5350. In some examples, the feedback 5350 includes positive feedback, for instance indicating that the output(s) 5330 closely align with expected output(s) and/or that the output(s) 5330 serve their intended purpose. In some examples, the feedback 5350 includes negative feedback, for instance indicating a mismatch between the output(s) 5330 and the expected output(s), and/or that the output(s) 5330 do not serve their intended purpose. For instance, high amounts of loss and/or error (e.g., exceeding a threshold) can be interpreted as negative feedback, while low amounts of loss and/or error (e.g., less than a threshold) can be interpreted as positive feedback. Similarly, high amounts of alignment (e.g., exceeding a threshold) can be interpreted as positive feedback, while low amounts of alignment (e.g., less than a threshold) can be interpreted as negative feedback.

In response to positive feedback in the feedback 5350, the ML engine 5320 can perform the update 5355 to update the ML model(s) 5325 to strengthen and/or reinforce weights (and/or connections and/or hyperparameters) associated with generation of the output(s) 5330 to encourage the ML engine 5320 to generate similar output(s) 5330 given similar input(s) 5305. In this way, the update 5355 can improve the ML model(s) 5325 itself by improving the accuracy of the ML model(s) 5325 in generating output(s) 5330 that are similarly accurate given similar input(s) 5305. In response to negative feedback in the feedback 5350, the ML engine 5320 can perform the update 5355 to update the ML model(s) 5325 to weaken and/or remove weights (and/or connections and/or hyperparameters) associated with generation of the output(s) 5330 to discourage the ML engine 5320 from generating similar output(s) 5330 given similar input(s) 5305. In this way, the update 5355 can improve the ML model(s) 5325 itself by improving the accuracy of the ML model(s) 5325 in generating output(s) 5330 are more accurate given similar input(s) 5305. In some examples, for instance, the update 5355 can improve the accuracy of the ML model(s) 5325 in generating output(s) 5330 by reducing false positive(s) and/or false negative(s) in the output(s) 5330.

For instance, here, if some of the output(s) 5330 are used to identify and/or predict issue(s) 5334 and/or to recommend repair(s) 5338, and the issue(s) 5334 are accurate and/or the repair(s) 5338 are successful, the success of the recognition of the issue(s) 5334 and/or the success of the repair(s) 5338 can be interpreted as feedback 5350 that is positive (e.g., positive feedback). On the other hand, if some of the output(s) 5330 are used to identify and/or predict issue(s) 5334 and/or to recommend repair(s) 5338, and the issue(s) 5334 are inaccurate and/or the repair(s) 5338 fail (e.g., are unsuccessful), the failure (or lack of success) of the recognition of the issue(s) 5334 and/or the failure (or lack of success) of the repair(s) 5338 can be interpreted as feedback 5350 that is negative (e.g., negative feedback). Either way, the update 5355 can improve the machine learning system 5300 and the overall system by improving the consistency with which the recognition of the issue(s) 5334, and/or the repair(s) 5338, are successful.

In some examples, the ML engine 5320 can also perform an initial training of the ML model(s) 5325 before the ML model(s) 5325 are used to generate the output(s) 5330 based on the input(s) 5305. During the initial training, the ML engine 5320 can train the ML model(s) 5325 based on training data 5360. In some examples, the training data 5360 includes examples of input(s) (of any input types discussed with respect to the input(s) 5305), output(s) (of any output types discussed with respect to the output(s) 5330), and/or feedback (of any feedback types discussed with respect to the feedback 5350). In some cases, positive feedback in the training data 5360 can be used to perform positive training, to encourage the ML model(s) 5325 to generate output(s) similar to the output(s) in the training data given input of the corresponding input(s) in the training data. In some cases, negative feedback in the training data 5360 can be used to perform negative training, to discourage the ML model(s) 5325 from generate output(s) similar to the output(s) in the training data given input of the corresponding input(s) in the training data. In some examples, the training of the ML model(s) 5325 (e.g., the initial training with the training data 5360, update(s) 5355 based on the feedback 5350, and/or other modification(s)) can include fine-tuning of the ML model(s) 5325, retraining of the ML model(s) 5325, or a combination thereof.

In some examples, the ML model(s) 5325 can include an ensemble of multiple ML models, and the ML engine 5320 can curate and manage the ML model(s) 5325 in the ensemble. The ensemble can include ML model(s) 5325 that are different from one another to produce different respective outputs, which the ML engine 5320 can average (e.g., mean, median, and/or mode) to identify the output(s) 5330. In some examples, the ML engine 5320 can calculate the standard deviation of the respective outputs of the different ML model(s) 5325 in the ensemble to identify a level of confidence in the output(s) 5330. In some examples, the standard deviation can have an inverse relationship with confidence. For instance, if the respective outputs of the different ML model(s) 5325 are very different from one another (and thus have a high standard deviation above a threshold), the confidence that the output(s) 5330 are accurate may be low (e.g., below a threshold). On the other hand, if the respective outputs of the different ML model(s) 5325 are equal or very similar to one another (and thus have a low standard deviation below a threshold), the confidence that the output(s) 5330 are accurate may be high (e.g., above a threshold). In some examples, different ML models(s) 5325 in the ensemble can include different types of models. For instance, in some examples, an ensemble can include a NN and a SVM that are both trained to process the input(s) 5305 to generate at least a subset of the output(s) 5330. In some examples, the ensemble may include different ML model(s) 5325 that are trained to process different inputs of the input(s) 5305 and/or to generate different outputs of the output(s) 5330. For instance, in some examples, a first model (or set of models) can process the input(s) 5305 to generate the score(s) 5332, while a second model (or set of models) can process the input(s) 5305 to generate the issue(s) 5334. In some examples, the ML engine 5320 can choose specific ML model(s) 5325 to be included in the ensemble because the chosen ML model(s) 5325 are effective at accurately processing particular types of input(s) 5305, are effective at accurately generating particular types of output(s) 5330, are generally accurate, process input(s) 5305 quickly, generate output(s) 5330 quickly, are computationally efficient, have higher or lower degrees of uncertainty than other models in the ensemble, or a combination thereof.

In some examples, one or more of the ML model(s) 5325 can be initialized with weights, connections, and/or hyperparameters that are selected randomly. This can be referred to as random initialization. These weights, connections, and/or hyperparameters are modified over time through training (e.g., initial training with the training data 5360 and/or update(s) 5355 based on the feedback 5350), but the random initialization can still influence the way the ML model(s) 5325 process data, and thus can still cause different ML model(s) 5325 (with different random initializations) to produce different output(s) 5330. Thus, in some examples, different ML model(s) 5325 in an ensemble can have different random initializations.

As an ML model (of the ML model(s) 5325) is trained (e.g., along the initial training with the training data 5360, update(s) 5355 based on the feedback 5350, and/or other modification(s)), different versions of the ML model at different stages of training can be referred to as checkpoints. In some examples, after each new update to a model (e.g., update 5355) generates a new checkpoint for the model, the ML engine 5320 tests the new checkpoint (e.g., against testing data and/or validation data where the correct output(s) are known) to identify whether the new checkpoint improves over older checkpoints or not, and/or if the new checkpoint introduces new errors (e.g., false positive(s) and/or false negative(s)). This testing can be referred to as checkpoint benchmark scoring. In some examples, in checkpoint benchmark scoring, the ML engine 5320 produces a benchmark score for one or more checkpoint(s) of one or more ML model(s) 5325, and keeps the checkpoint(s) that have the best (e.g., highest or lowest) benchmark scores in the ensemble. In some examples, if a new checkpoint is worse than an older checkpoint, the ML engine 5320 can revert to the older checkpoint. The benchmark score for a can represent a level of accuracy of the checkpoint and/or number of errors (e.g., false positive or false negative) by the checkpoint during the testing (e.g., against the testing data and/or the validation data). In some examples, an ensemble of the ML model(s) 5325 can include multiple checkpoints of the same ML model.

In some examples, the ML model(s) 5325 can be modified, either through the initial training (with the training data 5360), an update 5355 based on the feedback 5350, or another modification to introduce randomness, variability, and/or uncertainty into an ensemble of the ML model(s) 5325. In some examples, such modification(s) to the ML model(s) 5325 can include dropout (e.g., Monte Carlo dropout), in which one or more weights or connections are selected at random and removed. In some examples, dropout can also be performed during inference, for instance to modify the output(s) 5330 generated by the ML model(s) 5325. The term Bayesian Machine Learning (BML) can refer to random dropout, random initialization, and/or other randomization-based modifications to the ML model(s) 5325. In some examples, the modification(s) to the ML model(s) 5325 can include a hyperparameter search and/or adjustment of hyperparameters. The hyperparameter search can involve training and/or updating different ML models 5325 with different values for hyperparameters and evaluating the relative performance of the ML models 5325 (e.g., against (e.g., against testing data and/or validation data where the correct output(s) are known) to identify which of the ML models 5325 performs best. Hyperparameters can include, for instance, temperature (e.g., influencing level creativity and/or randomness), top P (e.g., influencing level creativity and/or randomness), frequency penalty (e.g., to prevent repetitive language between one of the output(s) 5330 and another), presence penalty (e.g., to encourage the ML model(s) 5325 to introduce new data in the output(s) 5330), other parameters or settings, or a combination thereof.

In some examples, the ML engine 5320 can perform retrieval-augmented generation (RAG) using the model(s) 5325. For instance, in some examples, the ML engine 5320 can pre-process the input(s) 5305 by retrieving additional information from one or more data store(s) 5370 (e.g., any of the databases and/or other data structures discussed herein) and using the additional information to enhance the input(s) 5305 before the input(s) 5305 are processed by the ML model(s) 5325 to generate the output(s) 5330. For instance, in some examples, the enhanced versions of the input(s) 5305 can include the additional information that the ML engine 5320 retrieved from the from one or more data store(s) based on the RAG query(s) 5342. In some examples, this RAG process provides the ML model(s) 5325 with more relevant information, allowing the ML model(s) 5325 to generate more accurate and/or personalized output(s) 5330.

FIG. 54 is a flow diagram illustrating a process 5400 for controlling and/or indicating condition(s) with component(s). The process 5400 can be performed by, and/or using, a mining platform system. The mining platform system can include, for instance, the mining system 105, the hashing management architecture 200, the mining system 320, the package 405, the interactive element 410, the user device 415, a device that displays and/or receives inputs via any of the mining platform user interfaces disclosed herein (e.g., the mining platform user interface 505, the mining platform user interface 605, the mining platform user interface 705, the mining platform user interface 905, the mining platform user interface 1005, the mining platform user interface 1105, the mining platform user interface 1205, the mining platform user interface 1305, the mining platform user interface 1405, the mining platform user interface 1505, the mining platform user interface 1605, the mining platform user interface 1705, the mining platform user interface 1805, the mining platform user interface 1905, the mining platform user interface 2005, the mining platform user interface 2205, the mining platform user interface 2305, the mining platform user interface 2805, the mining platform user interface 2905, the mining platform user interface 3205, other user interfaces discussed herein, or a combination thereof), the PSU 2410, the PSU 2510, the mobile device associated with the mobile key 2720, the hardware wallet or hardware key device associated with the hardware key 2730, the server associated with the hardware key 2730, the power management system 3320, the at least one hash ASIC 3510, the modular mining system 3720, the mining system 3900, the mining platform user interface 4305, the mining systems 4420A-4420D, the short-range wireless transceiver(s) 4430A-4430D, the mining system 4505, the mining platform user interface 4605, the hashboard 4705, the heatsinks 4710A-4710C, the mining platform user interface 4905, the mining platform user interface 5005, the data filtering architecture 5100, a system that performs the process 5200, the machine learning system 5300, the ML engine 5320, the ML model(s) 5325, the feedback engine(s) 5345, the data store(s) 5370, the mining system that performs the process 5500, the mining system that performs the process 5600, the mining system that performs the process 5700, the environment 5800 for application interface customization, the environment 5900, the system 6000, a system, an apparatus, a point of sale (POS) system or terminal, a transaction instrument reader device, a processor that performs instructions stored in a non-transitory computer-readable storage medium, any subsystems or components of any of the above-listed systems, any other computing systems disclosed herein, or a combination thereof.

In some examples, at operation 5405, the mining platform system (or a subsystem thereof) is configured to, and can, receive contextual data associated with a mining system (e.g., mining system 105, hashing management architecture 200, mining system 320, modular mining system 3720). At operation 5410, the mining platform system (or a subsystem thereof) is configured to, and can, analyze the contextual data associated with the mining system. The contextual data includes at least one measurement of at least one characteristic of the at least one component of the mining system.

In some examples, the contextual data includes sensor data from at least one sensor (e.g., sensor(s) 180) of the mining system. In some examples, the at least one sensor includes a temperature sensor, and the sensor data indicates a temperature of the least one component (e.g., ASIC, hashboard, control board, mining system as a whole). In some examples, the at least one sensor is associated with a fan, and the sensor data indicates a characteristic of the fan. The characteristic can be associated with a speed of the fan, an acceleration of the fan, a deceleration of the fan, a pressure of fluid flow (e.g., air flow or liquid flow) caused by the fan, a speed of fluid flow (e.g., air flow or liquid flow) caused by the fan, or a combination thereof.

In some examples, the at least one characteristic associated with the at least component (e.g., ASIC, hashboard, or mining system as a whole) includes at least one of a hashrate, a power consumption rate, or an efficiency.

At operation 5415, the mining platform system (or a subsystem thereof) is configured to, and can, identify, based on the analysis of operation 5410, whether a condition associated with at least one component of the mining system is identified (e.g., detected, met, and/or satisfied). If, at operation 5415, the mining platform system identifies that the condition is identified, then operation 5415 is followed by operation 5420 in the process 5400. If, at operation 5415, the mining platform system identifies that the condition is not identified, then operation 5415 is followed by operation 5405 or operation 5410 in the process 5400, for instance with the mining platform system continuing to receive, monitor, and/or analyze the contextual data as the contextual data is received, and until the condition is identified.

In some examples, identifying the condition includes identifying that the at least one component is at least one of defective, malfunctioning, non-functional, functioning incorrectly, functioning below threshold level(s), due for maintenance, in need of repair, or in need of replacement.

In some examples, a color of the indicator corresponds to the condition. In some examples, a second color corresponds to a second condition. For instance, different colors (e.g., red, orange, yellow, green, blue, purple) can be assigned to different conditions, such as defective, malfunctioning, non-functional, functioning incorrectly, functioning below threshold level(s), due for maintenance, in need of repair, or in need of replacement.

At operation 5420, the mining platform system (or a subsystem thereof) is configured to, and can, select, based on the identification of the condition associated with the at least one component (in operation 5415), at least one indicator to activate. The at least one indicator is a subset of a plurality of indicators of the mining system. The plurality of indicators corresponds to the plurality of components of the mining system. In some examples, each of the plurality of indicators corresponds to a component of the plurality of components of the mining system.

In some examples, the at least one component includes a first component, and the at least one indicator includes a first indicator. In some examples, a shape of the first indicator is based on a shape of the first component, and a shape of a second indicator (of the plurality of indicators) is based on a shape of a second component (of the plurality of components). For instance, in the indicator interface 305, as noted in the legend 800, the indicators that correspond to the hashboards (e.g., indicating hashboard issues 810 when blinking or illuminated in a specific color) are shaped like parallel lines, representing the linear sides of parallel hashboards in slots in the mining system 105 (e.g., see hashboards 2110A-2110C in slots 2120A-2120C in FIG. 21). Similarly, in the indicator interface 305 as noted in the legend 800, the indicators that correspond to the fans (e.g., indicating fan issues 820) are shaped like circles, matching the circular shapes of the fans (e.g., top fan 310A, bottom fan 310B, top fan 2610A, bottom fan 2610B) of the mining system. Similarly, in the indicator interface 305 as noted in the legend 800, the indicator that correspond to the control board (e.g., indicating control board issues 830) is shaped like a square or a rectangle, matching the square or rectangular shape of the control board (e.g., control board 110, second controller 280, control board 2630) of the mining system. Similarly, in the indicator interface 305 as noted in the legend 800, the indicator that correspond to the PSU (e.g., indicating power supply issues 840) is shaped like a rectangle, matching the rectangular shape of the PSU (e.g., PSU 195, voltage (VDD) 230, ground (Gnd) 220, PSU 325) of the mining system.

In some examples the at least one component includes a first component, and the at least one indicator includes a first indicator. In some examples, a color of the first indicator corresponds to the first component, and a color of a second indicator (of the plurality of indicators) corresponds to a second component (of the plurality of components). For instance, in some examples, different colors (and/or blinking patterns) for indicators can correspond to hashboard issues 810, fan issues 820, control board issues 830, or power supply issues 840, respectively. For instance, in a scenario like the one shown in the diagram 3000 of FIG. 30, where a user is looking at an array of mining systems from a distance, use of different colors for different components can help the user know which items (e.g., replacement components, tools) to bring where. Once the user is closer to a specific mining system, the mining system can switch to different indicators corresponding to different components, and/or different colors corresponding to different conditions, for instance, as in the legend 800 of FIG. 8.

At operation 5425, the mining platform system (or a subsystem thereof) is configured to, and can, activate the at least one indicator to indicate the condition associated with the at least one component.

In some examples, the plurality of indicators includes a plurality of light sources (e.g., the lights 130 of the indicator interface 305), and activating the at least one indicator includes changing an illumination characteristic of at least one light source of the plurality of light sources. Changing the illumination characteristic can refer to activating the at least one light source from a deactivated state, deactivating the at least one light source from an activated state, causing the at least one light source to start blinking (where causing the at least one light source was previously not blinking), causing the at least one light source to change from a first blinking pattern to a second blinking pattern, causing the at least one light source to change from a first color to a second color, causing the at least one light source to change from a first set of colors to a second set of colors, or a combination thereof. In some examples, the at least one light source can include a display screen, and changing the illumination characteristic can include changing content displayed on the display screen (e.g., to identify and/or indicate the condition).

In some examples, the plurality of indicators includes a plurality of audio output devices (e.g., speakers), and activating the at least one indicator includes changing an audio output characteristic of at least one audio output device of the plurality of audio output devices. Changing the audio output characteristic can refer to activating the at least one audio output device from a deactivated state, deactivating the at least one audio output device from an activated state, changing what audio is played using the at least one audio output device, or a combination thereof.

In some examples, the mining platform system (or a subsystem thereof) is configured to, and can, transmit a notification to a user device. The notification indicates the condition associated with the at least one component. For instance, the notification can identify than the condition was identified (e.g., detected) in the at least one component. In some examples, the notification identifies the condition associated with the at least one component. For instance, the notification can identify which condition, specifically, was identified (e.g., detected) in the at least one component. In some examples, the notification identifies the mining system among a plurality of mining systems, for instance providing a dashboard or other user interface comparing performance of the plurality of mining systems and/or identifying which is the mining system in which the at least one component is experiencing the condition. In some examples, the notification identifies an action to take to remedy the condition associated with the at least one component. For instance, the notification can identify which repairs or replacements to undertake, and/or which tools and/or replacement parts might be necessary, to remedy the condition (e.g., to repair, replace, or perform maintenance on the at least one component).

In some examples, analyzing the contextual data to identify the condition (as in operation 5410 and/or operation 5415) includes processing the contextual data using a trained machine learning model (e.g., ML model(s) 5325) that outputs an indication of the condition. In some examples, the mining platform system (or a subsystem thereof) is configured to, and can, receive feedback data (e.g., feedback 5350) associated with the at least one indicator. The mining platform system (e.g., ML engine 5320) can update the trained machine learning model based on the feedback data associated with the at least one indicator (e.g., update 5355) to improve an accuracy of the trained machine learning model.

The process 5400 can provide a technical improvement by providing an improved user interface. For instance, selection of the at least one indicator corresponding to the at least one component (for which the condition is identified) represents a particular manner for summarizing and presenting information (e.g., that the condition is identified for at least one component) in an electronic device (e.g., the mining system). The process 5400 can provide a technical improvement by providing systems and methods for using sensors in a non-conventional way (e.g., for identifying the condition in the at least one component).

FIG. 55 is a flow diagram illustrating a process 5500 for controlling and/or indicating condition(s) with component(s). The process 5400 can be performed by, and/or using, a mining system. The mining system can include, for instance, the mining system 105, the hashing management architecture 200, the mining system 320, the package 405, the interactive element 410, the user device 415, a device that displays and/or receives inputs via any of the mining platform user interfaces disclosed herein (e.g., the mining platform user interface 505, the mining platform user interface 605, the mining platform user interface 705, the mining platform user interface 905, the mining platform user interface 1005, the mining platform user interface 1105, the mining platform user interface 1205, the mining platform user interface 1305, the mining platform user interface 1405, the mining platform user interface 1505, the mining platform user interface 1605, the mining platform user interface 1705, the mining platform user interface 1805, the mining platform user interface 1905, the mining platform user interface 2005, the mining platform user interface 2205, the mining platform user interface 2305, the mining platform user interface 2805, the mining platform user interface 2905, the mining platform user interface 3205, other user interfaces discussed herein, or a combination thereof), the PSU 2410, the PSU 2510, the mobile device associated with the mobile key 2720, the hardware wallet or hardware key device associated with the hardware key 2730, the server associated with the hardware key 2730, the power management system 3320, the at least one hash ASIC 3510, the modular mining system 3720, the mining system 3900, the mining platform user interface 4305, the mining systems 4420A-4420D, the short-range wireless transceiver(s) 4430A-4430D, the mining system 4505, the mining platform user interface 4605, the hashboard 4705, the heatsinks 4710A-4710C, the mining platform user interface 4905, the mining platform user interface 5005, the data filtering architecture 5100, a system that performs the process 5200, the machine learning system 5300, the ML engine 5320, the ML model(s) 5325, the feedback engine(s) 5345, the data store(s) 5370, the mining system that performs the process 5500, the mining system that performs the process 5600, the mining system that performs the process 5700, the environment 5800 for application interface customization, the environment 5900, the system 6000, a system, an apparatus, a point of sale (POS) system or terminal, a transaction instrument reader device, a processor that performs instructions stored in a non-transitory computer-readable storage medium, any subsystems or components of any of the above-listed systems, any other computing systems disclosed herein, or a combination thereof.

At operation 5505, the mining system (or a subsystem thereof) is configured to, and can, receive power through a power supply unit (e.g., PSU 195, voltage (VDD) 230, ground (Gnd) 220, PSU 325, power management system 3420, power supply units 3930). An amount of power inputs (e.g., sockets 3730, output modules 3935) of the power supply unit is aligned to an amount of phases of power (e.g., see FIGS. 24-25, FIGS. 33-34, and FIGS. 49-50). In some examples, the amount of power inputs of the power supply unit being aligned to the amount of phases of power reduces or avoids triple harmonics, thereby avoiding damage to the mining system.

At operation 5510, the mining system (or a subsystem thereof) is configured to, and can, supply power from the power supply unit to at least a control board (e.g., control board 110, second controller 280, control board 2630, control board 3915) and a plurality of hashboards (e.g., hashboards 155, hashing management architecture 200, hashboards 2110A-2110C, hashboard 2620, hashboard 3110, hashboards 3920, hashboard 4705).

At operation, 5515, the mining system (or a subsystem thereof) is configured to, and can, use the control board to allocate hash calculations among the plurality of hashboards.

In some examples, the hash calculations are used for mining a cryptocurrency (e.g., Bitcoin, Etherium).

At operation 5520, the mining system (or a subsystem thereof) is configured to, and can identify whether the allocation (of operation 5515) includes performance of the hash calculations using a set of hash chips of the plurality of hash chips (e.g., ASICs 170A-170Z, hashing chips 210A-210Q) of the plurality of hashboards. If the allocation (of operation 5515) includes performance of the hash calculations using the set of hash chips, then the process 5500 proceeds from operation 5520 to operation 5525. If the allocation (of operation 5515) does not includes performance of the hash calculations using the set of hash chips, then the process 5500 proceeds from operation 5520 to operation 5530.

At operation, 5525, the mining system (or a subsystem thereof) is configured to, and can, perform the hash calculations using the set of hashing chips of the plurality of hashing chips of the plurality of hashboards.

At operation, 5530, the mining system (or a subsystem thereof) is configured to, and can, perform the hash calculations using a second set of hashing chips of the plurality of hashing chips of the plurality of hashboards.

In some examples, the power supply unit includes a low dropout regulator (LDO), for instance to drive phase-locked loops (PLLs) (e.g., of the hashboard(s) and/or of the power supply unit) and keep in sync, for instance as illustrated in the power supply control circuitry 3500 of FIG. 35 and/or the data filtering architecture 5100 of FIG. 51.

In some examples, the power supply unit staggers the amount of phases of power to smoothen the power supplied from the power supply unit to at least the control board and the plurality of hashboards, for instance as illustrated in the circuit diagram 2500 of FIG. 25.

In some examples, the power supply unit is part of at least one of the plurality of hashboards. In some examples, each of the hashboards includes its own power supply unit.

In some examples, the mining system includes a housing. The control board, the power supply unit, and the plurality of hashboards are in the housing. In some examples, the plurality of hashboards are received into slots within the housing (e.g., receipt of hashboards 2110A-2110C into the slots 2120A-2120C, and/or receipt of the hashboards 3920 into slots in the housing 3905). In some examples, the mining system includes a fan (e.g., top fan 310A, bottom fan 310B, top fan 2610A, bottom fan 2610B, fans 3910). The fan directs a fluid (e.g., a gas such as air or a liquid such as a dielectric oil) through an interior of a housing, for instance to cool the other components of the mining system (e.g., the control board, the hashboards, the power supply unit).

In some examples, the control board predictively switches a configuration of the plurality of hashboards based on a predicted event. For instance, the predicted event can be a weather event (e.g., a storm) and/or an electrical grid event (e.g., a power outage or power surge). In some examples, the control board predictively switching the configuration of the plurality of hashboards includes the control board modifying which of the plurality of hashboards receives power from the power supply unit. In some examples, the control board predictively switching the configuration of the plurality of hashboards includes the control board modifying which hashing chips receive power from the power supply unit.

In some examples, the power supply unit includes a phase-locked loop (PLL) and a voltage-controlled oscillator (VCO). In some examples, the plurality of hashboards includes a phase-locked loop (PLL) and a voltage-controlled oscillator (VCO). For example, see the PLL and VCO of the power supply control circuitry 3500 of FIG. 35.

In some examples, the plurality of hashing chips is a plurality of application specific integrated circuits (ASICs).

In some examples, the mining system includes a sensor (e.g., sensor(s) 180) that measures a characteristic of at least a subset of the plurality of hashing chips of the plurality of hashboards.

In some examples, the mining system includes an indicator interface (e.g., indicator interface 305) with a plurality of light sources (e.g., lights 130). An illumination characteristic of at least one of the plurality of light sources changes in response to identification of a condition associated with at least one of the control board, the power supply unit, or the plurality of hashboards. Changing the illumination characteristic can refer to activating the at least one light source from a deactivated state, deactivating the at least one light source from an activated state, causing the at least one light source to start blinking (where causing the at least one light source was previously not blinking), causing the at least one light source to change from a first blinking pattern to a second blinking pattern, causing the at least one light source to change from a first color to a second color, causing the at least one light source to change from a first set of colors to a second set of colors, or a combination thereof. In some examples, the at least one light source can include a display screen, and changing the illumination characteristic can include changing content displayed on the display screen (e.g., to identify and/or indicate the condition).

The process 5500 can provide a technical improvement by reducing or eliminating phase imbalances and/or associated problems. For instance, in traditional mining systems, individual miners going down results in phase imbalances, leading to a risk of costly infrastructure failure, resulting in derating of infrastructure, and lowering utilization. In some examples, triple harmonics created by phase imbalances are a significant cause and/or reason for failures in cables, transformers, and/or switchgear breakers. This can generate excessive heat in equipment and cables, which can cause derating factors to go bad. Phase imbalances between supplied power and input power can lead to an inability to scale the power of operational miners to match inoperative miners. In some examples, with this phase imbalance, when one miner goes down it can affect the balance of all three phases of a three-phase power system, whether a board (e.g., of a mining system) is lost or goes down completely. Remaining miners on the other phases can be unable to scale their power to offset the power that has been lost. In some examples, the mining systems discussed herein (and/or server systems associated with the mining systems) provide backward compatibility with multiple power infrastructures by matching power phases with the input power. For instance, in some examples, a number of power inputs to the mining system is based on a number of phases of a power source that the plurality of mining systems receives power from. In some implementations, the mining system has three power supplies per miner. Each Power Supply Unit (PSU) is plugged into a separate phase in the PSU. If a hashboard goes down or a miner draws less power, the power draw is evenly distributed amongst all three phases. This allows miners to utilize a greater amount of power in their facility. In some implementations, the PSU is dynamically configured to plug into n phases, where n is between 1 and 3 (inclusive). This resolves the power imbalance (e.g., matching of the power phases with the input power), providing a technical improvement by improving reliability of the mining systems, preventing damage to the mining systems, and improving backup power functioning in mining systems.

FIG. 56 is a flow diagram illustrating a process 5600 for mining system interfacing. The process 5600 can be performed by, and/or using, a mining system. The mining system can include, for instance, the mining system 105, the hashing management architecture 200, the mining system 320, the package 405, the interactive element 410, the user device 415, a device that displays and/or receives inputs via any of the mining platform user interfaces disclosed herein (e.g., the mining platform user interface 505, the mining platform user interface 605, the mining platform user interface 705, the mining platform user interface 905, the mining platform user interface 1005, the mining platform user interface 1105, the mining platform user interface 1205, the mining platform user interface 1305, the mining platform user interface 1405, the mining platform user interface 1505, the mining platform user interface 1605, the mining platform user interface 1705, the mining platform user interface 1805, the mining platform user interface 1905, the mining platform user interface 2005, the mining platform user interface 2205, the mining platform user interface 2305, the mining platform user interface 2805, the mining platform user interface 2905, the mining platform user interface 3205, other user interfaces discussed herein, or a combination thereof), the PSU 2410, the PSU 2510, the mobile device associated with the mobile key 2720, the hardware wallet or hardware key device associated with the hardware key 2730, the server associated with the hardware key 2730, the power management system 3320, the at least one hash ASIC 3510, the modular mining system 3720, the mining system 3900, the mining platform user interface 4305, the mining systems 4420A-4420D, the short-range wireless transceiver(s) 4430A-4430D, the mining system 4505, the mining platform user interface 4605, the hashboard 4705, the heatsinks 4710A-4710C, the mining platform user interface 4905, the mining platform user interface 5005, the data filtering architecture 5100, a system that performs the process 5200, the machine learning system 5300, the ML engine 5320, the ML model(s) 5325, the feedback engine(s) 5345, the data store(s) 5370, the mining system that performs the process 5400, the mining system that performs the process 5500, the mining system that performs the process 5700, the environment 5800 for application interface customization, the environment 5900, the system 6000, a system, an apparatus, a point of sale (POS) system or terminal, a transaction instrument reader device, a processor that performs instructions stored in a non-transitory computer-readable storage medium, any subsystems or components of any of the above-listed systems, any other computing systems disclosed herein, or a combination thereof.

At operation 5605, the mining system (or a subsystem thereof) is configured to, and can, identify, based on contextual data associated with a mining system, that an alert is to be output about a component of the mining system. The component is one of a plurality of components of the mining system.

At operation 5610, the mining system (or a subsystem thereof) is configured to, and can, select, based on the identification of the component, an indicator of a plurality of indicators to activate based on the indicator corresponding to the component. Each of the plurality of indicators corresponds to at least one of the plurality of components. The mining system includes the plurality of indicators.

At operation 5615, the mining system (or a subsystem thereof) is configured to, and can, activate the indicator to output the alert about the component.

In some aspects, the process 5600 relates to identifying which indicator (e.g., indicator LED) to activate (e.g., illuminate) to alert a user about a specific component of a mining system.

In some aspects, the indicator is a light source (e.g., an LED or other type of light), and activating the indicator includes at least one of illuminating the light source (e.g., activating the light source from a deactivated state) or changing an illumination characteristic of the light source (e.g., changing a color, changing between steady illumination and a blinking or flashing state, changing a blinking or flashing pattern, or a combination thereof). In some aspects, the indicator is an audio output device (e.g., a speaker or headset), and activating the indicator includes playing audio via the audio output device. In some aspects, the indicator is a haptic output device (e.g., a haptic actuator), and activating the indicator includes outputting a vibration via the haptic output device. In some aspects, the indicator is a transmitter (e.g., a transmitter for a wireless communication protocol such as Wi-Fi or Bluetooth or WLAN), and activating the indicator includes sending a signal to a recipient device via the transmitter.

In some aspects, identifying that the alert is to be output about the component of the mining system (of operation 5605) includes identifying that the component is defective, malfunctioning, non-functional, or functioning incorrectly. In some aspects, identifying that the alert is to be output about the component of the mining system (of operation 5605) includes identifying that the component is to be replaced or is to undergo maintenance.

In some aspects, a shape of the indicator is based on (e.g., matches or corresponds to) a shape of the component, and a shape of a second indicator of the plurality of indicators is based on a shape of a second component of the plurality of components. In some aspects, a color of the indicator corresponds to (e.g., is based on or matches) the component, and a color of a second indicator of the plurality of indicators corresponds to a second component of the plurality of components. In some aspects, a position of the indicator (e.g., within an indicator interface 305) corresponds to (e.g., is based on or matches) a position of the component in the mining system, and a position of a second indicator of the plurality of indicators (e.g., within the indicator interface 305) corresponds to the position of the second component in the mining system. For instance, the shapes and/or colors and/or positions of indicators can be based on (e.g., match) the shapes and/or colors and/or positions of at least portions of the corresponding components. For instance, per the legend 800 and the indicator interface 305, the fans are represented by circles (e.g., as in the circular shape of the fans inside the fan housing) on the lower-left side of the indicator interface 305 (e.g., with the fans also being on the lower-left side of the mining system), the hashboards are represented by vertical lines (e.g., as in the side of the hashboard visible in FIG. 21 from the anterior side of the mining system) on the upper-left side of the indicator interface 305 (e.g., with the hashboard also being on the upper-left side of the mining system), the control board is represented by a square on the upper-right side of the indicator interface 305 (e.g., with the control board also being on the upper-right side of the mining system), and the power supply is represented by a rectangle on the lower-right side of the indicator interface 305 (e.g., with the power supply also being on the lower-right side of the mining system). In some examples, shapes, colors, and/or positions of the indicators are different for different components

In some aspects, identifying that the alert is to be output about the component of the mining system (of operation 5605) includes identifying a condition affecting the component, wherein a color of the indicator corresponds to the condition affecting the component. In some examples, colors of the indicators are different for different conditions (e.g., component is broken vs. component needs routine maintenance).

In some aspects, the mining system (or a subsystem thereof) is configured to, and can, transmit a second alert to a user device (e.g., a phone or mobile device), the second alert identifying the component.

In some aspects, identifying that the alert is to be output about the component of the mining system (of operation 5605) includes identifying a condition affecting the component. In some aspects, the condition affecting the component is identified in at least one of the alert or the second alert.

In some aspects, the mining system is part of a plurality of mining systems (e.g., in a rack, a container, an immersion tank, and/or another set or collection of mining systems). In some aspects, a number of power inputs to the mining system is based on a number of phases of a power source that the plurality of mining systems receives power from. The plurality of mining systems includes the mining system. In some aspects, the process 5600 involves matching power phases with the input power.

In some aspects, the indicator light(s) can also be illuminated to indicate an issue with another nearby mining system, as in the lights illuminated on the nearby mining systems (near the mining system 4505) in FIG. 45.

FIG. 57 is a flow diagram illustrating a process 5700 for predictive mining system control. The process 5700 can be performed by, and/or using, a mining system. The mining system can include, for instance, the mining system 105, the hashing management architecture 200, the mining system 320, the package 405, the interactive element 410, the user device 415, a device that displays and/or receives inputs via any of the mining platform user interfaces disclosed herein (e.g., the mining platform user interface 505, the mining platform user interface 605, the mining platform user interface 705, the mining platform user interface 905, the mining platform user interface 1005, the mining platform user interface 1105, the mining platform user interface 1205, the mining platform user interface 1305, the mining platform user interface 1405, the mining platform user interface 1505, the mining platform user interface 1605, the mining platform user interface 1705, the mining platform user interface 1805, the mining platform user interface 1905, the mining platform user interface 2005, the mining platform user interface 2205, the mining platform user interface 2305, the mining platform user interface 2805, the mining platform user interface 2905, the mining platform user interface 3205, other user interfaces discussed herein, or a combination thereof), the PSU 2410, the PSU 2510, the mobile device associated with the mobile key 2720, the hardware wallet or hardware key device associated with the hardware key 2730, the server associated with the hardware key 2730, the power management system 3320, the at least one hash ASIC 3510, the modular mining system 3720, the mining system 3900, the mining platform user interface 4305, the mining systems 4420A-4420D, the short-range wireless transceiver(s) 4430A-4430D, the mining system 4505, the mining platform user interface 4605, the hashboard 4705, the heatsinks 4710A-4710C, the mining platform user interface 4905, the mining platform user interface 5005, the data filtering architecture 5100, a system that performs the process 5200, the machine learning system 5300, the ML engine 5320, the ML model(s) 5325, the feedback engine(s) 5345, the data store(s) 5370, the mining system that performs the process 5400, the mining system that performs the process 5500, the mining system that performs the process 5600, the environment 5800 for application interface customization, the environment 5900, the system 6000, a system, an apparatus, a point of sale (POS) system or terminal, a transaction instrument reader device, a processor that performs instructions stored in a non-transitory computer-readable storage medium, any subsystems or components of any of the above-listed systems, any other computing systems disclosed herein, or a combination thereof.

At operation 5705, the mining system (or a subsystem thereof) is configured to, and can, predict, based on contextual data associated with an environment that a mining system is in, that a condition is to occur during a time period. The condition is predicted to affect availability of a resource by the mining system.

At operation 5710, the mining system (or a subsystem thereof) is configured to, and can, configure the mining system to predictively switch from a first configuration before the time period to a second configuration during the time period. The second configuration is operable to use the resource differently than the first configuration.

At operation 5715, the mining system (or a subsystem thereof) is configured to, and can, predictively switch the mining system from the first configuration to the second configuration in response to initiation of the time period.

In some aspects, the process 5700 relates to predictively reconfiguring a mining system based on predicted conditions (e.g., weather conditions, electrical grid conditions, etc.) that affect availability of a resource (e.g., power).

In some aspects, the condition is at least one of a weather condition or an electrical grid condition. For instance, in some examples, extreme weather conditions (whether hot or cold weather) can result in increased power usage (e.g., for heating and/or air conditioning) and thus more strain on the electrical grid, which can make power less available and/or reliable, and/or can make power more expensive in some cases.

In some aspects, the resource is power, and the second configuration being operable to use the resource differently than the first configuration (as in operation 5710) includes the second configuration being operable to use power at a different rate (e.g., higher or lower) than the first configuration, and/or at a different phase, and/or at a matching phase.

In some aspects, the mining system (or a subsystem thereof) is configured to, and can, configure the mining system to predictively switch from the second configuration back to the first configuration after the time period is over (e.g., after an extreme weather condition is over or a problem with the electrical grid is over). In some aspects, the mining system (or a subsystem thereof) is configured to, and can, configure the mining system to predictively switch from the second configuration to a third configuration after the time period is over. In some examples, the third configuration is operable to use the resource differently than the second condition and/or the first condition.

In some aspects the mining system includes a plurality of components, and the second configuration being operable to use the resource differently than the first configuration (as in operation 5710) includes the second configuration being operable to disable at least a subset of the plurality of components that are enabled in the first configuration.

In some aspects, the mining system includes a plurality of components, and the second configuration being operable to use the resource differently than the first configuration (as in operation 5710) includes the second configuration being operable to throttle at least a subset of the plurality of components that are not throttled in the first configuration.

In some aspects, the condition is associated with a component of the mining system, and the second configuration is operable to modify use of the component compared to the first configuration.

In some aspects, the condition is associated with a component of the mining system, and the mining system (or a subsystem thereof) is configured to, and can, predictively order at least one instance of the component before the time period.

In some aspects, the mining system is part of a plurality of mining systems (e.g., in a rack, a container, an immersion tank, and/or another set or collection of mining systems). In some aspects, a number of power inputs to the mining system is based on a number of phases of a power source that the plurality of mining systems receives power from. The plurality of mining systems includes the mining system. In some aspects, the process 5700 involves matching power phases with the input power.

FIG. 58 illustrates an example environment 5800 for application interface customization. The environment 5800 includes server(s) 5802 that can communicate over a network 5804 with end user devices 5806 and/or server(s) 5808 associated with third-party service provider(s). In various examples, the end user devices 5806 may comprise one or more merchant devices 5806(A), one or more user devices 5806(B) and/or 5806(C) in a peer network, one or more content consumption devices 5806(D), one or more artist user devices 5806(E), combinations of these examples, or other categories of user devices. The server(s) 5802 can be associated with one or more service providers that can provide one or more services for the benefit of users 5816, as described below. For example, the server(s) 5802 may enable services of service providers such as in association with a merchant platform 5810 (which may further include a buyer platform), a peer-to-peer (P2P) payment platform 5812, a media content platform 5814, a combination of these platforms, or other platforms associated with other service providers. While services and features are referenced throughout in connection with a particular one of the merchant platform 5810, the P2P payment platform 5812, or the media content platform 5814, it should be understood that any of these platforms may perform the functionality described in relation to any of the other platforms. Actions attributed to the service provider(s) can be performed by the server(s) 5802.

In some examples, the end user devices 5806, merchant platform 5810, P2P platform 5812, and/or media content platform 5814 can be examples of any mining system or set of mining systems of any of FIGS. 1-46, the mining system that performs the process 5400, the mining system that performs the process 5700, or a combination thereof. In some examples, individual ones of the end user devices 5806 can be operable by users 5816 (e.g., user of any of the mining systems disclosed herein). The users 5816 (individually referred to herein as “user 5816”) can be referred to as miners, customers, buyers, merchants, sellers, borrowers, employees, employers, payors, payees, couriers, artists, musicians, listeners, fans, supervisors, hosts, audience members, and so on. The users 5816 can interact with the end user devices 5806 via user interfaces presented via the end user devices 5806. In at least one example, a user interface can be presented via a web browser, or the like. Alternatively or additionally, a user interface can be presented via an application, such as a mobile application or desktop application, which can be provided by the merchant platform 5810, the P2P payment platform 5812, and/or the media content platform 5814, or which can be an otherwise dedicated application. In some examples, individual end user devices 5806 can have an instance or versioned instance of an application, which can be downloaded from an application store, for example, which can present the user interface(s) described herein.

In at least one example, the users 5816 can include merchants that can operate the seller device(s) 5806(A) that are configured for use by merchants. For the purpose of this discussion, a “merchant” can be any entity that offers items (e.g., goods or services) for purchase or other means of acquisition (e.g., rent, borrow, barter, etc.). The merchants can offer items for purchase or other means of acquisition via brick-and-mortar stores, mobile stores (e.g., pop-up shops, food trucks, etc.), online stores, event venues, combinations of the foregoing, and so forth. In some examples, at least some of the merchants can be associated with the same entity but can have different merchant locations and/or can have franchise/franchisee relationships.

In additional or alternative examples, the merchants can be different merchants. For the purpose of this discussion, “different merchants” can refer to two or more unrelated merchants. “Different merchants” therefore can refer to two or more merchants that are different legal entities (e.g., natural persons and/or corporate persons) that do not share accounting, employees, branding, etc. “Different merchants,” as used herein, have different names, employer identification numbers (EIN) s, lines of business (in some examples), inventories (or at least portions thereof), and/or the like. Thus, the use of the term “different merchants” does not refer to a merchant with various merchant locations or franchise/franchisee relationships. Such merchants—with various merchant locations or franchise/franchisee relationships—can be referred to as merchants having different merchant locations and/or different commerce channels.

The seller device 5806(A) can have an instance of a point of sale (“POS”) application 5820 stored thereon. The POS application 5820 can configure the seller device 5806(A) as a POS terminal, which enables the merchant to interact with one or more customers. In at least one example, interactions between the customers and the merchants that involve the exchange of funds (from the customers) for items or services (from the merchants) can be referred to as “transactions.” In at least one example, the POS application 5820 can determine transaction data associated with the POS transactions. Transaction data can include payment information, which can be obtained from a reader device 5822 associated with the seller device 5806(A), user authentication data, purchase amount information, point-of-purchase information (e.g., item(s) purchased, date of purchase, time of purchase, subscription type, etc.), etc. The POS application 5820 can send transaction data to the server(s) 5802 such that the server(s) 5802 can track transactions of the customers, merchants, and/or the users 5816 over time. Furthermore, the POS application 5820 can present a UI to enable the merchant to interact with the POS application 5820 and/or the merchant platform 5810 via the POS application 5820.

In at least one example, the seller device 5806(A) can be a special-purpose computing device configured as a POS terminal (via the execution of the POS application 5820). In at least one example, the POS terminal may be connected to a reader device 5822, which is capable of accepting a variety of payment instruments, such as credit cards, debit cards, gift cards, short-range communication based payment instruments, and the like, as described below. In at least one example, the reader device 5822 can plug in to a port in the seller device 5806(A), such as a microphone port, a headphone port, an audio-jack, a data port, or other suitable port. In additional or alternative examples, the reader device 5822 can be coupled to the seller device 5806(A) via another wired or wireless connection, such as via Bluetooth®, BLE, and so on. In some examples, the reader device 5822 can be a software solution executing on the POS terminal, e.g., a mobile phone. In some examples, the reader device 5822 can read information from alternative payment instruments including, but not limited to, wristbands and the like.

In some examples, the reader device 5822 may physically interact with payment instruments such as magnetic stripe payment cards, EMV payment cards, and/or short-range communication (e.g., near field communication (NFC), radio frequency identification (RFID), Bluetooth®, Bluetooth® low energy (BLE), etc.) payment instruments (e.g., cards, hardware wallets, fobs, or devices configured for tapping). The POS terminal may provide a rich user interface, communicate with the reader device 5822, and communicate with the merchant platform 5810, which can provide, among other services, a payment processing service. The server(s) 5802 associated with the merchant platform 5810 can communicate with server(s) 5808, as described below. In this manner, the POS terminal and reader device 5822 may collectively process transaction(s) between the merchants and customers. In some examples, multiple POS terminal(s) may be connected to a number of other devices, such as “secondary” terminals, e.g., back-of-the-house systems, printers, line-buster devices, reader devices, speakers, and the like, to allow for information from the secondary terminal to be shared between the primary POS terminal(s) and secondary terminal(s), for example via short-range communication technology. This kind of arrangement may continue operation in an offline-online scenario to allow one device (e.g., secondary terminal) to continue taking user input, and synchronize data with another device (e.g., primary terminal) when the primary or secondary terminal switches to online mode. In other examples, such data synchronization may happen periodically or at randomly selected time intervals.

While the POS terminal and the reader device 5822 of the POS system 5824 are shown as separate devices, in additional or alternative examples, the POS terminal and the reader device 5822 can be part of a single device. In some examples, the reader device 5822 can have a display integrated therein for presenting information to customers of a merchant. In additional or alternative examples, the POS terminal can have a display integrated therein for presenting information to the customers of the merchant. POS systems, such as the POS system 5824, may be mobile, such that POS terminals and reader devices may process transactions in disparate locations across the world. POS systems can be used for processing card-present transactions and card-not-present (CNP) transactions.

A card-present transaction is a transaction where both a customer and the customer's payment instrument are physically present at the time of the transaction. Card-present transactions may be contact or contactless transactions processed by swipes (e.g., by sliding a magnetic strip through a reader device), dips (e.g., by inserting an embedded microchip into a reader device), taps (e.g., by wirelessly, through Bluetooth, NFC or other short range technology hover or tap a payment instrument into a reader device), or any other interaction between a physical payment instrument (e.g., a card), or otherwise present payment instrument, and a reader device 5822, whereby the reader device 5822 is able to obtain payment data from the payment instrument.

A CNP transaction is a transaction where a card, or other payment instrument, is not physically present at the POS such that payment data is manually keyed in (e.g., by a merchant, customer, etc.), or payment data is required to be recalled from a card-on-file data store, to complete the transaction.

The POS system 5824, the server(s) 5802, and/or the server(s) 5808 may exchange payment information and transaction data to determine whether transactions are authorized. For example, the POS system 5824 may provide encrypted payment data, user authentication data, purchase amount information, point-of-purchase information, etc. (collectively, transaction data) to server(s) 5802 over the network(s) 5804. The server(s) 5802 may send the transaction data to the server(s) 5808.

For the purpose of this discussion, the “payment service providers” can be acquiring banks (“acquirer”), issuing banks (“issuer”), card payment networks, and the like. In an example, an acquirer is a bank or financial institution that processes payments (e.g., credit or debit card payments) and can assume risk on behalf of merchants(s). An acquirer can be a registered member of a card association (e.g., Visa®, MasterCard®), and can be part of a card payment network. In at least one example, the service provider can serve as an acquirer and connect directly with the card payment network.

The card payment network (e.g., the server(s) 5808 associated therewith) can forward the fund transfer request to an issuing bank (e.g., “issuer”). The issuer is a bank or financial institution that offers a financial account (e.g., credit or debit card account) to a user. The issuer (e.g., the server(s) 5808 associated therewith) can make a determination as to whether the customer has the capacity to absorb the relevant charge associated with the payment transaction. In at least one example, the merchant platform 5810 can serve as an issuer and/or can partner with an issuer. The transaction is either approved or rejected by the issuer and/or the card payment network (e.g., the server(s) 5808 associated therewith), and a payment authorization message is communicated from the issuer to the POS device via a path opposite of that described above, or via an alternate path.

The server(s) 5808 may send an authorization notification over the network(s) 5804 to the server(s) 5802, which may send the authorization notification to the POS system 5824 over the network(s) 5804 to indicate whether the transaction is authorized. The server(s) 5802 may also transmit additional information such as transaction identifiers to the POS system 5824. In one example, the server(s) 5802 may include a merchant application and/or other functional components for communicating with the POS system 5824 and/or the server(s) 5808 to authorize or decline transactions (e.g., the API 5818). In examples, the merchant platform 5810 can enable the merchants to receive cash payments, payment card payments, and/or electronic payments from customers for POS transactions and the service provider can process transactions on behalf of the merchants.

Based on the authentication notification that is received by the POS system 5824 from server(s) 5802, the merchant may indicate to the customer whether the transaction has been approved. In some examples, approval may be indicated at the POS system 5824, for example, at a display of the POS system 5824. In some cases, such as with a smart phone or watch operating as a short-range communication payment instrument, information about the approved transaction may be provided to the short-range communication payment instrument for presentation via a display of the smart phone or watch. In some examples, additional or alternative information can additionally be presented with the approved transaction notification including, but not limited to, receipts, special offers, coupons, or loyalty program information.

The merchant platform 5810 can provide, among other services, payment processing services, inventory management services, catalog management services, business banking services, financing services, lending services, reservation management services, web-development services, payroll services, employee management services, appointment services, loyalty tracking services, restaurant management services, order management services, fulfillment services, onboarding services, identity verification (IDV) services, media content (e.g., music, videos, etc.) management and/or subscription services, and so on. In some examples, the end user devices 5806 can access all of the services. In some cases, the end user devices 5806 can have gradated access to the services, which can be based on risk tolerance, IDV outputs, subscriptions, and so on. In at least one example, access to such services can be availed to the merchants via the POS application 5820. In additional or alternative examples, each service can be associated with its own access point (e.g., application, web browser, etc.).

As the merchant platform 5810 processes transactions on behalf of the merchants, the merchant platform 5810 can maintain accounts or balances for the merchants in one or more ledgers. For example, the merchant platform 5810 can analyze transaction data received for a transaction to determine an amount of funds owed to a merchant for the transaction and deposit funds into an account of the merchant. The account can have a stored balance, which can be managed by the merchant platform 5810. The account can be different from a conventional bank account at least because the stored balance is managed by a ledger of the merchant platform 5810 and the associated funds are accessible via various withdrawal channels including, but not limited to, scheduled deposit, same-day deposit, instant deposit, and a linked payment instrument.

A scheduled deposit can occur when the merchant platform 5810 transfers funds associated with a stored balance of the merchant to a bank account of the merchant that is held at a bank or other financial institution (e.g., associated with the server(s) 5808). Scheduled deposits can occur at a prearranged time after a POS transaction is funded, which can be a business day after the POS transaction occurred, or sooner or later. In some examples, the merchant can access funds prior to a scheduled deposit (e.g., same-day deposits and/or real-time deposits). Further, in at least one example, the merchant can have a payment instrument that is linked to the stored balance that enables the merchant to access the funds without first transferring the funds from the account managed by the merchant platform 5810 to the bank account of the merchant.

In at least one example, the merchant platform 5810 may provide inventory management services. That is, the merchant platform 5810 may provide inventory tracking and reporting. Inventory management services may enable the merchant to access and manage a database storing data associated with a quantity of each item that the merchant has available (i.e., an inventory). Furthermore, in at least one example, the merchant platform 5810 can provide catalog management services to enable the merchant to maintain a catalog, which can be a database storing data associated with items that the merchant has available for acquisition (i.e., catalog management services). The merchant platform 5810 can offer recommendations related to pricing of the items, placement of items on the catalog, and multi-party fulfillment of the inventory, to name a few examples.

In at least one example, the merchant platform 5810 can provide business banking services, which allow the merchant to track deposits (from payment processing and/or other sources of funds) into an account of the merchant, payroll payments from the account (e.g., payments to employees of the merchant), payments to other merchants (e.g., business-to-business) directly from the account or from a linked debit card, withdrawals made via scheduled deposit and/or real-time deposit, configure allocations among multiple balances or accounts (e.g., spending, saving, taxes, etc.), etc. Furthermore, the business banking services can enable the merchant to obtain a customized payment instrument (e.g., credit card), check how much money the merchant is earning (e.g., via presentation of available earned balance), understand where the money of the merchant is going (e.g., via deposit reports (which can include a breakdown of fees), spend reports, etc.), access/use earned money (e.g., via scheduled deposit, real-time deposit, linked payment instrument, etc.), have improved control of the money of the merchant (e.g., via management of deposit schedule, deposit speed, linked instruments, etc.), etc. Moreover, the business banking services can enable the merchants to visualize their cash flow to track their financial health, set aside money for upcoming obligations (e.g., savings), organize money around goals, etc.

In at least one example, the merchant platform 5810 can provide financing services and products, such as via business loans, consumer loans, fixed term loans, flexible term loans, and the like. In at least one example, the service provider can utilize one or more risk signals to determine whether to extend financing offers and/or terms associated with such financing offers. Such risk signals can be particular to an individual platform or service, as described herein, or can be based on aggregated data associated with multiple of the platforms or services. In at least one example, the merchant platform 5810 can provide financing services for offering and/or lending a loan to a borrower that is to be used for, in some instances, financing the borrower's short-term operational needs (e.g., a capital loan). Additionally or alternatively, the merchant platform 5810 can provide financing services for offering and/or lending a loan to a borrower that is to be used for, in some instances, financing the borrower's consumer purchase (e.g., a consumer loan). In at least one example, a borrower can submit a request for a loan to enable the borrower to purchase an item from a merchant. The merchant platform 5810 can generate the loan based at least in part on determining that the borrower purchased or intends to purchase the item from the merchant. Advances, loans, or other funds provided to a merchant or other user can be repaid via a variety of mechanisms. In some examples, loans can be repaid in installments (e.g., multiple payments over time), at a particular date, from a portion of incoming funds (e.g., payments processed for the merchant, tax refunds, direct deposits, etc.), or the like.

The merchant platform 5810 can provide web-development services, which enable users 5816 who are unfamiliar with HTML, XML, Javascript, CSS, or other web design tools to create and maintain functional websites. Further, in addition to websites, the web-development services can create and maintain other online omni-channel presences, such as social media posts for example. In some examples, the resulting web page(s) and/or other content items can be used for offering item(s) for sale via an online/e-commerce platform. In at least one example, the merchant platform 5810 can recommend and/or generate content items to supplement omni-channel presences of the merchants.

Furthermore, the merchant platform 5810 can provide payroll services to enable employers to pay employees for work performed on behalf of employers. In at least one example, the merchant platform 5810 can receive data that includes time worked by an employee (e.g., through imported timecards and/or POS interactions), sales made by the employee, gratuities received by the employee, and so forth. Based on such data, the merchant platform 5810 can make payroll payments to employee(s) on behalf of an employer via the payroll service. For instance, the merchant platform 5810 can facilitate the transfer of a total amount to be paid out for the payroll of an employee from the bank of the employer to the bank of the merchant platform 5810 to be used to make payroll payments. In at least one example, when the funds have been received at the bank of the merchant platform 5810, the merchant platform 5810 can pay the employee, such as by check or direct deposit.

Moreover, in at least one example, the merchant platform 5810 can provide employee management services for managing schedules of employees. Further, the merchant platform 5810 can provide appointment services for enabling users 5816 to set schedules for scheduling appointments and/or users 5816 to schedule appointments.

In some examples, the merchant platform 5810 can provide restaurant management services to enable users 5816 to make and/or manage reservations, to monitor front-of-house and/or back-of-house operations, and so on. In such examples, the seller device(s) 5806(A) and/or server(s) 5802 can be configured to communicate with one or more other computing devices, which can be located in the front-of-house (e.g., POS device(s)) and/or back-of-house (e.g., kitchen display system(s) (KDS)). In at least one example, the merchant platform 5810 can provide order management services and/or fulfillment services to enable restaurants (or other merchant types) to manage open tickets, split tickets, and so on and/or manage fulfillment services.

In some examples, the merchant platform 5810 can provide omni-channel fulfillment services. A fulfillment service includes item ordering and delivery services, such as via a courier. In some examples, the courier can be an unmanned aerial vehicle (e.g., a drone), an autonomous vehicle, or any other type of vehicle capable of receiving instructions for traveling between locations. For instance, if a customer places an order with a merchant and the merchant cannot fulfill the order because one or more items are out of stock or otherwise unavailable, the merchant platform 5810 can leverage other merchants and/or sales channels that are part of the merchant platform 5810 to fulfill the customer's order. That is, another merchant can provide the one or more items to fulfill the order of the customer. Furthermore, in some examples, another sales channel (e.g., online, brick-and-mortar, etc.) can be used to fulfill the order of the customer.

In some examples, the merchant platform 5810 can enable conversational commerce via conversational commerce services, which can use one or more machine learning mechanisms to analyze messages exchanged between two or more users 5816, voice inputs into a virtual assistant or the like, to determine intents of user(s) 5816. In some examples, the merchant platform 5810 can utilize determined intents to automate customer service, offer promotions, provide recommendations, or otherwise interact with customers in real-time. In at least one example, the merchant platform 5810 can integrate products and services, and payment mechanisms into a communication platform (e.g., messaging, etc.) to enable customers to make purchases, or otherwise transact, without having to call, email, or visit a web page or other channel of a merchant. That is, conversational commerce alleviates the need for customers to toggle back and forth between conversations and web pages to gather information and make purchases.

In at least one example, a user 5816 may be new to the merchant platform 5810 such that the user 5816 that has not registered (e.g., subscribed to receive access to one or more services offered by the merchant platform 5810) with the merchant platform 5810. The merchant platform 5810 can offer onboarding services for registering a potential user 5816 with the merchant platform 5810. In some examples, onboarding can involve presenting various questions, prompts, and the like to a potential user 5816 to obtain information that can be used to generate a profile for the potential user 5816. In at least one example, the merchant platform 5810 can provide limited or short-term access to its services prior to, or during, onboarding (e.g., a user of a peer-to-peer payment service can transfer and/or receive funds prior to being fully onboarded, a merchant can process payments prior to being fully onboarded, a user of a music streaming service can listen to music having advertisement breaks prior to being fully onboarded, etc.). In response to full or partial completion of onboarding, any limited or short-term access to services of the merchant platform 5810 can be transitioned to more permissive (e.g., less limited) or longer-term access to such services.

The merchant platform 5810 can be associated with IDV services, which can be used by the merchant platform 5810 for compliance purposes and/or can be offered as a service, for instance to third-party service providers (e.g., associated with the server(s) 5808). That is, the merchant platform 5810 can offer IDV services to verify the identity of users 5816 seeking to use or using their services. Identity verification may involve requesting a customer (or potential customer) to provide information that is used by compliance departments to prove that the information is associated with an identity of a real person or entity (e.g., an artist). In at least one example, the merchant platform 5810 can perform services for determining whether identifying information provided by a user 5816 accurately identifies the customer (or potential customer).

Techniques described herein can be configured to operate in both real-time/online and offline modes. “Online” modes refer to modes when devices are capable of communicating with the merchant platform 5810 while offline mode refers to modes when devices are unable to communicate with the server(s) 5808 due to network connectivity issue, for example. In such examples, devices may operate in “offline” mode where at least some payment data is stored (e.g., on the seller device(s) 5806(A)) and/or the server(s) 5802 until connectivity is restored and the payment data can be transmitted to the server(s) 5802 and/or the server(s) 5808 for processing.

In at least one example, the merchant platform 5810 can be associated with a hub, such as an order hub, an inventory hub, a fulfillment hub and so on, which can enable integration with one or more additional service providers (e.g., associated with the additional server(s) 5808). In some examples, such additional service providers can offer additional or alternative services and the service provider can provide an interface or other computer-readable instructions to integrate functionality of the service provider into the one or more additional service providers.

Turning now to the P2P functionality provided by the environment 5800, the P2P platform 5812 can provide a peer-to-peer payment service that enables peer-to-peer payments between two or more of the users 5816. Two or more of the users 5816 may be considered “peers” in a peer-to-peer interaction, such as a payment. In at least one example, the P2P platform 5812 can communicate with instances of a payment application 5826 (or other access point) installed on end user devices 5806 configured for operation by the users 5816. In an example, an instance of the payment application 5826 executing on a first user device 5806(B) operated by a payor (e.g., one of the users 5816) can send a request to the P2P platform 5812 to transfer an asset (e.g., fiat currency, non-fiat currency, digital assets such as non-fungible tokens (NFTs), cryptocurrency, securities, gift cards, and/or related assets) from the payor to a payee (e.g., a different one of the users 5816) via a peer-to-peer payment. In some examples, assets associated with an account of the payor are transferred to an account of the payee. In some examples, assets can be held at least temporarily in an account of the P2P platform 5812 prior to transferring the assets to the account of the payee.

In some examples, the P2P platform 5812 can utilize a ledger system to track transfers of assets between users 5816. FIG. 59, below, provides additional details associated with such a ledger system. The ledger system can enable users 5816 to own fractional shares of assets that are not conventionally available. For instance, a user can own a fraction of a Bitcoin, an NFT, or a stock. Additional details are described herein.

In at least one example, the P2P platform 5812 can facilitate transfers and can send notifications related thereto to instances of the payment application 5826 executing on user device(s) of payee(s). As an example, the P2P platform 5812 can transfer assets from an account of a first user to an account of a second user and can send a notification to the user device 5806(B) of the second user for presentation via a user interface. The notification can indicate that a transfer is in process, a transfer is complete, or the like. In some examples, the P2P platform 5812 can send additional or alternative information to the instances of the payment application 5826 (e.g., low balance to the payor, current balance to the payor or the payee, etc.). In some examples, the payor and/or payee can be identified automatically, e.g., based on context, proximity, prior transaction history, and so on. In other examples, the payee can send a request for funds to the payor prior to the payor initiating the transfer of funds. In some embodiments, the P2P platform 5812 funds the request to payee on behalf of the payor, to speed up the transfer process and compensate for lags that may be attributed to the payor's financial network.

In some examples, the P2P platform 5812 can trigger the peer-to-peer payment process through identification of a “payment proxy” having a particular syntax. The payment proxy is useable in lieu of payment data. That is, payment data and a payment proxy can be linked to, or otherwise associated with, a user account of a user and either can be used for making payments. In an example, the syntax can include a monetary currency indicator prefixing one or more alphanumeric characters (e.g., $Cash). The currency indicator operates as the tagging mechanism that indicates to the server(s) 5802 to treat the inputs as a request from the payor to transfer assets, where detection of the syntax triggers a transfer of assets. The currency indicator can correspond to various currencies including but not limited to, dollar ($), euro (€), pound (£), rupee (ℑ), yuan (¥), etc. Although use of the dollar currency indicator ($) is used herein, it is to be understood that any currency symbol or other symbol could equally be used. In some examples, additional or alternative identifiers can be used to trigger the peer-to-peer payment process. For instance, email, telephone number, social media handles, artist or band names, and/or the like can be used to trigger and/or identify users of a peer-to-peer payment process.

In some examples, the peer-to-peer payment process can be initiated through instances of the payment application 5826 executing on the end user devices 5806. In at least some embodiments, the peer-to-peer process can be implemented within a landing page associated with a user and/or an identifier of a user. The term “landing page,” as used here, refers to a virtual location identified by a personalized location address that is dedicated to collect payments on behalf of a recipient associated with the personalized location address. The personalized location address that identifies the landing page can be a uniform resource locator (URL), which can include a payment proxy discussed above. The P2P platform 5812 can generate the landing page to enable the recipient to conveniently receive one or more payments from one or more senders.

In some examples, the peer-to-peer payment process can be implemented within a forum. The term “forum,” as used here, refers to a content provider's media channel (e.g., a social networking platform, a microblog, a blog, video sharing platform, a music sharing platform, etc.) that enables user interaction and engagement through streaming of content, comments, posts, messages on electronic bulletin boards, messages on a social networking platform, and/or any other types of messages. In some examples, the content provider can be the service provider as described with reference to FIG. 58 or a third-party service provider associated with the server(s) 5808. In examples where the content provider is a third-party service provider, the server(s) 5808 can be accessible via one or more APIs 5818 or other integrations. In some examples, “forum” may also refer to an application or webpage of an e-commerce or retail organization that offers products and/or services. Such websites can provide an online “form” to complete before or after the products or services are added to a virtual cart. Some of these fields may be configured to receive payment information, such as a payment proxy, in lieu of other kinds of payment mechanisms, such as credit cards, debit cards, prepaid cards, gift cards, virtual wallets, etc.

In some embodiments, the peer-to-peer process can be implemented within a communication application, such as a messaging application. The term “messaging application,” as used here, refers to any messaging application that enables communication between users (e.g., sender and recipient of a message) over a wired or wireless communications network, through use of a communication message. The messaging application can be internal to the P2P platform 5812 (e.g., the P2P platform 5812 offers a chat or messaging service that is within the payment application or accessible via the payment application). In some examples, the messaging application can be external to the P2P platform 5812. (e.g., the messaging application is hosted by a third-party service provider associated with the server(s) 5808, which can be accessible via one or more of the APIs 5818 or other integrations). The messaging application can include, for example, a text messaging application for communication between phones (e.g., conventional mobile telephones or smartphones), or a cross-platform instant messaging application for smartphones and phones that use the Internet for communication.

Funds received from payments can be stored in stored balances that are linked to, or otherwise associated with, user accounts. In some examples, the P2P platform 5812 can enable users 5816 to perform banking transactions via instances of the payment application 5826. For example, users can configure direct deposits, recurring deposits, or other deposits (e.g., tax refunds, loans, etc.) for adding assets to their various ledgers/balances. In some examples, users can deposit physical cash via ATMs or other deposit sources, which can include merchants, such as those merchants that utilize the payment processing system described above. In some examples, the P2P platform 5812 can enable users to allocate funds between different accounts, sub-accounts, or balances (e.g., spending, saving, different assets, different currencies), etc. Further, users 5816 can configure bill pay, recurring payments, and/or the like using assets associated with their accounts. In some examples, the P2P platform 5812, with consent of the user, can track individual transactions made using the payment application and can utilize such transaction data to make personalized or customized recommendations, determine creditworthiness, generate tax documentation, and/or the like.

In addition to sending and/or receiving assets via peer-to-peer transactions, the P2P platform 5812 enables users to buy and/or sell assets via asset networks such as cryptocurrency networks, securities networks, and/or the like. In some examples, acquisition of such assets can be in whole or fractional shares. The ledger system described below with reference to FIG. 59 can enable such assets to be acquired in fractional shares and/or in real-time or near real-time (by delaying or omitting the need to buy/sell assets via asset networks or exchanges). In some examples, users can “gift” assets to other users, for example, by transferring cryptocurrency, stocks, or the like to one another.

In some examples, the P2P platform 5812 can enable users to link payment instruments to their user accounts. As a result, users can use their linked payment instruments to access funds in their accounts or balances. In some examples, the payment instrument can be a credit card, debit card, card linked to multiple accounts or balances via software or hardware, a fob or other object having payment data stored thereon, or the like. In some examples, the payment instrument can be a virtual payment instrument or a physical payment instrument. In some examples, the virtual payment instrument can be issued in real-time or for temporary usage. In some examples, the virtual payment instrument can have the same or different payment data as a corresponding physical payment instrument. Payment instruments can be customizable using a design user interface of the payment application. Such customization can enable users to select colors, stamps, images, text, or the like for surface(s) of their payment instruments. In some examples, users can draw or otherwise interact with the design user interface to personalize surface(s) of their payment instruments.

In some examples, users can associate incentives with their payment instruments. Incentives can be recommended to users based on user preferences (inferred or explicitly identified), geolocation, propensity to redeem, value, and/or the like. In some examples, incentives can be particular to individual merchants, types of merchants, types of transactions, and/or the like. In at least one example, when a user uses their payment instrument at a merchant or type of merchant associated with an incentive, or for a transaction type associated with an incentive, the P2P platform 5812 can automatically apply the incentive to the transaction. In some examples, users can gift other users “gift cards” that can be associated with payment instruments. That is, a user can transfer an amount of funds to another user and such funds can be associated with a condition (e.g., merchant, merchant type, transaction type, location, etc.) that, upon satisfaction, enables the amount of funds, or a portion thereof, to be applied to a transaction. In at least one example, when a user uses their payment instrument for a transaction that satisfies the condition, the P2P platform 5812 can automatically apply the amount of funds associated with the gift card to the transaction.

In some examples, users can configure their account such that when they use their payment instruments, the P2P platform 5812 can deposit an amount of funds into a savings account, investing account, bitcoin account, or the like.

In some examples, users can search for or browse other users, merchants, items, or the like via the payment application. In some examples, search results can be personalized and/or customized for the user (e.g., based on user data collected with consent of the user). In some examples, users can shop or otherwise purchase items from other users, merchants, or the like from within the payment application or via a deep link to a merchant application or website.

The P2P platform 5812 can offer primary and secondary accounts, wherein a primary account is a sponsor or other delegate of one or more secondary accounts. Such accounts can be useful for families, wherein a parent or other guardian is a sponsor or delegate to one or more child accounts, or where a child is a sponsor or delegate of an elderly parent's account. In some examples, primary accounts can establish limits on secondary accounts, such as spending limits, or the like. In some examples, the primary account owner is the user legally responsible for the account and their identity may be verifiable for secondary user accounts to perform certain transactions, such as buying/selling cryptocurrency or stocks. In some examples, one or more primary accounts and one or more secondary accounts can form a “group” with shared goals, such as saving, investing, or the like.

The P2P platform 5812 can present activity data via an activity user interface of the payment application. In some examples, activity can be presented by merchant, date, time, amount, or the like. In some examples, interactions between entities can be represented in conversational communications such that each interaction or transaction is represented as a message. In some examples, users can interact with individual messages and/or send/request funds from within such a conversational communication. In some examples, such conversational communications can represent conversations of a group of two or more users. Groups can be used to pool funds, obtain group discounts or incentives, or enable multiple users to participate in financial transactions together (e.g., group investing, group savings, etc.).

The P2P platform 5812 can offer a variety of financial training or learning opportunities. In some examples, such training or learning can be personalized for individual users, for example, based on user data and/or transaction data of the user that is obtained with consent of the user. In some examples, such user data and/or transaction data can be analyzed to make actionable recommendations with respect to optimizing financial health of users of the P2P platform 5812.

In some examples, components of the environment 5800 may be integrated to enable payments at the point-of-sale using assets associated with user accounts of the P2P platform 5812. As illustrated in the environment 5800, the components can communicate with one another via the network 5804, where one or more APIs 5818 or other functional components can be used to facilitate such communication.

In at least one example, an integration can enable a customer to participate in a transaction via their own computing device (e.g., user device 5806(B)) instead of interacting with a merchant device of a merchant, such as the seller device 5806(A). In such an example, the POS application 5820, associated with a payment processing platform and executable by the seller device 5806(A) of the merchant, can present a Quick Response (QR) code, or other code that can be used to identify a transaction (e.g., a transaction code), in association with a transaction between the customer and the merchant. The QR code, or other transaction code, can be provided to the POS application 5820 via an API 5818 associated with the peer-to-peer payment platform. In an example, the customer can utilize their own computing device, such as the user device 5806(B), to capture the QR code, or the other transaction code, and to provide an indication of the captured QR code, or other transaction code, to server(s) 5802.

Based at least in part on the integration of the peer-to-peer payment platform and the payment processing platform (e.g., via the API 5818), the server(s) 5802 of the merchant platform 5810 can exchange communications with a payment application 5826 associated with the P2P platform 5812 and/or the POS application 5820 to process payment for the transaction using a peer-to-peer payment where the customer is a first “peer” and the merchant is a second “peer.”

Based at least in part on receiving an indication of which payment method a user (e.g., customer or merchant) intends to use for a transaction, techniques described herein utilize an integration between the P2P platform 5812 and merchant platform 5810 (which can be a first- or third-party integration) such that a QR code, or other transaction code, specific to the transaction can be used for providing transaction details, location details, customer details, or the like to a computing device of the customer, such as the user device 5806(B), to enable a contactless (peer-to-peer) payment for the transaction, and transferring funds from an account of the customer to an account of the merchant.

In at least one example, techniques described herein can offer improvements to conventional payment technologies at both brick-and-mortar points of sale and online points of sale. For example, at brick-and-mortar points of sale, techniques described herein can enable customers to “scan to pay,” by using their computing devices to scan QR codes, or other transaction codes, encoded with data as described herein, to remit payments for transactions. In such a “scan to pay” example, a customer computing device, such as the user device 5806(B), can be specially configured as a buyer-facing device that can enable the customer to view cart building in near real-time, interact with a transaction during cart building using the customer computing device, authorize payment via the customer computing device, apply coupons or other incentives via the customer computing device, add gratuity, loyalty information, feedback, or the like via the customer computing device, etc. In another example, merchants can “scan for payment” such that a customer can present a QR code, or other transaction code, that can be linked to a payment instrument or stored balance. Funds associated with the payment instrument or stored balance can be used for payment of a transaction.

As described above, techniques described herein can offer improvements to conventional payment technologies at online points of sale, as well as brick-and-mortar points of sale. For example, multiple applications can be used in combination during checkout. That is, the POS application 5820 and the payment application 5826, as described herein, can process a payment transaction by routing information input via the merchant application to the payment application for completing a “frictionless” payment.

Returning to the “scan to pay” examples described herein, QR codes, or other transaction codes, can be presented in association with a merchant web page or ecommerce web page. In at least one example, techniques described herein can enable customers to “scan to pay,” by using their computing devices to scan or otherwise capture QR codes, or other transaction codes, encoded with data, as described herein, to remit payments for online/ecommerce transactions. A customer computing device, such as the user device 5806(B), can be specially configured as a buyer-facing device having functionality similar to the functionality described above in the brick-and-mortar example.

In some examples, based at least in part on capturing the QR code, or other transaction code, the merchant platform 5810 can provide transaction data to the P2P platform 5812 for presentation via the payment application 5826 on the computing device of the customer, such as the user device 5806(B), to enable the customer to complete the transaction via their own computing device. In some examples, in response to receiving an indication that the QR code, or other transaction code, has been captured or otherwise interacted with via the customer computing device, the P2P platform 5812 can determine that the customer authorizes payment of the transaction using funds associated with a stored balance of the customer that is managed and/or maintained by the P2P platform 5812. Such authorization can be implicit such that the interaction with the transaction code can imply authorization of the customer. Alternatively or additionally, the P2P platform 5812 can request express authorization to process payment for the transaction using the funds associated with the stored balance and the customer can interact with the payment application to expressly authorize the settlement of the transaction. In some examples, such an authorization (implicit or express) can be provided prior to a transaction being complete and/or initialization of a conventional payment flow. That is, in some examples, such an authorization can be provided during cart building (e.g., adding item(s) to a virtual cart) and/or prior to payment selection. In some examples, such an authorization can be provided after payment is complete (e.g., via another payment instrument). Based at least in part on receiving an authorization to use funds associated with the stored balance (e.g., implicitly or explicitly) of the customer, the P2P platform 5812 can transfer funds from the stored balance of the customer to the merchant platform 5810. In at least one example, the merchant platform 5810 can deposit the funds, or a portion thereof, into a stored balance of the merchant that is managed and/or maintained by the merchant platform 5810. In such an example, the merchant platform 5810 can be a “peer” to the customer in a peer-to-peer transaction.

In some examples, techniques described herein can enable the customer to interact with the transaction after payment for the transaction has been settled. For example, in at least one example, the merchant platform 5810 can cause a total amount of a transaction to be presented via a user interface associated with the payment application 5826 such that the customer can provide gratuity, feedback, loyalty information, or the like, via an interaction with the user interface. In another example, the merchant platform 5810 can adjust a total amount of a transaction based on events during a shopping experience, such as adding or removing a charge to the total amount based on whether a media content item requested by the customer to be played during a shopping experience was in fact played. In some examples, because the customer has already authorized payment via the P2P platform 5812, if the customer inputs a tip and/or an event affecting the total amount of the transaction is triggered, the P2P platform 5812 can transfer additional funds, associated with the tip or event, to the merchant platform 5810. This pre-authorization (or maintained authorization) of sorts can enable faster, more efficient payment processing when the tip is received and/or the event initiates the trigger. Further, the customer can provide feedback and/or loyalty information via the user interface presented by the payment application, which can be associated with the transaction. Using the pre-authorization techniques described herein results in fewer data transmissions and thus, techniques described herein can conserve bandwidth and reduce network congestion. Moreover, as described above, funds associated with tips can be received faster and more efficiently than with conventional payment technologies.

In addition to the improvements described above, techniques described herein can provide enhanced security in payment processing. In some examples, if a camera, or other sensor, used to capture a QR code, or other transaction code, is integrated into a payment application 5826 (e.g., instead of a native camera, or other sensor), techniques described herein can utilize an indication of the QR code, or other transaction code, received from the payment application for two-factor authentication to enable more secure payments.

It should be noted that, while techniques described herein are directed to contactless payments using QR codes or other transaction codes, in additional or alternative examples, techniques described herein can be applicable for contact payments. That is, in some examples, a customer can swipe a payment instrument (e.g., a credit card, a debit card, or the like) via a reader device associated with a merchant device, dip a payment instrument into a reader device associated with a merchant computing device, tap a payment instrument with a reader device associated with a merchant computing device, or the like, to initiate the provisioning of transaction data to the customer computing device. In some examples, the payment instrument can be associated with the P2P platform 5812 as described herein (e.g., a debit card linked to a stored balance of a customer) such that when the payment instrument is caused to interact with a payment reader, the merchant platform 5810 can exchange communications with the P2P platform 5812 to authorize payment for a transaction and/or provision associated transaction data to a computing device of the customer associated with the transaction.

Turning now to media content functionality provided by the environment 5800, the media content platform 5814 can provide digital media to a content consumption device 5806(D) where playback may occur using “streaming.” In examples, “streaming” media content involves encoding the media content and transmitting the encoded media content over the network 5804 to a media player or a media application executing on a device (e.g., via a speaker). The device then decodes and plays the media content while data is being received. In some cases, a buffer queues some of the data of the media content (e.g., audio data, video data, etc.) ahead of the media being played. During moments of network congestion, which leads to lower available bandwidth, less media content data is added to the buffer, which drains down as media content is being dequeued during streaming playback. However, during moments of high network bandwidth, the buffer is replenished, adding media content data to the buffer.

In at least one example, the media content platform 5814 can provide a digital media streaming service (e.g., subscription-based, non-subscription-based) that enables a content consumption device 5806(D) to stream and/or download digital media content via a listener application 5828 installed on the content consumption device 5806(D). For instance, the media content platform 5814 may comprise a digital audio streaming service (e.g., for music, podcasts, audiobooks, etc.), a digital video streaming service, and/or a streaming service that provides streaming of various different types of digital media content or multimedia. In such cases where digital media content items are downloaded and stored locally on the content consumption devices 5806(D), the listener application 5828 may verify access rights to the digital media content items at time intervals, for instance intermittently (e.g., when the content consumption device 5806(D) has a network connection with the media content platform 5814 via the network(s) 5804), and/or at regular intervals (e.g., daily, weekly, monthly, etc.). In examples, access rights to the digital media content items may be provided when a subscription to the media content platform 5814 is active, while access rights to the digital media content items may be withheld when the subscription to the media content platform 5814 is terminated. Enabling storage on the end user devices 5806 and subsequent access to digital media content items via the listener application 5828 provides the users 5816 with the ability to access the digital media content items “offline” such as when a connection to the media content platform 5814 via the network(s) 5804 is unavailable or unreliable.

In some examples, the media content platform 5814 may additionally or alternatively provide an artist management service that enables the users 5816 to manage aspects of artist business via an artist application 5830 installed on the artist device 5806(E), such as data analytics and management (e.g., listener data, consumer data, etc.), marketing, regulatory obligations, cash flow management, publishing, customer relationship management (CRM), social media, event coordination, industry communications, digital media content ingestion and storage, and so forth. In some cases, the users 5816 can have graduated access to the services, which can be based on a user type (e.g., artist, group member, personal manager, business manager, attorney, agent, etc.), risk tolerance, artist verification status, listener and/or viewer analytics (e.g., number of streams in a month), and so on. In some cases, multiple users 5816 may have access to a single user account via respective end user devices 5806, with the various users having different access privileges to services provided by the artist management service. In various scenarios, an artist can designate functions provided by the artist management service to different members of the team associated with the artist, thus granting the respective team members access to services suited to the skills of the individual team members.

In some cases, the artist application 5830 and the listener application 5828 may be distinct applications having differing user experiences and verification processes for access, such as illustrated in the environment 5800. For instance, the media content platform 5814 may request additional verification, such as a link to an artist website, a sample of an artist's work, a verified credential supplied by a third party, etc. to grant access to the artist application 5830 in addition to information requested to access the listener application 5828. Further, the artist application 5830 may provide the artist management services described herein, without the subscription-based digital media streaming services described herein, and vice versa. However, examples are also considered in which functionality provided by the artist application 5830 and the listener application 5828 partially or fully overlap, and/or where verification processes for access are substantially similar.

In at least some examples, the media content platform 5814 enables interaction between the users 5816 utilizing the listener application 5828 installed on the content consumption devices 5806(D), and the users 5816 utilizing the artist application 5830 installed on the artist end user devices 5806(E). For example, the media content platform 5814 may provide interconnectivity between the subscription-based digital media streaming service and the artist management service. Functionality provided by the media content platform 5814 in such instances may include a communication channel between one or more of the users 5816 (e.g., a listener, fan, music supervisor, publisher, etc.) utilizing the listener application 5828 and another user (e.g., an artist) of the users 5816 utilizing the artist application 5830. The communication channel may include, for instance, a messaging platform (also referred to as a “messaging application” herein), a live streaming platform, a videoconferencing or teleconferencing platform, and/or a combination of these.

Additionally, in some cases, the media content platform 5814 may facilitate a resource transfer between the listener application 5828 and the artist application 5830. In an example, the media content platform 5814 may direct a resource, such as a portion of a subscription fee paid by one of the users 5816 designated as a listener, to one or more of the users 5816 designated as artists based on a number of instances that the listening user consumed (e.g., streamed, downloaded, etc.) content created by respective ones of the artist users. Alternatively or additionally, the media content platform 5814 may direct a resource, such as funds, from an account associated with a listening user to an account associated with an artist user (or vice versa), in accordance with transfers between accounts as described herein. The media content platform 5814 may facilitate resource transfers in examples such as merchandise purchases, event ticket purchases, “tipping” an artist, payments for royalties or other fees, and so forth.

In some examples, the media content platform 5814 enables interaction between individual ones of the users 5816 with one another via the listener application 5828 installed on the content consumption device 5806(D) and other of the content consumption devices 5806(D) via a communication channel as described above. In an example, the listener application 5828 may provide functionality via a communication channel for a user to stream an individual digital media item, a playlist, or the like to an audience comprising other ones of the content consumption devices 5806(D). Alternatively or additionally, the communication channel may facilitate sharing of individual digital media items, playlists, user and/or artist profiles, and the like between the users 5816 via messages, uniform resource locators (URLs), quick response (QR) codes, and so forth.

In some cases, the media content platform 5814 enables interaction between individual ones of the users 5816 with one another via the artist application 5830 installed on the artist device 5806(E) and other of the artist end user devices 5806 via a communication channel as described above. In some instances, the media content platform 5814 may provide recommendations for a particular user indicating which of the other users 5816 to communicate with. Such a recommendation may be based on a similarity (or dissimilarity) of content created by two or more of the users 5816, an overlap (or lack thereof) of audience members of the users 5816, a geographic location of the users 5816, a coinciding event location of the users 5816, and so forth. In some examples, a user may input parameters for a desired connection via the artist application 5830, and the media content platform 5814 may filter which of the users 5816 to surface for recommendations to the user based on the input parameters. Alternatively or additionally, the media content platform 5814 may implement one or more machine learning models to filter which of the users 5816 to surface for recommendations to the user. The recommendations provided by the media content platform 5814 may be data driven and thus increase relevance of communications presented to the users 5816 and reduce unsolicited communications that may be received by the users 5816.

The media content platform 5814 may interact with the server(s) 5808 associated with the third-party service providers to, for instance, ingest digital media items, report digital media consumption data, pay royalties, and the like. In some examples, the server(s) 5808 may be accessible by the media content platform 5814 via one or more APIs 5818 or other integrations. In some cases, the third-party service provider may be a digital media content provider (e.g., a record label, a performance rights organization (PRO), an independent artist, etc.). In such cases, the media content platform 5814 may receive digital media content items from the server(s) 5808, along with metadata associated with the digital media content items. The metadata, in some instances, may indicate individual contributors to a digital media content item such as an artist or artists, a songwriter (e.g., a composer, lyricist, author, etc.), a producer (which may further include a co-producer, a mastering engineer, a mixing engineer, a recording engineer, an arranger, a programmer, etc.), a musician (e.g., instrumentalist, vocalist, etc.), a visual artist, and so forth, with an indication of the role of the individual contributor. Alternatively or additionally, the metadata may indicate information such as release date, track title, track duration, clean or explicit version, jurisdiction information, and the like. The media content platform 5814 may use the metadata to associate the digital media content item as being created by a particular user, to provide search results to the users 5816, to generate playlists, and so forth. Further, the media content platform 5814 may provide payments (e.g., royalties) to the third-party service provider based on a number of streams and/or downloads of individual digital media content items by the users 5816 via the listener application 5828.

Techniques described herein are directed to services provided via a distributed system of end user devices 5806 that are in communication with server(s) 5802 of the service provider. That is, techniques described herein are directed to a specific implementation—or, a practical application—of utilizing a distributed system of end user devices 5806 that are in communication with server(s) 5802 of the merchant platform 5810, the P2P platform 5812, and/or the media content platform 5814 to perform a variety of services, as described above. The unconventional configuration of the distributed system described herein enables the server(s) 5802 that are remotely-located from end-users (e.g., users 5816) to intelligently offer services based on aggregated data associated with the end-users, such as the users 5816 (e.g., data associated with multiple, different merchants and/or multiple, different buyers; data associated with multiple different listeners and/or multiple different artists, etc.), in some examples, in near-real time. Accordingly, techniques described herein are directed to a particular arrangement of elements that offer technical improvements over conventional techniques for performing payment processing services, P2P payment services, media content services, and the like. For small business owners and artists in particular, the business environment is typically fragmented and relies on unrelated tools and programs, making it difficult for an owner or an artist to manually consolidate and view such data. The techniques described herein constantly or periodically monitor disparate and distinct user accounts, e.g., accounts within the control of the merchant platform 5810, the P2P platform 5812, and/or the media content platform 5814, and those outside of the control of these service providers, to track the standing (payables, receivables, payroll, invoices, appointments, capital, balances, collaborations, etc.) of the users 5816. The techniques herein provide a consolidated view of a user's cash flow, predict needs, preemptively offer recommendations or services, such as capital, coupons, etc., and/or enable money movement between disparate accounts (merchant's, another merchant's, or even payment service's) in a frictionless and transparent manner.

As described herein, artificial intelligence, machine learning, and the like can be used to dynamically make determinations, recommendations, and the like, thereby adding intelligence and context-awareness to an otherwise one-size-fits-all scheme for providing payment processing services, P2P payment services, media content services, and/or additional or alternative services described herein. In some implementations, the distributed system is capable of applying the intelligence derived from an existing user base to a new user, thereby making the onboarding experience for the new user personalized and frictionless when compared to traditional onboarding methods. Further, models or algorithms that are used to implement techniques described herein may be retrained over time to improve outcomes for subsequent scenarios based on outcomes of previous scenarios. Thus, techniques described herein improve existing technological processes.

As described above, various graphical user interfaces (GUIs) can be presented to facilitate techniques described herein. Some of the techniques described herein are directed to user interface features presented via GUIs to improve interaction between users 5816 and end user devices 5806. Furthermore, such features are changed dynamically based on the profiles of the users involved interacting with the GUIs. As such, techniques described herein are directed to improvements to computing systems.

The merchant platform 5810, the P2P platform 5812, and/or the media content platform 5814 are capable of providing additional or alternative services, and the services described above are offered as a sampling of services. In at least one example, the merchant platform 5810, the P2P platform 5812, and/or the media content platform 5814 can exchange data with the server(s) 5808 associated with third-party service providers. Such third-party service providers can provide information that enables the merchant platform 5810, the P2P platform 5812, and/or the media content platform 5814 to provide services, such as those described above. In additional or alternative examples, such third-party service providers can access services of the merchant platform 5810, the P2P platform 5812, and/or the media content platform 5814. That is, in some examples, the third-party service providers can be subscribers, or otherwise access, services of the merchant platform 5810, the P2P platform 5812, and/or the media content platform 5814.

FIG. 59 illustrates an example environment 5900 including a service provider system 5902 which may be associated with the server(s) 5802 of FIG. 58. The environment 5900 may also include a user device 5904, which may correspond to any of the end user devices 5806 described in relation to FIG. 58. In examples, the service provider system 5902 may include one or a combination of the merchant platform 5810, the P2P platform 5812, or the media content platform 5814, as well as one or more data store(s) 5906 that can store assets in an asset storage 5908, as well as data in user account(s) 5910. In some examples, the environment 5900 may also include a public blockchain 5914, one or more nodes 5916, and/or a hardware wallet 5918. The service provider system 5902, the user device 5904, public blockchain 5914, the node(s) 5916, and the hardware wallet 5918 may be connected and able to communicate via one or more networks 5920, which may have the same or similar functionality described in relation to the network 5804 of FIG. 58.

In some examples, user account(s) 5910 can include merchant account(s), customer account(s), media content subscriber account(s), artist account(s), and so forth. In at least one example, the asset storage 5908 can be used to record whether individual assets are registered to a user account 5910. For example, the asset storage 5908 can include asset wallet(s) 5922 for storing records of assets owned by the service provider system 5902, such as cryptocurrency, securities, NFTs, or the like, and communicating with one or more asset networks, such as cryptocurrency networks, NFT networks, securities networks, or the like. In some examples, the asset network can be a first-party network or a third-party network, such as a cryptocurrency exchange or the stock market. In examples where the asset network is a third-party network, the server(s) 5808 of FIG. 58 can be associated therewith.

The asset wallet 5922 can be associated with one or more addresses and can vary addresses used to acquire assets (e.g., from the asset network(s)) so that its holdings are represented under a variety of addresses on the asset network. In examples where the service provider system 5902 has holdings of cryptocurrency (e.g., in the asset wallet 5922), a user can acquire cryptocurrency directly from the service provider system 5902. In some examples, the service provider system 5902 can include logic for buying and selling cryptocurrency to maintain a desired level of cryptocurrency. In some examples, the desired level can be based on a volume of transactions over a period of time, balances of collective cryptocurrency ledgers, exchange rates, or trends in changing of exchange rates such that the cryptocurrency is trending towards gaining or losing value with respect to the fiat currency. In some scenarios, the buying and selling of cryptocurrency, and therefore the associated updating of the public ledger of an asset network can be separate from a customer-merchant transaction or a peer-to-peer transaction, and therefore not necessarily time-sensitive. This can enable batching transactions to reduce computational resources and/or costs. The service provider system 5902 can provide the same or similar functionality for securities or other assets.

The asset storage 5908 may contain ledgers that store records of assignments of assets to users 5816. Specifically, the asset storage 5908 may include asset ledger 5924, fiat currency ledger 5926, and/or other ledger(s) 5928, which can be used to record transfers of assets between users 5816 and/or one or more third-parties (e.g., merchant network(s), payment card network(s), ACH network(s), equities network(s), the asset network, securities networks, etc.). In doing so, the asset storage 5908 can maintain a running balance of assets managed by the service provider system 5902. The ledger(s) of the asset storage 5908 can further indicate some of the running balance for individual ledger(s) stored in the asset storage 5908 are assigned or registered to one or more user account(s) 5910.

In at least one example, the asset storage 5908 can include transaction logs 5930, which can include, as transaction data, records of past transactions involving the service provider system 5902 and/or the user account 5910. In some examples, the data store(s) 5906 can store a private blockchain 5932. A private blockchain 5932 can function to record sender addresses, recipient addresses, public keys, values of cryptocurrency transferred, and/or can be used to verify ownership of cryptocurrency tokens to be transferred. In some examples, the service provider system 5902 can record transactions involving cryptocurrency until the number of transactions has exceeded a determined limit (e.g., number of transactions, storage space allocation, etc.). Based at least in part on determining that the limit has been reached, the service provider system 5902 can publish the transactions in the private blockchain 5932 to the public blockchain 5914 (e.g., associated with the asset network), where miners can verify the transactions and record the transactions to blocks on the public blockchain 5914. In at least one example, the service provider system 5902 can participate as miner(s) at least for transactions to which the respective platform is a party to, to be posted to the public blockchain 5914.

In some cases, the data store(s) 5906 can store and/or manage multiple user accounts, an example of which is described in relation to the user account 5910. In at least one example, the user account 5910 can include user account data 5934, which can include, but is not limited to, data associated with user identifying information (e.g., name, phone number, address, artist or band name, verified credentials, etc.), user identifier(s) (e.g., alphanumeric identifiers, etc.), user preferences (e.g., learned or user-specified), purchase history data (e.g., identifying one or more items purchased (and respective item information), subscription tier information, etc.), linked payment sources (e.g., bank account(s), stored balance(s), etc.), payment instruments used to purchase one or more items, returns associated with one or more orders, statuses of one or more orders (e.g., preparing, packaging, in transit, delivered, etc.), etc.), appointments data (e.g., previous appointments, upcoming (scheduled) appointments, timing of appointments, lengths of appointments, etc.), payroll data (e.g., employers, payroll frequency, payroll amounts, etc.), reservations data (e.g., previous reservations, upcoming (scheduled) reservations, reservation duration, interactions associated with such reservations, etc.), inventory data, user service data, loyalty data (e.g., loyalty account numbers, rewards redeemed, rewards available, etc.), risk indicator(s) (e.g., level(s) of risk), etc.

In at least one example, the user account data 5934 can include account activity 5936 and user wallet key(s) 5938. In some examples, the user wallet key(s) 5938 can include a public-private key-pair and a respective address associated with the asset network or other asset networks. In some examples, the user wallet key(s) 5938 may include one or more key pairs, which can be unique to the asset network or other asset networks.

In addition to the user account data 5934, the user account 5910 can include ledger(s) for account(s) managed by the service provider system 5902, for the user. For example, the user account 5910 may include an asset ledger 5924, a fiat currency ledger 5926, and/or one or more other ledgers 5928. The ledger(s) can indicate that a corresponding user utilizes the service provider system 5902 to manage corresponding accounts (e.g., a cryptocurrency account, a securities account, a fiat currency account, an artist account, etc.). It should be noted that in some examples, the ledger(s) can be logical ledger(s) and the data can be represented in a single database. In some examples, individual ones of the ledger(s), or portions thereof, can be maintained by the service provider system 5902.

In some examples, the asset ledger 5924 can store a balance for each of one or more cryptocurrencies (e.g., Bitcoin, Ethereum, Litecoin, etc.) registered to the user account 5910. In at least one example, the asset ledger 5924 can further record transactions of cryptocurrency assets associated with the user account 5910. For example, the user account 5910 can receive cryptocurrency from the asset network using the user wallet key(s) 5938. In some examples, the user wallet key(s) 5938 may be generated for the user upon request. User wallet key(s) 5938 can be requested by the user in order to send, exchange, or otherwise control the balance of cryptocurrency held by the service provider system 5902 (e.g., in the asset wallet 5922) and registered to the user. In some examples, the user wallet key(s) 5938 may not be generated until a user account requires such. This on-the-fly wallet key generation provides enhanced security features for users, reducing the number of access points to a user account's balance and, therefore, limiting exposure to external threats.

Each account ledger can reflect a positive balance when funds are added to the corresponding account. An account can be funded by transferring currency in the form associated with the account from an external account (e.g., transferring a value of cryptocurrency to the service provider system 5902 and the value is credited as a balance in asset ledger 5924), by purchasing currency in the form associated with the account using currency in a different form (e.g., buying a value of cryptocurrency from the service provider system 5902 using a value of fiat currency reflected in fiat currency ledger 12391226, and crediting the value of cryptocurrency in asset ledger 5924), or by conducting a transaction with another user (customer or merchant) of the service provider system 5902 wherein the account receives incoming currency (which can be in the form associated with the account or a different form, in which the incoming currency may be converted to the form associated with the account).

With specific reference to funding a cryptocurrency account, a user may have a balance of cryptocurrency stored in another cryptocurrency wallet. In some examples, the other cryptocurrency wallet can be associated with a third-party unrelated to the service provider system 5902 (i.e., an external account). Such a transaction can request that the user to transfer an amount of the cryptocurrency in a message signed by user's private key to an address provided by the service provider system 5902. In at least one example, the transaction can be sent to miners to bundle the transaction into a block of transactions and to verify the authenticity of the transactions in the block. Once a miner has verified the block, the block is written to the public blockchain 5914 where the service provider system 5902 can then verify that the transaction has been confirmed and can credit the user's asset ledger 5924 with the transferred amount. When an account is funded by transferring cryptocurrency from a third-party cryptocurrency wallet, an update can be made to the public blockchain 5914. In some cases, this update of the public blockchain 5914 need not take place at a time-critical moment, such as when a transaction is being processed by a merchant in store or online.

In some examples, a user can purchase cryptocurrency to fund their cryptocurrency account. In some examples, the user can purchase cryptocurrency through services offered by the service provider system 5902. As described above, in some examples, the service provider system 5902 can acquire cryptocurrency from a third-party source. In examples where the service provider system 5902 has its own cryptocurrency assets, cryptocurrency transferred in a transaction (e.g., data with address provided for receipt of transaction and a balance of cryptocurrency transferred in the transaction) can be stored in an asset wallet 5922 associated with the service provider system 5902. In at least one example, the service provider system 5902 can credit the asset ledger 5924 of the user. Additionally, while the service provider system 5902 recognizes that the user retains the value of the transferred cryptocurrency through crediting the asset ledger 5924, an inspection of the blockchain will show the cryptocurrency as having been transferred to the service provider system 5902. In some examples, the asset wallet 5922 can be associated with many different addresses. In such examples, an inspection of the blockchain may not necessarily associate all cryptocurrency stored in asset wallet 5922 as belonging to the same entity. The presence of a private ledger used for real-time transactions and maintained by the service provider system 5902, combined with updates to the public ledger at other times, allows for extremely fast transactions using cryptocurrency to be achieved. In some examples, the “private ledger” can refer to the asset ledger 5924, which in some examples, can utilize the private blockchain 5932, as described herein. The “public ledger” can correspond to the public blockchain 5914 associated with the asset network.

In at least one example, an asset ledger 5924, fiat currency ledger 5926, or the like associated with the user account 5910 can be credited when conducting a transaction with another user (customer or merchant) wherein the user receives incoming currency. In some examples, a user can receive cryptocurrency in the form of payment for a transaction with another user. In at least one example, such cryptocurrency can be used to fund the asset ledger 5924. In some examples, a user can receive fiat currency or another currency in the form of payment for a transaction with another user. In at least one example, at least a portion of such funds can be converted into cryptocurrency by the service provider system 5902 and used to fund the asset ledger 5924 of the user.

In examples, a user can also have an account in U.S. dollars, which can be tracked, for example, via the fiat currency ledger 5926. Such an account can be funded by transferring money from a bank account at a third-party bank to an account maintained by the service provider system 5902 as is conventionally known. In some examples, a user can receive fiat currency in the form of payment for a transaction with another user. In such examples, at least a portion of such funds can be used to fund the fiat currency ledger 5926.

In some examples, a user can have one or more internal payment cards registered with the service provider system 5902. Internal payment cards can be linked to one or more of the accounts associated with the user account 5910. In some embodiments, options with respect to internal payment cards can be adjusted and managed using an application (e.g., the payment application 5826, a wallet application 5912, etc.).

In at least one example, the user account 5910 can be associated with the asset wallet accessible via a wallet application 5912 of the user device 5904, or a stored balance for use in payment transactions, peer-to-peer transactions, payroll payments, etc. In at least one example, the asset wallet 5922 can store data indicating an address provided for receipt of a cryptocurrency transaction. In at least one example, the balance of the asset wallet 5922 can be based at least in part on a balance of the asset ledger 5924. In at least one example, funds availed via the asset wallet 5922 can be stored in the asset wallet 5922. Funds availed via the asset wallet 5922 can be tracked via the asset ledger 5924. The asset wallet 5922, however, can be associated with additional cryptocurrency funds.

In at least one example, when the service provider system 5902 includes a private blockchain 5932 for recording and validating cryptocurrency transactions, the asset wallet 5922 can be used instead of, or in addition to, the asset ledger 5924. For example, a merchant can provide the address of the asset wallet 5922 for receiving payments. In an example where a customer is paying in cryptocurrency and the customer has their own cryptocurrency wallet account associated with the service provider system 5902, the customer can send a message signed by its private key including its wallet address (i.e., of the customer) and identifying the cryptocurrency and value to be transferred to the merchant's asset wallet 5922. The service provider system 5902 can complete the transaction by reducing the cryptocurrency balance in the customer's cryptocurrency wallet and increasing the cryptocurrency balance in the merchant's asset wallet 5922. In addition to recording the transaction in the respective cryptocurrency wallets, the transaction can be recorded in the private blockchain 5932 and the transaction can be confirmed. A user can perform a similar transaction with cryptocurrency in a peer-to-peer transaction as described above.

While the asset ledger 5924 and/or asset wallet 5922 are each described above with reference to cryptocurrency, the asset ledger 5924 and/or asset wallet 5922 can alternatively be used in association with securities. In some examples, different ledgers and/or wallets can be used for different types of assets. That is, in some examples, a user can have multiple asset ledgers and/or asset wallets for tracking cryptocurrency, securities, or the like.

It should be noted that user(s) having accounts managed by the service provider system 5902 is an aspect of the technology disclosed that enables technical advantages of increased processing speed and improved security.

The description of the environment 5900 above generally relates to a centralized service provider system 5902 that at least partially facilitates storing and managing assets in the data store 5906. However, the environment 5900 may also facilitate decentralized storage and management of assets alternatively or in addition to centralized storage and management as described above. For instance, the environment 5900 may include a decentralized platform implemented using a plurality of nodes (e.g., web nodes), an example of which is illustrated as node 5916. The node 5916 is representative of a computer or other device tasked with validating transactions and/or maintaining a copy of a blockchain ledger, such as a ledger associated with the public blockchain 5914. The decentralized platform may be implemented via the environment 5900 through use of decentralized identifiers and verifiable credentials that are stored and managed by user devices 5904. A decentralized identifier is configured as a self-owned identifier that supports decentralized authentication and routing. A self-owned identifier in a blockchain network is a unique identifier that is owned and controlled by an individual entity on the blockchain, as contrasted with an entity controlled by a centralized authority (e.g., the service provider system 5902). The decentralized identity referenced by a decentralized identifier gives an entity control over what data can be accessed, stored, modified, and so forth by other entities, such as the service provider system 5902.

The node 5916, as representative of one of a plurality of decentralized nodes (e.g., decentralized web nodes), supports data storage and relays that allows entities, service provider systems, individuals, organizations and so forth to send, store, and receive encrypted or public messages and data. The node 5916 is universally addressable and is “crawlable” using data addressing in relation to the decentralized identifiers. The node 5916 is also configured to support decentralized replication of data across the nodes that is consistent across multiple nodes over time through continued data communication between the nodes in the decentralized platform. The node 5916 is configurable to support secure encryption through use of a cryptographic key associated with an individual's decentralized identifier and support semantic discovery to discover different forms of published data.

Verifiable credentials are an open standard for digital credentials, and employ a data format for cryptographic presentation and verification of claims. A verifiable credential represents an indication of trust of a piece of information related to an entity. For example, a verifiable credential indicates that the issuer of the verifiable credential trusts the holder of the verifiable credential; the holder trusts a verifier of the verifiable credential; and that the verifier trusts the issuer. Verifiable credentials may be issued by anyone, about anything, and can be presented to and verified by everyone granted access to the verifiable credential. Accordingly, a user of the user device 5904 may be an issuer, a holder, and/or a verifier, as can the service provider system 5902.

In some examples, the user device 5904 may implement a wallet application 5912 configured to manage decentralized identifiers and/or verifiable credentials. For instance, the wallet application 5912 may provide a user interface for implementation of access controls to various data associated with the decentralized identifier by the service provider system 5902, to other user devices, and so forth. Additionally, the wallet application 5912 may be configured to provide functionality for resource transfers (e.g., cryptocurrency, fiat currency, etc.) with the service provider system 5902, other user devices, and the like, based on techniques described herein.

In some examples, the hardware wallet 5918 may store cryptocurrency assets in combination with the wallet application 5912 and the service provider system 5902. For instance, the hardware wallet 5918, the wallet application 5912, and the service provider system 5902 may each store a respective, different private key, where a transaction with the cryptocurrency assets is signed by at least two of the three private keys. The user interface provided by the wallet application 5912 may allow a user to request a transaction. The wallet application 5912 may then sign the transaction with the private key of the wallet application 5912, have either the hardware wallet 5918 or the service provider system 5902 use a second of the three private keys to sign the transaction, and then provide the transaction with two signatures to the public blockchain 5914 for processing.

FIG. 60 depicts an illustrative block diagram illustrating a system 6000 for performing techniques described herein. The system 6000 includes a user device 6002, that communicates with server computing device(s) (e.g., server(s) 6004) via network(s) 6006 (e.g., the Internet, cable network(s), cellular network(s), cloud network(s), wireless network(s) (e.g., Wi-Fi) and wired network(s), as well as close-range communications such as Bluetooth®, Bluetooth® low energy (BLE), and the like). While a single user device 6002 is illustrated, in additional or alternate examples, the system 6000 can have multiple user devices, as described above with reference to FIG. 58.

In some examples, the client device 6002 and/or the server 6004 can include, and/or be examples of, the any mining system or set of mining systems of any of FIGS. 1-46, the mining system that performs the process 5400, the mining system that performs the process 5700, or a combination thereof. The user interface 6020 can be an example of any of the user interfaces of any of FIGS. 1-46, or vice versa.

In at least one example, the user device 6002 can be any suitable type of computing device, e.g., portable, semi-portable, semi-stationary, or stationary. Some examples of the user device 6002 can include, but are not limited to, a tablet computing device, a smart phone or mobile communication device, a laptop, a netbook or other portable computer or semi-portable computer, a desktop computing device, a terminal computing device or other semi-stationary or stationary computing device, a dedicated device, a wearable computing device or other body-mounted computing device, an augmented reality device, a virtual reality device, a speaker device, an automobile or other vehicle type, an Internet of Things (IoT) device, etc. That is, the user device 6002 can be any computing device capable of sending communications and performing the functions according to the techniques described herein. The user device 6002 can include devices, e.g., payment card readers, or components capable of accepting payments, as described below. The user device 6002 may be representative of, and provide functionality for, the user devices 5806 described in relation to FIG. 58.

In the illustrated example, the user device 6002 includes one or more processors 6008, one or more computer-readable media 6010, one or more communication interface(s) 6012, one or more input/output (I/O) devices 6014, a display 6016, sensor(s) 6018, one or more encoders 6046, and one or more decoders 6048.

In at least one example, each processor 6008 can itself comprise one or more processors or processing cores. For example, the processor(s) 6008 can be implemented as one or more microprocessors, microcomputers, microcontrollers, digital signal processors, central processing units, state machines, logic circuitries, and/or any devices that manipulate signals based on operational instructions. In some examples, the processor(s) 6008 can be one or more hardware processors and/or logic circuits of any suitable type specifically programmed or configured to execute the algorithms and processes described herein. The processor(s) 6008 can be configured to fetch and execute computer-readable processor-executable instructions stored in the computer-readable media 6010.

Depending on the configuration of the user device 6002, the computer-readable media 6010 can be an example of tangible non-transitory computer storage media and can include volatile and nonvolatile memory and/or removable and non-removable media implemented in any type of technology for storage of information such as computer-readable processor-executable instructions, data structures, program components or other data. The computer-readable media 6010 can include, but is not limited to, RAM, ROM, EEPROM, flash memory, solid-state storage, magnetic disk storage, optical storage, and/or other computer-readable media technology. Further, in some examples, the user device 6002 can access external storage, such as RAID storage systems, storage arrays, network attached storage, storage area networks, cloud storage, or any other medium that can be used to store information and that can be accessed by the processor(s) 6008 directly or through another computing device or network. Accordingly, the computer-readable media 6010 can be computer storage media able to store instructions, components or components that can be executed by the processor(s) 6008. Further, when mentioned, non-transitory computer-readable media exclude media such as energy, carrier signals, electromagnetic waves, and signals per se.

The computer-readable media 6010 can be used to store and maintain any number of functional components that are executable by the processor(s) 6008. In some implementations, these functional components comprise instructions or programs that are executable by the processor(s) 6008 and that, when executed, implement operational logic for performing the actions and services attributed above to the user device 6002. Functional components stored in the computer-readable media 6010 can include a user interface 6020 to enable users to interact with the user device 6002, and thus the server(s) 6004 and/or other networked devices. In some examples, the user interface 6020 can include a UI associated with a mining application used to perform, control, and/or monitor the mining operations disclosed herein, as performed using the mining ASIC(s) of the hashboard(s) disclosed herein. In at least one example, a user can interact with the user interface via touch input, spoken input, gesture, or any other type of input. The word “input” is also used to describe “contextual” input that may not be directly provided by the user via the user interface 6020. For example, user's interactions with the user interface 6020 are analyzed using, e.g., natural language processing techniques, user movement tracking techniques, eye tracking techniques, etc. to determine context or intent of the user, which may be treated in a manner similar to “direct” user input.

Depending on the type of the user device 6002, the computer-readable media 6010 can also optionally include other functional components and data, such as other components and data 6022, which can include programs, drivers, etc., and the data used or generated by the functional components. In addition, the computer-readable media 6010 can also store data, data structures and the like, that are used by the functional components. Further, the user device 6002 can include many other logical, programmatic and physical components, of which those described are merely examples that are related to the discussion herein.

In at least one example, the computer-readable media 6010 can include additional functional components, such as an operating system 6024 for controlling and managing various functions of the user device 6002 and for enabling user interactions.

The communication interface(s) 6012 can include one or more interfaces and hardware components for enabling communication with various other devices, such as over the network(s) 6006 or directly. For example, communication interface(s) 6012 can enable communication through one or more network(s) 6006, which can include, but are not limited any type of network known in the art, such as a local area network or a wide area network, such as the Internet, and can include a wireless network, such as a cellular network, a cloud network, a local wireless network, such as Wi-Fi and/or close-range wireless communications, such as Bluetooth®, BLE, NFC, RFID, a wired network, or any other such network, or any combination thereof. Accordingly, network(s) 6006 can include both wired and/or wireless communication technologies, including Bluetooth®, BLE, Wi-Fi and cellular communication technologies, as well as wired or fiber optic technologies. Components used for such communications can depend at least in part upon the type of network, the environment selected, or both. Protocols for communicating over such networks are well known and will not be disclosed herein in detail.

Embodiments of the disclosure may be provided to users through a cloud computing infrastructure. Cloud computing refers to the provision of scalable computing resources as a service over a network, to enable convenient, on-demand network access to a shared pool of configurable computing resources that can be rapidly provisioned and released with minimal management effort or service provider interaction. Thus, cloud computing allows a user to access virtual computing resources (e.g., storage, data, applications, and even complete virtualized computing systems) in “the cloud,” without regard for the underlying physical systems (or locations of those systems) used to provide the computing resources.

The user device 6002 can further include one or more input/output (I/O) devices 6014. The I/O devices 6014 can include speakers, a microphone, a camera, and various user controls (e.g., buttons, a joystick, a keyboard, a keypad, etc.), a haptic output device, and so forth. The I/O devices 6014 can also include attachments that leverage the accessories (audio-jack, USB-C, Bluetooth, etc.) to connect with the user device 6002.

In at least one example, user device 6002 can include a display 6016. Depending on the type of computing device(s) used as the user device 6002, the display 6016 can employ any suitable display technology. For example, the display 6016 can be a liquid crystal display, a plasma display, a light emitting diode display, an OLED (organic light-emitting diode) display, an electronic paper display, or any other suitable type of display able to present digital content thereon. In at least one example, the display 6016 can be an augmented reality display, a virtual reality display, or any other display able to present and/or project digital content. In some examples, the display 6016 can have a touch sensor associated with the display 6016 to provide a touchscreen display configured to receive touch inputs for enabling interaction with a graphic interface presented on the display 6016. Accordingly, implementations herein are not limited to any particular display technology. In some examples, the user device 6002 may not include the display 6016, and information can be presented by other means, such as aurally, haptically, etc.

In addition, the user device 6002 can include sensor(s) 6018. The sensor(s) 6018 can include a global positioning system (“GPS”) device able to indicate location information. Further, the sensor(s) 6018 can include, but are not limited to, an accelerometer, gyroscope, compass, proximity sensor, camera, microphone, and/or a switch.

In some examples, the GPS device can be used to identify a location of a user. In at least one example, the location of the user can be used by the merchant platform 5810, the P2P platform 5812, and/or the media content platform 5814, described above, to provide one or more services. That is, in some examples, the service provider can implement geofencing to provide particular services to users by the merchant platform 5810, the P2P platform 5812, and/or the media content platform 5814.

In examples, the user device 6002 includes a codec system, which may comprise an encoder 6046 and/or a decoder 6048. The encoder 6046 is configured to encode a data stream or signal from an analog signal (e.g., an analog audio signal, an analog video signal, etc.) to a digital signal for transmission or storage. The decoder 6048 is configured to convert the digital signal back to an analog signal, such as for playback or editing. In some cases, the encoder 6046 may be configured to encode the data stream or analog signal in an encrypted format, and the decoder 6048 may accordingly be configured to decrypt the digital signal as part of the decoding process (e.g., using a cryptographic key). Additionally, in some examples, the encoder 6046 may compress data to reduce transmission bandwidth and/or storage space for the digital signal. One example of a compression codec system is a lossless codec, in which the digital data stream is a compressed format of the original data stream, but retains the information present in the original data stream. Another example of a compression codec system is a lossy codec which reduces the quality of the digital data stream but can increase the compression of the data stream relative to lossless codec systems. The codec system comprising the encoder 6046 and/or the decoder 6048 may be specialized to accomplish various different objectives, such as to preserve motion, preserve color, minimize latency, maintain fidelity, minimize bit-rate, optimize for different output device types, maintain synchronization of audio and video (e.g., using a metadata synchronization data stream), and so on. Although not explicitly illustrated in the example system 6000, the server 6004 may include an encoder 6046 and/or a decoder 6048 as well.

Additionally, the user device 6002 can include various other components that are not shown, examples of which include removable storage, a power source, such as a battery and power control unit, a barcode scanner, a printer, a cash drawer, and so forth.

In addition, as described in relation to FIG. 58, the user device 6002 can include, be connectable to, or otherwise be coupled to a reader device 6026, for reading payment instruments and/or identifiers associated with payment objects. The reader device 6026 can include a read head for reading a magnetic strip of a payment card, and further can include encryption technology for encrypting the information read from the magnetic strip. Additionally or alternatively, the reader device 6026 can be an EMV payment reader, which in some examples, can be embedded in the user device 6002. Moreover, numerous other types of readers can be employed with the user device 6002 herein, depending on the type and configuration of the user device 6002.

The reader device 6026 may be a portable magnetic stripe card reader, optical scanner, smartcard (card with an embedded IC chip) reader (e.g., an EMV-compliant card reader or short-range communication-enabled reader), RFID reader, or the like, configured to detect and obtain data from various types of payment instruments. Accordingly, the reader device 6026 may include hardware implementation, such as slots, magnetic tracks, and rails with one or more sensors or electrical contacts to facilitate detection and acceptance of a payment instrument. That is, the reader device 6026 may include hardware implementations to enable the reader device 6026 to interact with a payment instrument via a swipe, a dip, or a tap to obtain payment data associated with a customer. Additionally or optionally, the reader device 6026 may also include a biometric sensor to receive and process biometric characteristics and process them as payment instruments, given that such biometric characteristics are registered with the payment service and connected to a financial account with a bank server. The reader device 6026 may include processing unit(s), computer-readable media, a reader chip, a transaction chip, a timer, a clock, a network interface, a power supply, and so on. That is, the reader device 6026 may include any of the computing components described herein with reference to the user device 6002 to implement the functionality provided by the reader device 6026.

In examples, the reader device 6026 includes a reader chip, which may perform functionality to control the power supply, among other functionality of the reader device 6026. The power supply may include one or more power supplies such as a physical connection to AC power or a battery. Power supply may include power conversion circuitry for converting AC power and generating a plurality of DC voltages for use by components of reader device 6026. When power supply includes a battery, the battery may be charged via a physical power connection, via inductive charging, or via any other suitable method.

The reader device 6026 may also include a transaction chip that may perform functionalities relating to processing of payment transactions, interfacing with payment instruments, cryptography, and other payment-specific functionality. That is, the transaction chip may access payment data associated with a payment instrument and may provide the payment data to a POS terminal, as described above. The payment data may include, but is not limited to, a name of the customer, an address of the customer, a type (e.g., credit, debit, etc.) of a payment instrument, a number associated with the payment instrument, a verification value (e.g., PIN Verification Key Indicator (PVKI), PIN Verification Value (PVV), Card Verification Value (CVV), Card Verification Code (CVC), etc.) associated with the payment instrument, an expiration data associated with the payment instrument, a primary account number (PAN) corresponding to the customer (which may or may not match the number associated with the payment instrument), restrictions on what types of charges/debts may be made, etc. The transaction chip may encrypt the payment data upon receiving the payment data.

It should be understood that in some examples, the reader chip may have its own processing unit(s) and computer-readable media and/or the transaction chip may have its own processing unit(s) and computer-readable media. In other examples, the functionalities of reader chip and transaction chip may be embodied in a single chip or a plurality of chips, each including any suitable combination of processing units and computer-readable media to collectively perform the functionalities of reader chip and transaction chip as described herein.

While the user device 6002, which can be a POS terminal, and the reader device 6026 are shown as separate devices, in additional or alternative examples, the user device 6002 and the reader device 6026 can be part of a single device, which may be a battery-operated device. In some examples, the reader device 6026 can have a display integrated therewith, which can be in addition to (or as an alternative of) the display 6016 associated with the user device 6002.

The server(s) 6004 can include one or more servers or other types of computing devices that can be embodied in any number of ways. For example, in the example of a server, the components, other functional components, and data can be implemented on a single server, a cluster of servers, a server farm or data center, a cloud-hosted computing service, a cloud-hosted storage service, and so forth, although other computer architectures can additionally or alternatively be used.

Further, while the figures illustrate the components and data of the server(s) 6004 as being present in a single location, these components and data can alternatively be distributed across different computing devices and different locations in any manner. Consequently, the functions can be implemented by one or more server computing devices, with the various functionality described above distributed in various ways across the different computing devices. Multiple server(s) 6004 can be located together or separately, and organized, for example, as virtual servers, server banks and/or server farms. The described functionality can be provided by the servers of a single merchant or enterprise, or can be provided by the servers and/or services of multiple different customers or enterprises.

In the illustrated example, the server(s) 6004 can include one or more processors 6028, one or more computer-readable media 6030, one or more I/O devices 6032, and one or more communication interfaces 6034. Each processor 6028 can be a single processing unit or a number of processing units, and can include single or multiple computing units or multiple processing cores. The processor(s) 6028 can be implemented as one or more microprocessors, microcomputers, microcontrollers, digital signal processors, central processing units, state machines, logic circuitries, and/or any devices that manipulate signals based on operational instructions. For example, the processor(s) 6028 can be one or more hardware processors and/or logic circuits of any suitable type specifically programmed or configured to execute the algorithms and processes described herein. The processor(s) 6028 can be configured to fetch and execute computer-readable instructions stored in the computer-readable media 6030, which can program the processor(s) 6028 to perform the functions described herein.

The computer-readable media 6030 can include volatile and nonvolatile memory and/or removable and non-removable media implemented in any type of technology for storage of information, such as computer-readable instructions, data structures, program components, or other data. Such computer-readable media 6030 can include, but is not limited to, RAM, ROM, EEPROM, flash memory or other memory technology, optical storage, solid state storage, magnetic tape, magnetic disk storage, RAID storage systems, storage arrays, network attached storage, storage area networks, cloud storage, or any other medium that can be used to store the desired information and that can be accessed by a computing device. Depending on the configuration of the server(s) 6004, the computer-readable media 6030 can be a type of computer-readable storage media and/or can be a tangible non-transitory media to the extent that when mentioned, non-transitory computer-readable media exclude media such as energy, carrier signals, electromagnetic waves, and signals per se.

The computer-readable media 6030 can be used to store any number of functional components that are executable by the processor(s) 6028. In many implementations, these functional components comprise instructions or programs that are executable by the processors 6028 and that, when executed, specifically configure the one or more processors 6028 to perform the actions attributed above to the merchant platform 5810, the P2P platform 5812, and/or the media content platform 5814. Functional components stored in the computer-readable media 6030 can optionally include an interface component 6036, an predictive control component 6038, and one or more other components and data 6040. The computer-readable media 6030 can additionally include an operating system 6042 for controlling and managing various functions of the server(s) 6004.

In some examples, the interface component 6036 can analyze the performance of different components of the mining system (and/or other types of contextual information about the mining systems) and provide granular status updates on the statuses of the different components of the mining system (e.g., as being in need of repair, replacement, and/or maintained), for instance via the indicator interface 305 and/or via alerts sent to the user device. For instance, in some examples, the interface component 6036 can perform, and/or be involved in performance of, the process 5400.

In some examples, the predictive control component 6038 can analyze conditions in the environment and/or the mining systems (and/or other types of contextual information about the environment and/or mining systems) to predict a condition that is to occur, such as a weather condition and/or a condition of the electrical grid powering the mining systems. Before the arrival of the time period in which the condition is predicted to occur, the predictive control component 6038 can configure the mining system to predictively switch from a first configuration before the time period to a second configuration during the time period. In the second configuration, the mining system can use a resource (e.g., power) differently than in the first configuration (e.g., using less power, using more power). When the time period arrives, the mining system (and/or the predictive control component 6038) can cause the mining system to switch from the first configuration to the second configuration. In some examples, the predictive control component 6038 can configure the mining system to return from the second configuration back to the first configuration after the time period is over (e.g., after an extreme weather condition is over or a problem with the electrical grid is over).

determine whether a given interface (e.g., sensor and/or communication interface) is usable or non-usable in a current mode of a context-sensitive scanner system (and/or an application running on the context-sensitive scanner system). In some examples, the interface component 6036 and the predictive control component 6038 can work together, for instance utilizing mode control engine(s) 360 and/or the ML model(s) 725.

The payment component can be configured to receive transaction data from POS systems. The payment component can transmit requests (e.g., authorization, capture, settlement, etc.) to payment service server computing device(s) to facilitate POS transactions between merchants and customers. The payment component can communicate the successes or failures of the POS transactions to the POS systems.

The training component can be configured to train models using machine-learning mechanisms, as well as retrain the models to improve outputs provided by the models based on feedback received over time. For example, a machine-learning mechanism can analyze training data to train a data model that generates an output, which can be a recommendation, a score, and/or another indication. Machine-learning mechanisms can include, but are not limited to supervised learning algorithms (e.g., artificial neural networks, Bayesian statistics, support vector machines, decision trees, classifiers, k-nearest neighbor, etc.), unsupervised learning algorithms (e.g., artificial neural networks, association rule learning, hierarchical clustering, cluster analysis, etc.), semi-supervised learning algorithms, deep learning algorithms, etc.), statistical models, etc. In at least one example, machine-trained data models can be stored in a datastore associated with the user device(s) 6002 and/or the server(s) 6004 for use at a time after the data models have been trained (e.g., at runtime).

The one or more “components” referenced herein may be implemented as more components or as fewer components, and functions described for the components may be redistributed depending on the details of the implementation. The term “component,” as used herein, refers broadly to software stored on non-transitory storage medium (e.g., volatile or non-volatile memory for a computing device), hardware, or firmware (or any combination thereof) components. Modules are typically functional such that they may generate useful data or other output using specified input(s). A component may or may not be self-contained. An application program (also called an “application”) may include one or more components, or a component may include one or more application programs that can be accessed over a network or downloaded as software onto a device (e.g., executable code causing the device to perform an action). An application program (also called an “application”) may include one or more components, or a component may include one or more application programs. In additional and/or alternative examples, the component(s) may be implemented as computer-readable instructions, various data structures, and so forth via at least one processing unit to configure the computing device(s) described herein to execute instructions and to perform operations as described herein.

In some examples, a component may include one or more application programming interfaces (APIs) to perform some or all of its functionality (e.g., operations). In at least one example, a software developer kit (SDK) can be provided by the service provider to allow third-party developers to include service provider functionality and/or avail service provider services in association with their own third-party applications. Additionally or alternatively, in some examples, the service provider can utilize a SDK to integrate third-party service provider functionality into its applications. That is, API(s) and/or SDK(s) can enable third-party developers to customize how their respective third-party applications interact with the service provider or vice versa.

The communication interface(s) 6034 can include one or more interfaces and hardware components for enabling communication with various other devices, such as over the network(s) 6006 or directly. For example, communication interface(s) 6034 can enable communication through one or more network(s) 6006, which can include, but are not limited any type of network known in the art, as described herein.

The server(s) 6004 can further be equipped with various I/O devices 6032. Such I/O devices 6032 can include a display, various user interface controls (e.g., buttons, joystick, keyboard, mouse, touch screen, biometric or sensory input devices, etc.), audio speakers, connection ports and so forth.

In at least one example, the system 6000 can include a datastore 6044 that can be configured to store data that is accessible, manageable, and updatable. In some examples, the datastore 6044 can be integrated with the user device 6002 and/or the server(s) 6004. In other examples, as shown in FIG. 60, the datastore 6044 can be located remotely from the server(s) 6004 and can be accessible to the server(s) 6004. The datastore 6044 can comprise multiple databases and/or servers connected locally and/or remotely via the network(s) 6006. In at least one example, the datastore 6044 can store user profiles, which can include merchant profiles, customer profiles, artist profiles, and so on.

Merchant profiles can store, or otherwise be associated with, data associated with merchants. For instance, a merchant profile can store, or otherwise be associated with, information about a merchant (e.g., name of the merchant, geographic location of the merchant, operating hours of the merchant, employee information, etc.), a merchant category classification (MCC), item(s) offered for sale by the merchant, hardware (e.g., device type) used by the merchant, transaction data associated with the merchant (e.g., transactions conducted by the merchant, payment data associated with the transactions, items associated with the transactions, descriptions of items associated with the transactions, itemized and/or total spends of each of the transactions, parties to the transactions, dates, times, and/or locations associated with the transactions, etc.), loan information associated with the merchant (e.g., previous loans made to the merchant, previous defaults on said loans, etc.), risk information associated with the merchant (e.g., indications of risk, instances of fraud, chargebacks, etc.), appointments information (e.g., previous appointments, upcoming (scheduled) appointments, timing of appointments, lengths of appointments, etc.), payroll information (e.g., employees, payroll frequency, payroll amounts, etc.), employee information, reservations data (e.g., previous reservations, upcoming (scheduled) reservations, interactions associated with such reservations, etc.), inventory data, customer service data, etc. The merchant profile can securely store bank account information as provided by the merchant. Further, the merchant profile can store payment information associated with a payment instrument linked to a stored balance of the merchant, such as a stored balance maintained in a ledger by the service provider.

Customer profiles can store customer data including, but not limited to, customer information (e.g., name, phone number, address, banking information, etc.), customer preferences (e.g., learned or customer-specified), purchase history data (e.g., identifying one or more items purchased (and respective item information), payment instruments used to purchase one or more items, returns associated with one or more orders, statuses of one or more orders (e.g., preparing, packaging, in transit, delivered, etc.), etc.), appointments data (e.g., previous appointments, upcoming (scheduled) appointments, timing of appointments, lengths of appointments, etc.), payroll data (e.g., employers, payroll frequency, payroll amounts, etc.), reservations data (e.g., previous reservations, upcoming (scheduled) reservations, reservation duration, interactions associated with such reservations, etc.), inventory data, customer service data, media content consumption data (e.g., number of streams of media content and by which artists, direct artist payouts, playlists generated or “favorited,” durations of listening and/or watching individual media content items, actions performed while consuming media content (e.g., skips, repeats, volume changes, etc.), locations at which media content is consumed, devices used to consume media content, activities during which media content is consumed, etc.), etc.

Artist profiles can store data including, but not limited to, artist information (e.g., artist's performance or stage name, band name, artist's legal name, record label, phone number, address, social media handles, website address, banking information, etc.), artist preferences (e.g., learned or artist-specified), media content (and/or associated data) at least partially attributed to the artist (e.g., songs, videos, artists in a same genre or having shared listeners, etc.), event data (e.g., tour dates, appearance dates, appointments, etc.), financial data (e.g., advance data, recoupment data, royalty data, payouts data, etc.), payroll data (e.g., employees, contractors, venues, payroll frequency, etc.), listening data (e.g., number of streams on media content platform(s), listening trends, etc.), fan data (number of followers on media content platform(s), number of followers on social media platform(s), etc.), reservations data (e.g., venue reservations, studio recording reservations, previous reservations, upcoming (scheduled) reservations, reservation duration, interactions associated with such reservations, etc.), inventory data (e.g., merchandise inventory), customer service data, and so forth.

Furthermore, in at least one example, the datastore 6044 can store inventory database(s) and/or catalog database(s). As described above, an inventory can store data associated with a quantity of each item that a merchant has available to the merchant. Furthermore, a catalog can store data associated with items that a merchant has available for acquisition. The datastore 6044 can store additional or alternative types of data as described herein.

The phrases “in some examples,” “according to various examples,” “in the examples shown,” “in one example,” “in other examples,” “various examples,” “some examples,” and the like generally mean the particular feature, structure, or characteristic following the phrase is included in at least one example of the present invention, and may be included in more than one example of the present invention. In addition, such phrases do not necessarily refer to the same examples or to different examples.

If the specification states a component or feature “can,” “may,” “could,” or “might” be included or have a characteristic, that particular component or feature is not required to be included or have the characteristic.

Further, the aforementioned description is directed to devices and applications that are related to payment technology. However, it will be understood, that the technology can be extended to any device and application. Moreover, techniques described herein can be configured to operate irrespective of the kind of payment object reader, POS terminal, web applications, mobile applications, POS topologies, payment cards, computer networks, and environments.

Various figures included herein are flowcharts showing example methods involving techniques as described herein. The methods illustrated are described with reference to components described in the figures for convenience and ease of understanding. However, the methods illustrated are not limited to being performed using components described in the figures and such components are not limited to performing the methods illustrated herein.

Furthermore, the methods described above are illustrated as collections of blocks in logical flow graphs, which represent sequences of operations that can be implemented in hardware, software, or a combination thereof. In the context of software, the blocks represent computer-executable instructions stored on one or more computer-readable storage media that, when executed by processor(s), perform the recited operations. Generally, computer-executable instructions include routines, programs, objects, components, data structures, and the like that perform particular functions or implement particular abstract data types. The order in which the operations are described is not intended to be construed as a limitation, and any number of the described blocks can be combined in any order and/or in parallel to implement the processes. In some embodiments, one or more blocks of the process can be omitted entirely. Moreover, the methods can be combined in whole or in part with each other or with other methods.

What is claimed is:

1. A cryptocurrency mining system comprising:
a housing;
a plurality of hashboards received into slots within the housing, wherein the plurality of hashboards each include a plurality of hashing chips that perform hash calculations;
a control board in the housing, wherein the control board allocates the hash calculations among the plurality of hashboards;
a fan that directs a fluid through an interior of the housing;
a power supply unit that supplies power to at least the control board, the fan, and the plurality of hashboards, wherein an amount of power inputs of the power supply unit is aligned to an amount of phases of power.

2. The cryptocurrency mining system of claim 1, wherein the hash calculations are used for mining a cryptocurrency.

3. The cryptocurrency mining system of claim 1, wherein the plurality of power inputs of the power supply unit being aligned to the plurality of phases of power reduces triple harmonics.

4. A system comprising:
a plurality of hashboards, wherein the plurality of hashboards include a plurality of hashing chips that perform hash calculations;
a control board that allocates the hash calculations among the plurality of hashboards; and
a power supply unit that supplies power to at least the control board and the plurality of hashboards, wherein an amount of power inputs of the power supply unit is aligned to an amount of phases of power.

5. The system of claim 4, wherein the hash calculations are used for mining a cryptocurrency.

6. The system of claim 4, wherein the amount of power inputs of the power supply unit being aligned to the amount of phases of power reduces triple harmonics.

7. The system of claim 4, wherein the power supply unit includes a low dropout regulator (LDO).

8. The system of claim 4, wherein the power supply unit staggers the amount of phases of power to smoothen the power supplied from the power supply unit to at least the control board and the plurality of hashboards.

9. The system of claim 4, wherein the power supply unit is part of at least one of the plurality of hashboards.

10. The system of claim 4, further comprising:
a housing, wherein the control board is in the housing, wherein the power supply unit is in the housing, and wherein the plurality of hashboards are received into slots within the housing.

11. The system of claim 10, further comprising:
a fan, wherein the fan directs a fluid through an interior of a housing, wherein the fluid is one of a gas or a liquid.

12. The system of claim 4, wherein the control board predictively switches a configuration of the plurality of hashboards based on a predicted event, wherein the predicted event is at least one of a weather event or an electrical grid event.

13. The system of claim 12, wherein the control board predictively switching the configuration of the plurality of hashboards includes the control board modifying which of the plurality of hashboards receives power from the power supply unit.

14. The system of claim 12, wherein the control board predictively switching the configuration of the plurality of hashboards includes the control board modifying which hashing chips receive power from the power supply unit.

15. The system of claim 4, wherein the power supply unit includes a phase-locked loop (PLL) and a voltage-controlled oscillator (VCO).

16. The system of claim 4, wherein the plurality of hashboards includes a phase-locked loop (PLL) and a voltage-controlled oscillator (VCO).

17. The system of claim 4, wherein the plurality of hashing chips is a plurality of application specific integrated circuits (ASICs).

18. The system of claim 4, further comprising:
a sensor that measures a characteristic of at least a subset of the plurality of hashing chips of the plurality of hashboards.

19. The system of claim 4, further comprising:
an indicator interface with a plurality of light sources, wherein an illumination characteristic of at least one of the plurality of light sources changes in response to identification of a condition associated with at least one of the control board, the power supply unit, or the plurality of hashboards.

20. A method comprising:
receiving power through a power supply unit, wherein an amount of power inputs of the power supply unit is aligned to an amount of phases of power;
supplying power from the power supply unit to at least a control board and a plurality of hashboards;
using the control board to allocate hash calculations among the plurality of hashboards; and
performing the hash calculations using a plurality of bashing chips of the plurality of hashboards.
